(19) United States
(12) Patent Application Publication
(10) Pub. No.: US 2021/0408090 A1
(43) Pub. Date: Dec. 30, 2021

(54) IMAGING DEVICE

(71) Applicant: SONY SEMICONDUCTOR SOLUTIONS CORPORATION, KANAGAWA (JP)

(72) Inventor: YUSUKE KOHYAMA, KANAGAWA (JP)

(21) Appl. No.: 17/291,221

(22) PCT Filed: Oct. 31, 2019
(86) PCT No.: PCT/JP2019/042756

§ 371 Date: May 4, 2021

(30) Foreign Application Priority Data
Nov. 16, 2018 (JP) 2018-215383

(51) Int. Cl. H01L 27/146

(52) U.S. Cl. CPC H01L 27/1463; H01L 27/14609; H01L 27/14643; H01L 27/14621

(57) ABSTRACT

An imaging device according to an embodiment of the present disclosure includes: a plurality of photoelectric conversion sections; a plurality of color filters provided for the respective photoelectric conversion sections; an element separation section extending from between adjacent two of the photoelectric conversion sections to between adjacent two of the color filters; and a diffusion layer being provided in contact with a surface, of the element separation section, on side of the photoelectric conversion section, and having an electric conductivity type different from an electric conductivity type of the photoelectric conversion section.

### TECHNICAL FIELD

The present disclosure relates to an imaging device.

### BACKGROUND ART

In imaging devices, suppressing a crosstalk between pixels is an important issue. In order to suppress the crosstalk between pixels, it has heretofore been common to provide a separation structure called a DTI (Deep Trench Isolation) between pixels. For example, NPTL 1 discloses FDTI (Front DTI) formed from side of a front surface of a silicon wafer. In addition, for example, NPTLs 2 and 3 disclose a BDTI (Back DTI) formed from side of a back surface of a silicon wafer.

### CITATION LIST

### Non-Patent Literature

NPTL 1: A. Tournier et. al., “Pixel-to-Pixel isolation by Deep Trench technology: Application to CMOS Image Sensor”, IISW, R5, 2011
NPTL 2: K. Kitamura et. al., “Suppression of Crosstalk by Using Backside Deep Trench Isolation for 1.12 pm Backside Illuminated CMOS Image Sensor”, IEDM, p. 537, 2012
NPTL 3: S. Choi et. al., “An All Pixel PDAF CMOS Image Sensor with 0.64 μm×1.28 μm Photodiode Separated by Self-aligned In-pixel Deep Trench Isolation for High AF Performance”, VLSI Symp. Tech., p. 104, 2017

### SUMMARY OF THE INVENTION

Incidentally, in the field of imaging devices, it is required to suppress the crosstalk between pixels more effectively. It is therefore desirable to provide an imaging device that makes it possible to suppress a crosstalk between pixels more effectively.

An imaging device according to a first aspect of the present disclosure includes: a plurality of photoelectric conversion sections; a plurality of color filters provided for the respective photoelectric conversion sections; an element separation section extending from between adjacent two of the photoelectric conversion sections to between adjacent two of the color filters; and a diffusion layer being provided in contact with a surface, of the element separation section, on side of the photoelectric conversion section, and having an electric conductivity type different from an electric conductivity type of the photoelectric conversion section.

According to the imaging device of the first aspect of the present disclosure, the element separation section is provided, extending from between the two adjacent photoelectric conversion sections to between the two adjacent color filters. This allows for suppression of light leakage through a gap between the photoelectric conversion section and the color filter.

An imaging device according to a second aspect of the present disclosure includes: a plurality of photoelectric conversion sections provided in matrix in a semiconductor substrate; and an element separation section provided in the semiconductor substrate and between adjacent two of the photoelectric conversion sections. The element separation section has a DTI structure configured by an insulating film in contact with an inner wall of a trench provided in the semiconductor substrate and a metal buried part formed inside the insulating film. The metal buried part is formed by aluminum or an aluminum alloy.

According to the imaging device of the second aspect of the present disclosure, the element separation section between the two adjacent photoelectric conversion sections is provided with the metal buried part formed by aluminum or an aluminum alloy. This allows for suppression of light leakage through a gap between the two adjacent photoelectric conversion sections.

An imaging device according to a third aspect of the present disclosure includes: a plurality of photoelectric conversion sections provided in matrix in a semiconductor substrate; and an element separation section provided in the semiconductor substrate and between adjacent two of the photoelectric conversion sections. The imaging device further includes a well layer, a diffusion layer, and a plurality of readout circuits. The well layer is provided on side of a surface, of the semiconductor substrate, opposite to a light-receiving surface, and has an electric conductivity type different from an electric conductivity type of the photoelectric conversion section. The diffusion layer is provided in contact with a surface, of the element separation section, on side of the photoelectric conversion section, and has an electric conductivity type different from the electric conductivity type of the photoelectric conversion section. The plurality of readout circuits are provided one by one in the well layer for the respective photoelectric conversion sections. Each of the readout circuits outputs a pixel signal based on charges outputted from the photoelectric conversion section.

According to the imaging device of the third aspect of the present disclosure, the element separation section and the diffusion layer being in contact with the surface on the side of the photoelectric conversion section and having the electric conductivity type different from the electric conductivity type of the photoelectric conversion section are provided between the two adjacent photoelectric conversion sections. In this imaging device, the plurality of readout circuits each sharing the plurality of photoelectric conversion sections are further provided in the well layer provided in contact with the surface on the side of the photoelectric conversion section. This makes it possible to suppress light leakage through a gap between the two adjacent photoelectric conversion sections, while sharing the plurality of photoelectric conversion sections by one readout circuit.

### BRIEF DESCRIPTION OF THE DRAWINGS

FIG. 1 illustrates an example of a schematic configuration of an imaging device according to a first embodiment of the present disclosure.

FIG. 2 illustrates an example of a sensor pixel and a readout circuit of FIG. 1.

FIG. 3 illustrates an example of a cross-sectional configuration in a horizontal direction of the sensor pixel of FIG. 1.

FIG. 4 illustrates an example of a cross-sectional configuration in a vertical direction of the imaging device of FIG. 1.

FIG. 5 illustrates an example of a manufacturing process of the imaging device of FIG. 1.

FIG. 6 illustrates an example of a manufacturing process subsequent to FIG. 5.

FIG. 7 illustrates an example of a manufacturing process subsequent to FIG. 6.

FIG. 8 illustrates an example of a manufacturing process subsequent to FIG. 7.

FIG. 9 illustrates an example of a manufacturing process subsequent to FIG. 8.

FIG. 10 illustrates an example of a manufacturing process subsequent to FIG. 9.

FIG. 11 illustrates an example of a manufacturing process subsequent to FIG. 10.

FIG. 12 illustrates an example of a manufacturing process subsequent to FIG. 11.

FIG. 13 illustrates an example of a manufacturing process subsequent to FIG. 12.

FIG. 14 illustrates an example of a manufacturing process subsequent to FIG. 13.

FIG. 15 illustrates an example of a manufacturing process subsequent to FIG. 14.

FIG. 16 illustrates an example of a manufacturing process subsequent to FIG. 15.

FIG. 17 illustrates an example of a manufacturing process subsequent to FIG. 16.

FIG. 18 illustrates an example of a manufacturing process subsequent to FIG. 17.

FIG. 19 illustrates an example of a manufacturing process subsequent to FIG. 18.

FIG. 20 illustrates an example of a manufacturing process subsequent to FIG. 19.

FIG. 21 illustrates an example of a manufacturing process subsequent to FIG. 20.

FIG. 22 illustrates an example of a manufacturing process subsequent to FIG. 21.

FIG. 23 illustrates a modification example of a cross-sectional configuration in the vertical direction of the imaging device of FIG. 1.

FIG. 24 illustrates an example of a manufacturing process of the imaging device of FIG. 23.

FIG. 25 illustrates an example of a manufacturing process subsequent to FIG. 24.

FIG. 26 illustrates an example of a manufacturing process subsequent to FIG. 25.

FIG. 27 illustrates an example of a manufacturing process subsequent to FIG. 26.

FIG. 28 illustrates an example of a manufacturing process subsequent to FIG. 27.

FIG. 29 illustrates an example of a manufacturing process subsequent to FIG. 28.

FIG. 30 illustrates an example of a manufacturing process subsequent to FIG. 29.

FIG. 31 illustrates a modification example of a cross-sectional configuration in the vertical direction of the imaging device of FIG. 1.

FIG. 32 illustrates an example of a manufacturing process of the imaging device of FIG. 31.

FIG. 33 illustrates an example of a manufacturing process subsequent to FIG. 32.

FIG. 34 illustrates an example of a manufacturing process subsequent to FIG. 33.

FIG. 35 illustrates an example of a manufacturing process subsequent to FIG. 34.

FIG. 36 illustrates an example of a manufacturing process subsequent to FIG. 35.

FIG. 37 illustrates an example of a schematic configuration of an imaging device according to a second embodiment of the present disclosure.

FIG. 38 illustrates an example of a pixel of FIG. 37.

FIG. 39 illustrates an example of a cross-sectional configuration in the vertical direction of the imaging device of FIG. 38.

FIG. 40 illustrates an example of a manufacturing process of the imaging device of FIG. 38.

FIG. 41 illustrates an example of a manufacturing process subsequent to FIG. 40.

FIG. 42 illustrates an example of a manufacturing process subsequent to FIG. 41.

FIG. 43 illustrates an example of a manufacturing process subsequent to FIG. 42.

FIG. 44 illustrates an example of a manufacturing process subsequent to FIG. 43.

FIG. 45 illustrates an example of a manufacturing process subsequent to FIG. 44.

FIG. 46 illustrates an example of a manufacturing process subsequent to FIG. 45.

FIG. 47 illustrates an example of a manufacturing process subsequent to FIG. 46.

FIG. 48 illustrates an example of a manufacturing process subsequent to FIG. 47.

FIG. 49 illustrates an example of a manufacturing process subsequent to FIG. 48.

FIG. 50 illustrates an example of a manufacturing process subsequent to FIG. 49.

FIG. 51 illustrates an example of a manufacturing process subsequent to FIG. 50.

FIG. 52 illustrates an example of a manufacturing process subsequent to FIG. 51.

FIG. 53 illustrates an example of a manufacturing process subsequent to FIG. 52.

FIG. 54 illustrates an example of a manufacturing process subsequent to FIG. 53.

FIG. 55 illustrates a modification example of the sensor pixel and the readout circuit of the imaging device in FIG. 1.

FIG. 56 illustrates a modification example of the pixel of the imaging device of FIG. 38.

FIG. 57 illustrates an example of a cross-sectional configuration in the horizontal direction of an imaging device including the pixel of FIG. 56.

FIG. 58 illustrates an example of a cross-sectional configuration in the horizontal direction of an imaging device including the pixel of FIG. 56.

FIG. 59 illustrates an example of a cross-sectional configuration along a line A-A of FIG. 57.

FIG. 60 illustrates an example of a cross-sectional configuration along a line A-A of FIG. 58.

FIG. 61 illustrates a modification example of the sensor pixel and the readout circuit of FIG. 55.

FIG. 62 illustrates a modification example of the sensor pixel and the readout circuit of FIG. 55.

FIG. 63 illustrates a modification example of the sensor pixel and the readout circuit of FIG. 55.

FIG. 64 illustrates a modification example of a coupling mode between a plurality of readout circuits and a plurality of vertical signal lines.

FIG. 65 illustrates a modification example of a cross-sectional configuration in the horizontal direction of an imaging device having the configuration of FIG. 55.

FIG. 66 illustrates a modification example of a cross-sectional configuration in the horizontal direction of the imaging device having the configuration of FIG. 55.

FIG. 67 illustrates a modification example of a wiring line layout in a horizontal plane of the imaging device having the configuration of FIG. 55.

FIG. 68 illustrates a modification example of a wiring line layout in the horizontal plane of the imaging device having the configuration of FIG. 55.

FIG. 69 illustrates a modification example of a wiring line layout in the horizontal plane of the imaging device having the configuration of FIG. 55.

FIG. 70 illustrates a modification example of a wiring line layout in the horizontal plane of the imaging device having the configuration of FIG. 55.

FIG. 71 illustrates a modification example of a cross-sectional configuration in the vertical direction of the imaging device of FIG. 1.

FIG. 72 illustrates a modification example of the cross-sectional configuration in the horizontal direction of the imaging device of FIG. 1.

FIG. 73 illustrates a modification example of the cross-sectional configuration in the horizontal direction of the imaging device of FIG. 1.

FIG. 74 illustrates a modification example of the cross-sectional configuration in the horizontal direction of the imaging device of FIG. 1.

FIG. 75 illustrates a modification example of the cross-sectional configuration in the horizontal direction of the imaging device of FIG. 1.

FIG. 76 illustrates a modification example of the cross-sectional configuration in the horizontal direction of the imaging device of FIG. 1.

FIG. 77 illustrates a modification example of the cross-sectional configuration in the horizontal direction of the imaging device of FIG. 1.

FIG. 78 illustrates a modification example of the cross-sectional configuration in the horizontal direction of the imaging device of FIG. 1.

FIG. 79 illustrates an example of a circuit configuration of an imaging device provided with the imaging device according to any of the foregoing embodiments and modification examples thereof.

FIG. 80 illustrates an example of a configuration of the imaging device of FIG. 79, in which three substrates are stacked.

FIG. 81 illustrates an example in which a logic circuit is formed separately in a substrate including the sensor pixel and a substrate including the readout circuit.

FIG. 82 illustrates an example in which a logic circuit is formed in a third substrate.

FIG. 83 illustrates an example of a schematic configuration of an imaging system including the imaging device according to any of the foregoing embodiments and modification examples thereof.

FIG. 84 illustrates an example of an imaging procedure in the imaging system of FIG. 83.

FIG. 85 is a block diagram depicting an example of schematic configuration of a vehicle control system.

FIG. 86 is a diagram of assistance in explaining an example of installation positions of an outside-vehicle information detecting section and an imaging section.

FIG. 87 is a view depicting an example of a schematic configuration of an endoscopic surgery system.

FIG. 88 is a block diagram depicting an example of a functional configuration of a camera head and a camera control unit (CCU).

### MODES FOR CARRYING OUT THE INVENTION

Hereinafter, description is given in detail of embodiments of the present disclosure with reference to the drawings. It is to be noted that the description is given in the following order.

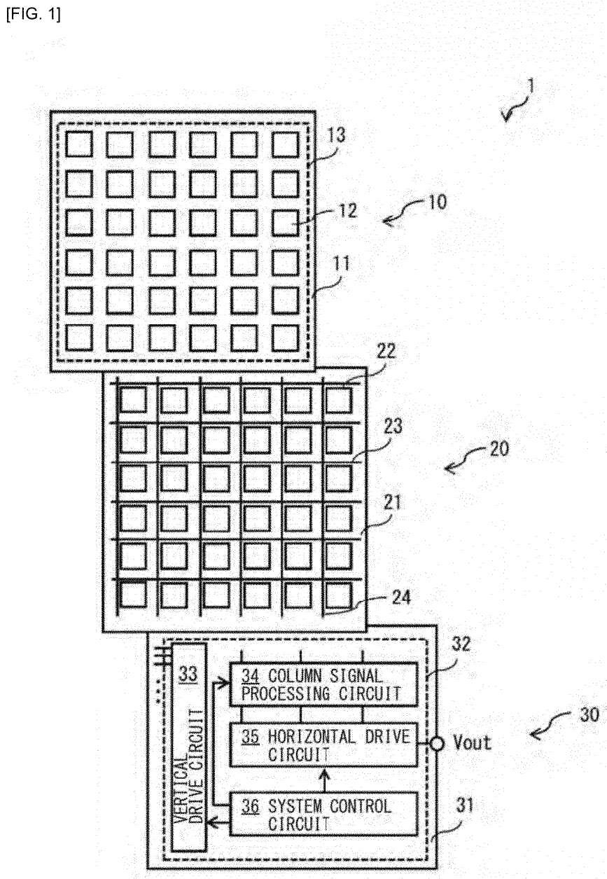

### 1. First Embodiment (Imaging Device) . . . FIGS. 1 to 22

### 2. Modification Examples of First Embodiment (Imaging Device)

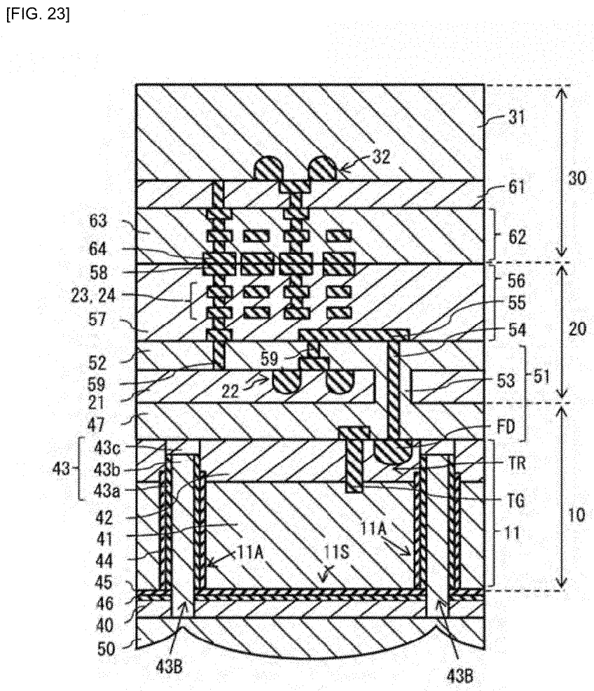

Modification Example A . . . FIGS. 23 to 30

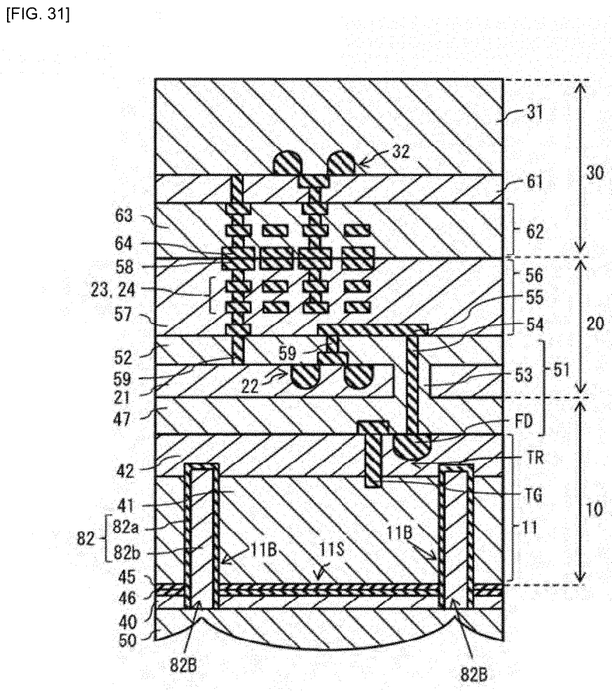

Modification Example B FIGS. 31 to 36

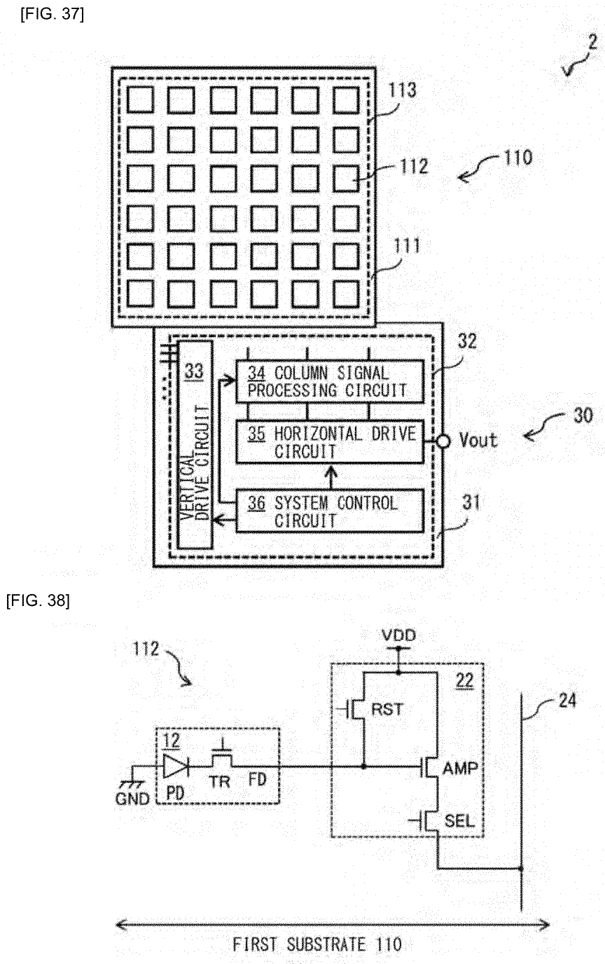

### 3. Second Embodiment (Imaging Device) . . . FIGS. 37 to 54

### 4. Modification Examples of Each Embodiment (Imaging Device)

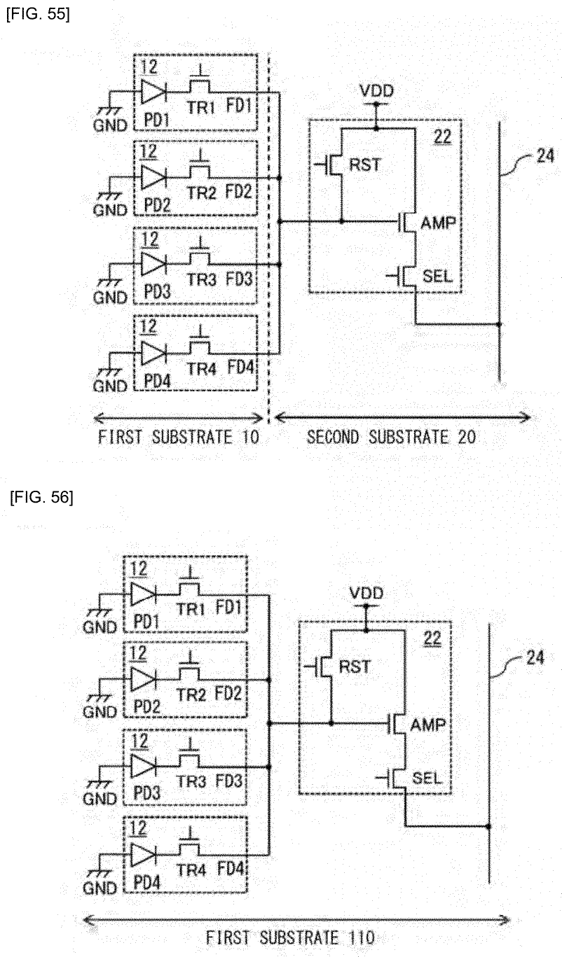

Modification Example C . . . FIG. 55

Modification Example D . . . FIG. 56

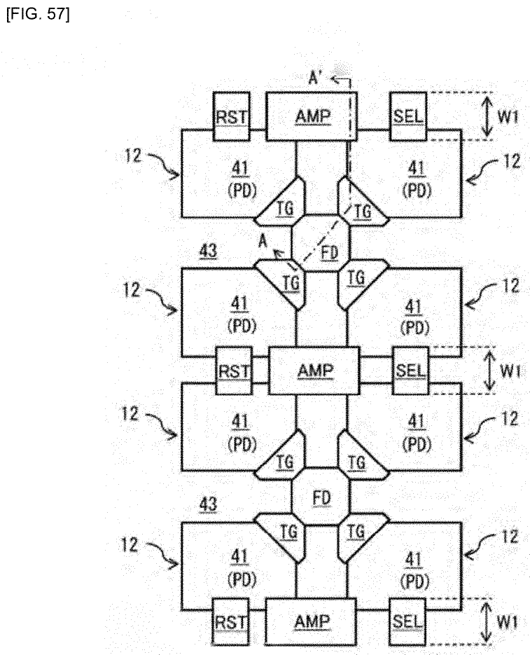

Modification Example E FIGS. 57 to 60

Modification Example F FIGS. 61 to 64

Modification Example G FIGS. 65 to 70

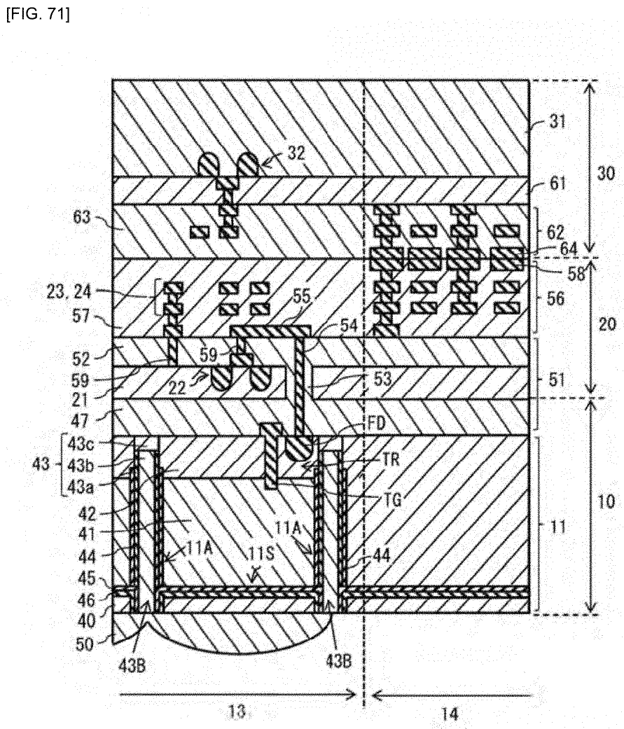

Modification Example H . . . FIG. 71

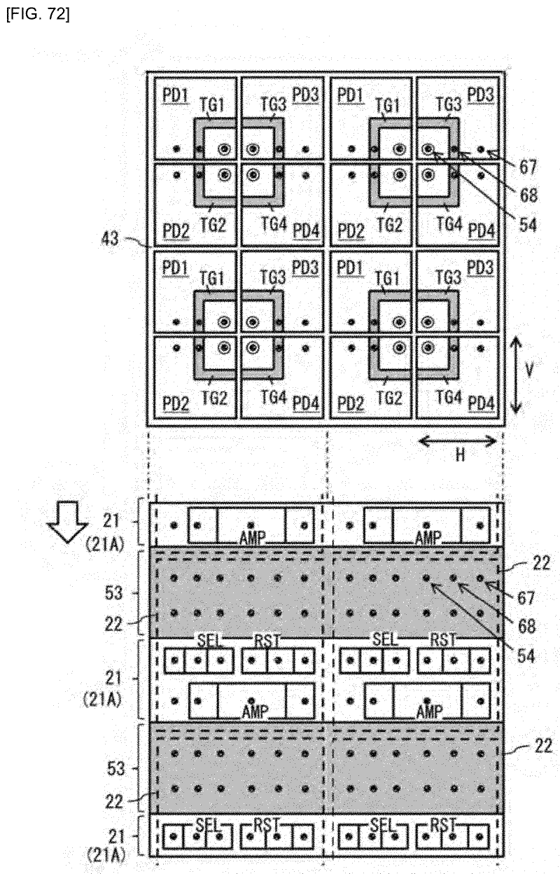

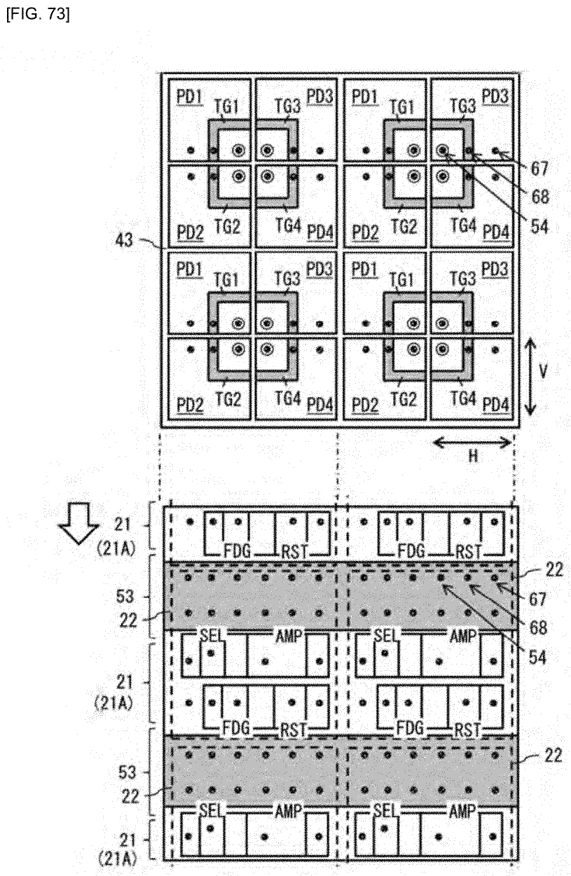

Modification Example I . . . FIGS. 72 and 73

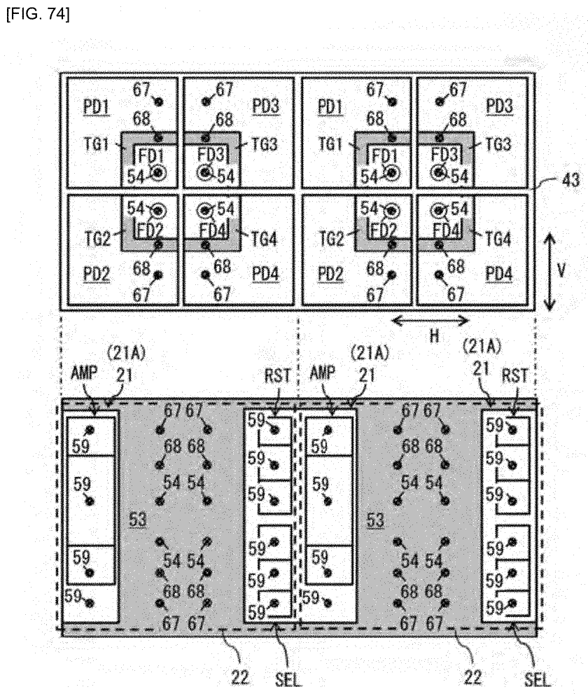

Modification Example J . . . FIG. 74

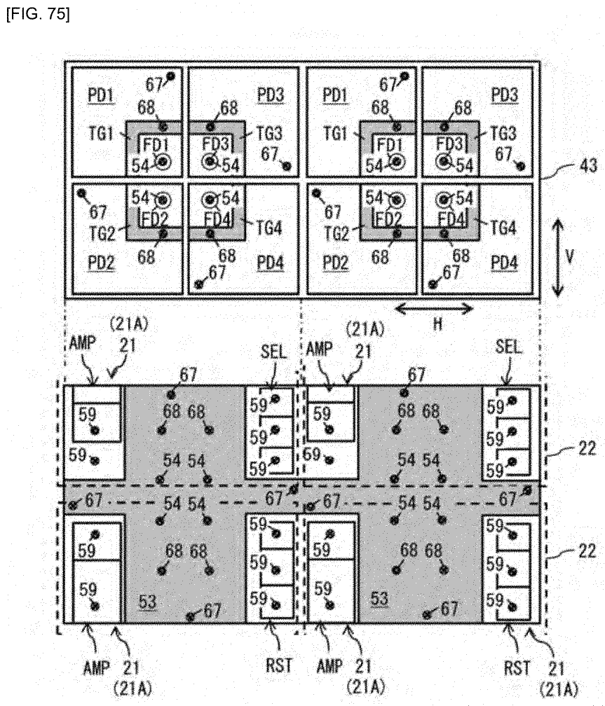

Modification Example K . . . FIG. 75

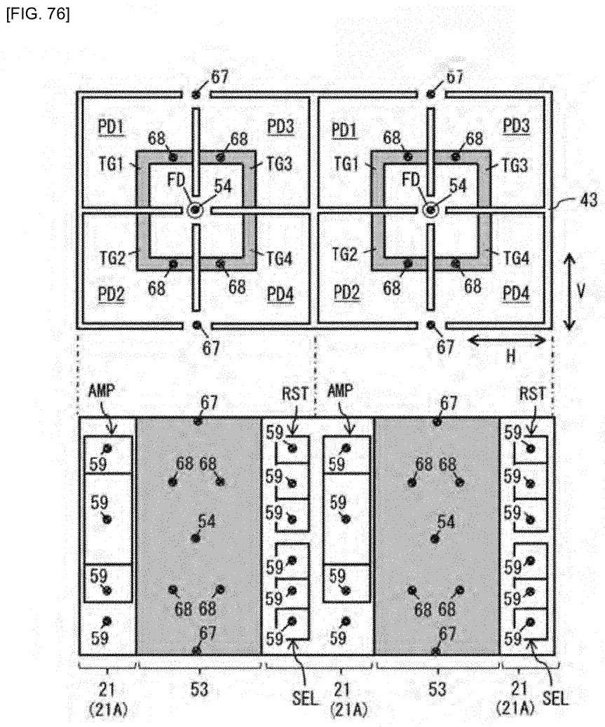

Modification Example L FIGS. 76 to 78

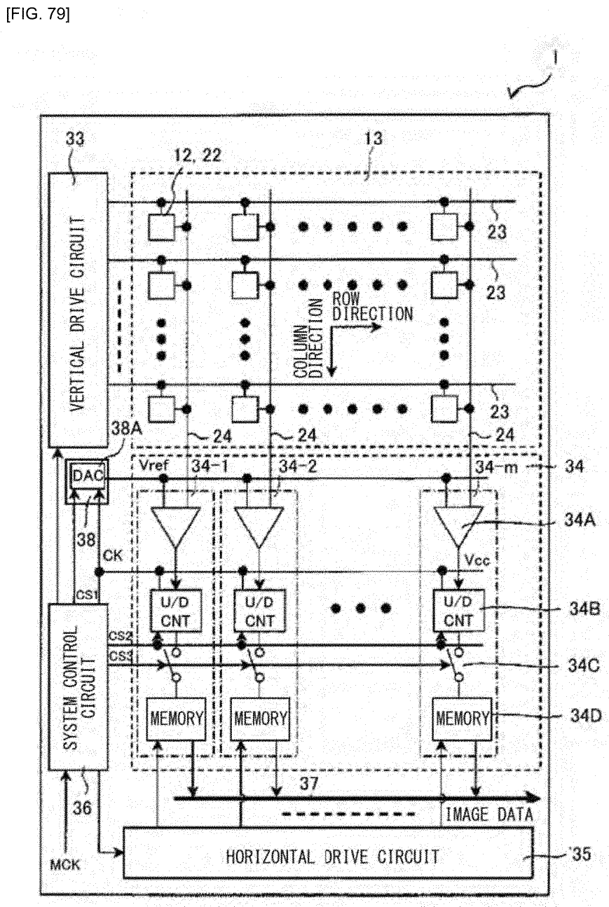

Modification Example M . . . FIG. 79

Modification Example N . . . FIG. 80

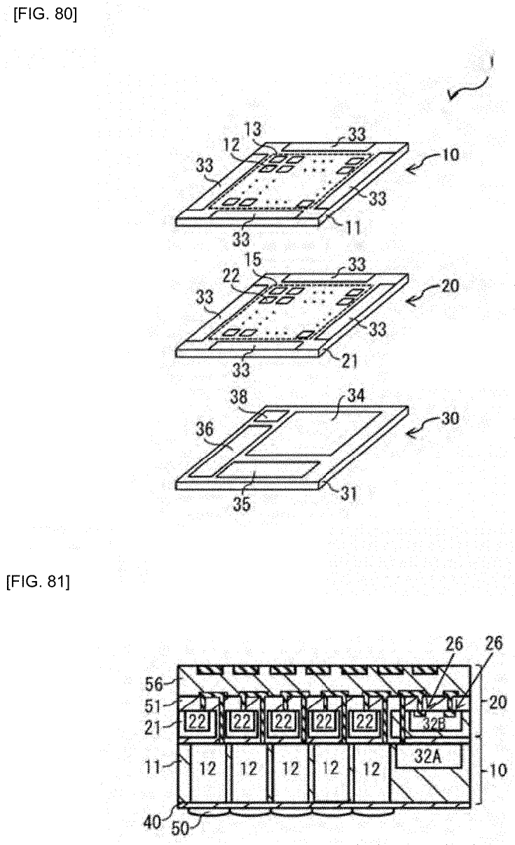

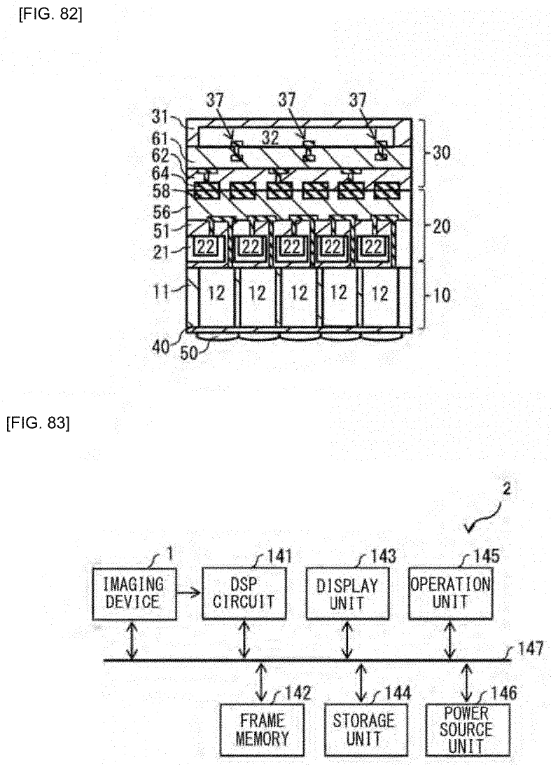

Modification Example 0 . . . FIGS. 81 and 82

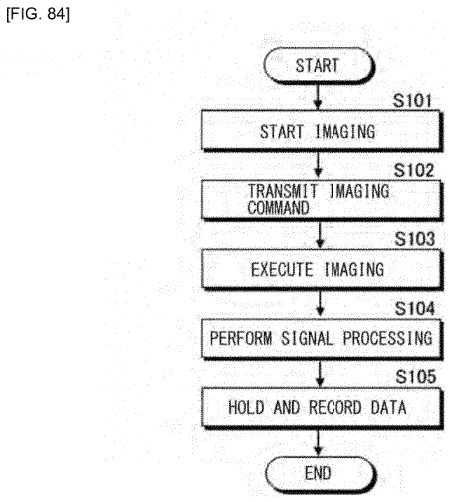

### 5. Application Example (Imaging System) . . . FIGS. 83 and 84

### 6. Practical Application Examples

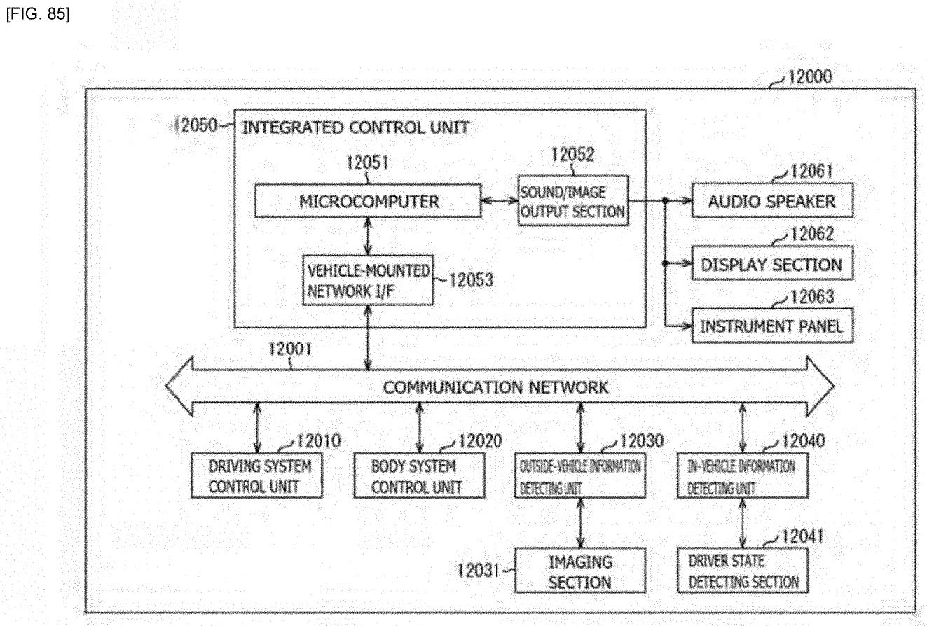

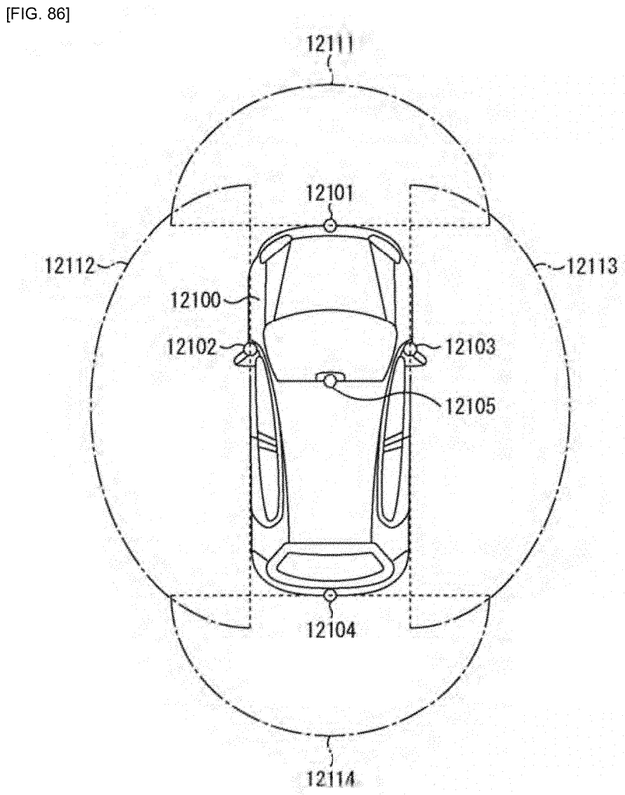

Example of Practical Application to Mobile Body . . . FIGS. 85 and 86

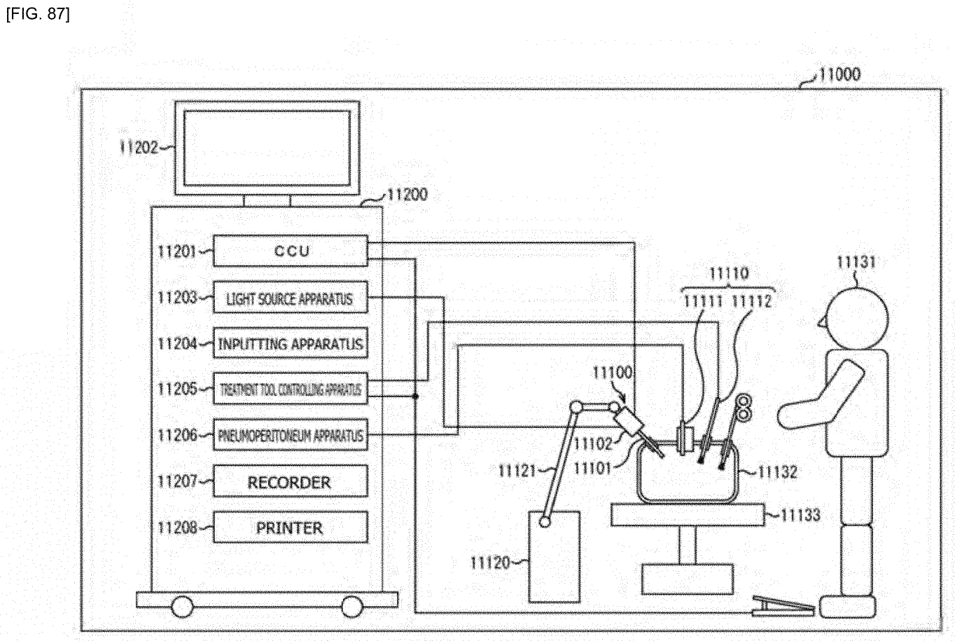

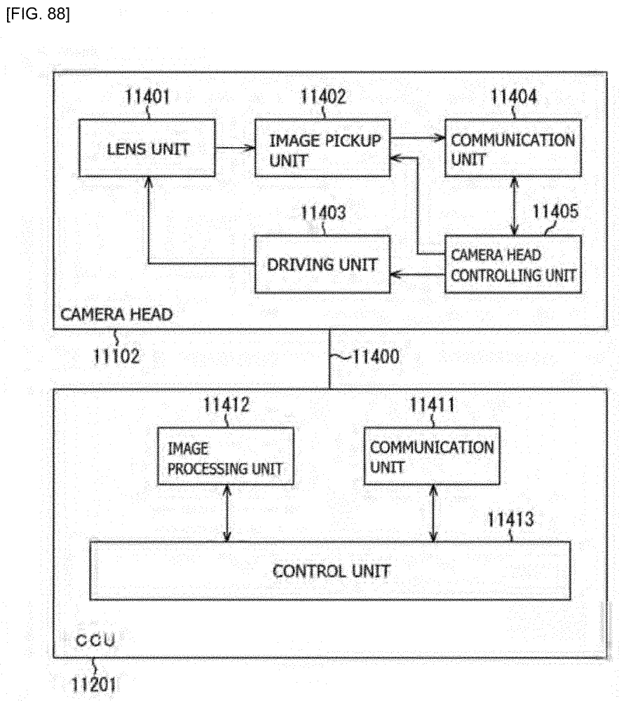

Example of Practical Application to Endoscopic Surgery System . . . FIGS. 87 and 88

### 1. First Embodiment

### [Configuration]

FIG. 1 illustrates an example of a schematic configuration of an imaging device 1 according to a first embodiment of the present disclosure. The imaging device 1 includes three substrates (a first substrate 10, a second substrate 20, and a third substrate 30). The imaging device 1 is a three-dimensionally structured imaging device configured by attaching the three substrates (first substrate 10, second substrate 20, and third substrate 30) together. The first substrate 10, the second substrate 20, and the third substrate 30 are stacked in this order.

The first substrate 10 is a substrate including, on a semiconductor substrate 11, a plurality of sensor pixels 12 that perform photoelectric conversion. The plurality of sensor pixels 12 are provided in matrix inside a pixel region 13 in the first substrate 10. The second substrate 20 is a substrate including, on a semiconductor substrate 21, readout circuits 22, which each output a pixel signal based on charges outputted from the sensor pixels 12 (e.g., photodiodes PD described later), with one readout circuit 22 provided for each sensor pixel 12. The second substrate 20 includes a plurality of pixel drive lines 23 extending in a row direction and a plurality of vertical signal lines 24 extending in a column direction. The third substrate 30 is a substrate including, on a semiconductor substrate 31, a logic circuit 32 that processes the pixel signal. The logic circuit 32 includes, for example, a vertical drive circuit 33, a column signal processing circuit 34, a horizontal drive circuit 35, and a system control circuit 36. The logic circuit 32 (specifically, the horizontal drive circuit 35) outputs an output-voltage Vout for each sensor pixel 12 to the outside. The logic circuit 32 includes, for example, a silicide as an electrode material.

The vertical drive circuit 33 sequentially selects, for example, the plurality of sensor pixels 12 in a unit of row. The column signal processing circuit 34 performs, for example, correlated double sampling (Correlated Double Sampling: CDS) processing on a pixel signal outputted from each sensor pixel 12 of a row selected by the vertical drive circuit 33. The column signal processing circuit 34 performs, for example, the CDS processing to thereby extract a signal level of the pixel signal and to hold pixel data corresponding to an amount of light reception of each sensor pixel 12. The horizontal drive circuit 35 sequentially outputs, for example, the pixel data held in the column signal processing circuit 34 to the outside. The system control circuit 36 controls, for example, driving of each of the blocks (the vertical drive circuit 33, the column signal processing circuit 34, and the horizontal drive circuit 35) inside the logic circuit 32.

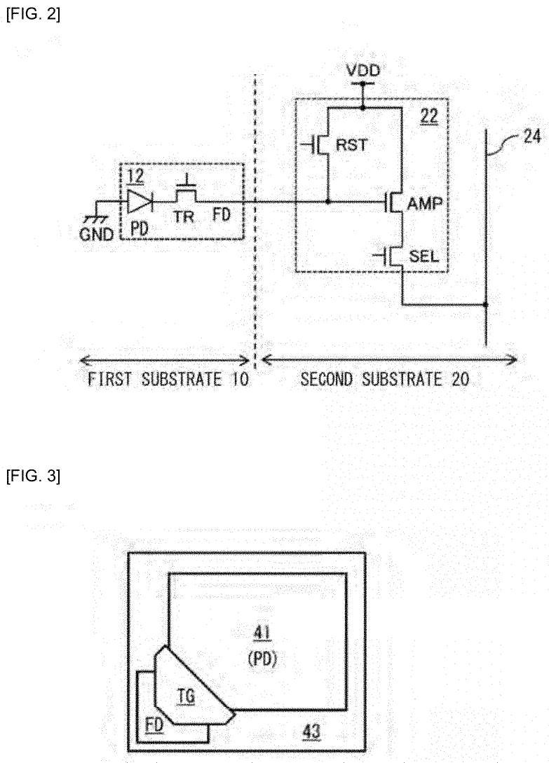

FIG. 2 illustrates an example of the sensor pixel 12 and the readout circuit 22. Hereinafter, description is given of a case where one readout circuit 22 is provided for each sensor pixel 12 as illustrated in FIG. 2.

The sensor pixel 12 includes a photodiode PD, a transfer transistor TR electrically coupled to the photodiode PD, and a floating diffusion FD that temporarily holds charges outputted from the photodiode PD via the transfer transistor TR. The photodiode PD corresponds to a specific example of a “photoelectric conversion section” of the present disclosure. The photodiode PD performs photoelectric conversion to generate charges corresponding to an amount of light reception. A cathode of the photodiode PD is coupled to a source of the transfer transistor TR, and an anode of the photodiode PD is coupled to a reference potential line (e.g., ground). A drain of the transfer transistor TR is coupled to the floating diffusion FD, and a gate of the transfer transistor TR is coupled to the pixel drive line 23. The transfer transistor TR is, for example, an NMOS (Metal Oxide Semiconductor) transistor.

In each sensor pixel 12, the floating diffusion FD is coupled to an input end of a corresponding readout circuit 22. The readout circuit 22 includes, for example, a reset transistor RST, a selection transistor SEL, and an amplification transistor AMP. A source of the reset transistor RST (an input end of the readout circuit 22) is coupled to the floating diffusion FD, and a drain of the reset transistor RST is coupled to a power source line VDD and a drain of the amplification transistor AMP. A gate of the reset transistor RST is coupled to the pixel drive line 23. A source of the amplification transistor AMP is coupled to a drain of the selection transistor SEL, and a gate of the amplification transistor AMP is coupled to the source of the reset transistor RST. A source of the selection transistor SEL (an output end of the readout circuit 22) is coupled to the vertical signal line 24, and a gate of the selection transistor SEL is coupled to the pixel drive line 23.

When the transfer transistor TR is brought into an ON state, the transfer transistor TR transfers charges of the photodiode PD to the floating diffusion PD. The gate (a transfer gate TG) of the transfer transistor TR extends to penetrate a p-well layer 42 (described later) from a top surface of the semiconductor substrate 11 to such a depth as to reach a PD (Photo Diode) 41, for example. The PD 41 corresponds to a specific example of the photodiode PD described above. The reset transistor RST resets an electric potential of the floating diffusion FD to a predetermined electric potential. When the reset transistor RST is brought into an ON state, the electric potential of the floating diffusion FD is reset to an electric potential of the power source line VDD. The selection transistor SEL controls an output timing of the pixel signal from the readout circuit 22. The amplification transistor AMP generates, as a pixel signal, a signal of a voltage corresponding to a level of charges held in the floating diffusion FD. The amplification transistor AMP configures a source-follower type amplifier, and output a pixel signal of a voltage corresponding to a level of charges generated in the photodiode PD. When the selection transistor SEL is brought into an ON state, the amplification transistor AMP amplifies an electric potential of the floating diffusion FD, and outputs a voltage corresponding to the electric potential to the column signal processing circuit 34 via the vertical signal line 24. The reset transistor RST, the amplification transistor AMP, and the selection transistor SEL are each, for example, an NMOS transistor.

It is to be noted that selection transistor SEL may be provided between the power source line VDD and the amplification transistor AMP. In this case, the drain of the reset transistor RST is coupled to the power source line VDD and the drain of the selection transistor SEL. The source of the selection transistor SEL is coupled to the drain of the amplification transistor AMP, and the gate of the selection transistor SEL is coupled to the pixel drive line 23. The source of the amplification transistor AMP (output end of the readout circuit 22) is coupled to the vertical signal line 24, and the gate of the amplification transistor AMP is coupled to the source of the reset transistor RST.

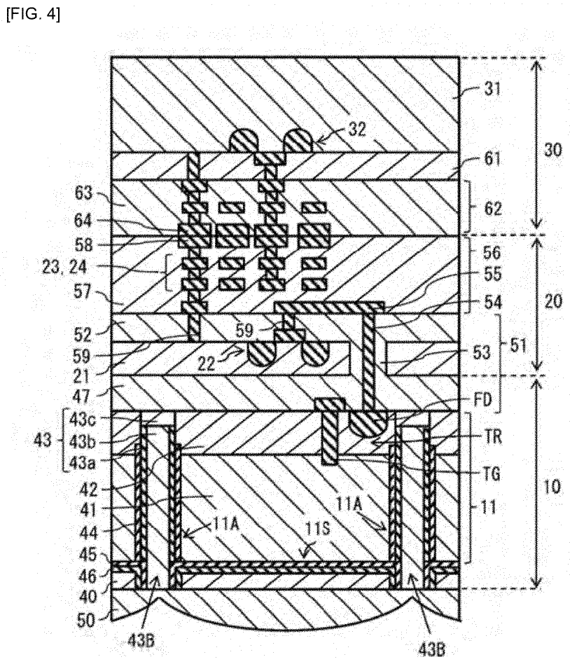

FIG. 3 illustrates an example of a cross-sectional configuration in a horizontal direction of the sensor pixel 12. FIG. 4 illustrates an example of a cross-sectional configuration in a vertical direction of the imaging device 1. FIG. 4 exemplifies a cross-sectional configuration of a location, of the imaging device 1, facing the sensor pixel 12. The imaging device 1 has a configuration in which the first substrate 10, the second substrate 20, and the third substrate 30 are stacked in this order, and further includes, on side of a back surface of the first substrate 10, a plurality of color filters 40 and a plurality of light-receiving lenses 50. The plurality of color filters 40 and the plurality of light-receiving lenses 50 are provided one by one for the respective PDs 41, for example, and are each provided at a position opposed to the PD 41. That is, the imaging device 1 is an imaging device of a backside illumination type. The sensor pixel 12 includes, for example, the PD 41, the transfer transistor TR, the floating diffusion FD, and the color filter 40.

The first substrate 10 has a configuration in which an insulating layer 47 is stacked on the semiconductor substrate 11. The first substrate 10 includes, as a portion of an interlayer insulating film 51, the insulating layer 47. The insulating layer 47 is provided in a gap between the semiconductor substrate 11 and the semiconductor substrate 21 described later. The semiconductor substrate 11 is configured by a silicon substrate. The semiconductor substrate 11 includes a p-well layer 42 at a portion of the top surface and a vicinity thereof, and includes the PD 41 of an electric conductivity type different from that of the p-well layer 42 at a deeper region than the p-well layer 42. The p-well layer 42 is provided on side of a surface opposite to a light-receiving surface 11S of the semiconductor substrate 11. The electric conductivity type of the p-well layer 42 is p-type. The electric conductivity type of the PD 41 is an electric conductivity type different from that of the p-well layer 42, and is n-type. The semiconductor substrate 11 includes, inside the p-well layer 42, the floating diffusion FD of an electric conductivity type different from that of the p-well layer 42.

The first substrate 10 includes the photodiode PD, the transfer transistor TR, and the floating diffusion FD for each sensor pixel 12. The first substrate 10 has a configuration in which the photodiode PD, the transfer transistor TR and the floating diffusion FD are provided on the top surface of the semiconductor substrate 11. The first substrate 10 includes an element separation section 43 that separates the sensor pixels 12 from each other. The element separation section 43 is formed to extend in a normal direction (thickness direction) of the semiconductor substrate 11. The element separation section 43 extends from between two PDs 41 adjacent to each other to between two color filters 40 adjacent to each other. The element separation section 43 is provided inside a trench 11A provided in the semiconductor substrate 11, and is provided to protrude from the light-receiving surface 11S of the semiconductor substrate 11. The trench 11A is formed to extend in the normal direction (thickness direction) of the semiconductor substrate 11. The element separation section 43 electrically and optically separates the two mutually adjacent PDs 41 from each other, and optically separates the two mutually adjacent color filters 40 from each other.

The element separation section 43 and the trench 11A are formed to surround the sensor pixel 12 in a horizontal in-plane direction, and are formed to further penetrate the semiconductor substrate 11. The element separation section 43 includes a DTI (Deep Trench Isolation) structure. The DTI is the FDTI formed from side of the top surface (side of a formation surface of the floating diffusion FD) of the semiconductor substrate 11. The DTI structure is formed to extend in the normal direction (thickness direction) of the semiconductor substrate 11. The DTI structure extends from between the two mutually adjacent PDs 41 to between the two mutually adjacent color filters 40. The DTI structure is provided within the trench 11A provided in the semiconductor substrate 11, and is provided to protrude from the light-receiving surface 11S of the semiconductor substrate 11.

In the element separation section 43, the DTI is configured by an insulating film 43a in contact with an inner wall of the trench 11A provided in the semiconductor substrate 11, and a metal buried part 43b provided inside the insulating film 43a. The insulating film 43a is, for example, an oxide film formed by thermally oxidizing the semiconductor substrate 11, and is formed by silicon oxide, for example. The metal buried part 43b is formed by utilizing, for example, a substitution phenomenon through heat treatment, and is formed by aluminum or an aluminum alloy, for example. The metal buried part 43b is collectively formed by utilizing, for example, a substitution phenomenon through heat treatment.

The element separation section 43 further includes an STI (Shallow Trench Isolation) 43c on the DTI. The STI 43c is formed by, for example, filling the trench 11A provided in the semiconductor substrate 11 with SiO₂ by means of CVD (Chemical Vapor Deposition) or the like. The first substrate 10 further includes, for example, a p-type solid-phase diffusion layer 44 in contact with a surface, of the element separation section 43, on side of the PD 41. The electric conductivity type of the p-type solid-phase diffusion layer 44 is an electric conductivity type different from that of the PD 41, and is p-type. The p-type solid-phase diffusion layer 44 is in contact with the p-well layer 42, and is electrically conducted to the p-well layer 42. The p-type solid-phase diffusion layer 44 is formed by diffusing p-type impurities from an inner surface of the trench 11A provided in the semiconductor substrate 11, and reduces mixing of a dark current into the PD 41.

The first substrate 10 further includes, for example, a fixed-charge film 45 in contact with a back surface (light-receiving surface 11S) of the semiconductor substrate 11. In order to suppress occurrence of a dark current due to an interface state of the light-receiving surface 11S of the semiconductor substrate 11, the fixed-charge film 45 has negative fixed charges. The fixed-charge film 45 is formed by, for example, an insulating film having negative fixed charges. Examples of a material of such an insulating film include hafnium oxide, zirconium oxide, aluminum oxide, titanium oxide, and tantalum oxide. An electric field induced by the fixed-charge film 45 forms a hole accumulation layer at the light-receiving surface 115. This hole accumulation layer suppresses generation of electrons from the light-receiving surface 115. The first substrate 10 further includes, for example, an antireflection film 46 on side of the back surface of the semiconductor substrate 11. The antireflection film 46 is formed in contact with the fixed-charge film 45, for example. The antireflection film 46 suppresses reflections of light incident on the PD 41, and efficiently allows light to reach the PD 41. The antireflection film 46 includes, for example, at least one of silicon oxide, silicon nitride, aluminum oxide, hafnium oxide, zirconium oxide, tantalum oxide, or titanium oxide.

The color filter 40 is provided on the side of the back surface (light-receiving surface 115) of the semiconductor substrate 11. The color filter 40 is formed in contact with the antireflection film 46, for example, and is provided at a position opposed to the PD 41, with the fixed-charge film 45 and the antireflection film 46 interposed therebetween. The light-receiving lens 50 is provided in contact with the color filter 40, for example, and is provided at a position opposed to the PD 41, with the color filter 40, the fixed-charge film 45 and the antireflection film 46 interposed therebetween. Here, the element separation section 43 is formed to penetrate the semiconductor substrate 11, and is formed further in contact with the light-receiving lens 50. The element separation section 43 is formed to allow a protrusion 43B, of the element separation section 43, protruding from the back surface (light-receiving surface 115) of the semiconductor substrate 11 to be in contact with the light-receiving lens 50. Accordingly, the element separation section 43 is formed to extend from between the two adjacent PDs 41 to between the two adjacent color filters 40. That is, the element separation section 43 (specifically, the DTI) not only separates the two mutually adjacent PDs 41, but also separates a gap between the PD 41 and the color filter 40.

The second substrate 20 has a configuration in which an insulating layer 52 is stacked on the semiconductor substrate 21. The second substrate 20 includes, as a portion of the interlayer insulating film 51, the insulating layer 52. The insulating layer 52 is provided in a gap between the semiconductor substrate 21 and the semiconductor substrate 31. The semiconductor substrate 21 is configured by a silicon substrate. The second substrate 20 includes one readout circuit 22 for one sensor pixel 12. The second substrate 20 has a configuration in which the readout circuit 22 is provided on a top surface of the semiconductor substrate 21. The second substrate 20 is attached to the first substrate 10, with a back surface of the semiconductor substrate 21 being opposed to side of the top surface of the semiconductor substrate 11. That is, the second substrate 20 is attached to the first substrate 10 in a face-to-back manner. The second substrate 20 further includes an insulating layer 53 that penetrates the semiconductor substrate 21, in the same layer as the semiconductor substrate 21. The second substrate 20 includes, as a portion of the interlayer insulating film 51, the insulating layer 53. The insulating layer 53 is provided to cover a side surface of a through-wiring line 54 described later.

A stacked body including the first substrate 10 and the second substrate 20 includes the interlayer insulating film 51 and the through-wiring line 54 provided inside the interlayer insulating film 51. The stacked body includes one through-wiring line 54 for each sensor pixel 12. The through-wiring line 54 extends in a normal direction of the semiconductor substrate 21, and is provided to penetrate a location, of the interlayer insulating film 51, including the insulating layer 53. The first substrate 10 and the second substrate 20 are electrically coupled to each other by the through-wiring line 54. Specifically, the through-wiring line 54 is coupled to the floating diffusion FD and a coupling wiring line 55 described later.

The stacked body including the first substrate 10 and the second substrate 20 further includes, inside the interlayer insulating film 51, two through-wiring lines (unillustrated) for each sensor pixel 12. The two through-wiring lines each extend in the normal direction of the semiconductor substrate 21, and is provided to penetrate a location, of the interlayer insulating film 51, including the insulating layer 53. The first substrate 10 and the second substrate 20 are electrically coupled to each other by the two through-wiring lines. Specifically, one through-wiring line is coupled to the p-well 42 of the semiconductor substrate 11 and to a wiring line inside the second substrate 20. The other through-wiring line is electrically coupled to the transfer gate TG and to the pixel drive line 23.

The second substrate 20 includes, for example, inside the insulating layer 52, a plurality of coupling sections 59 coupled to the readout circuit 22 and the semiconductor substrate 21. The second substrate 20 further includes, for example, a wiring layer 56 on the insulating layer 52. The wiring layer 56 includes, for example, an insulating layer 57, and the plurality of pixel drive lines 23 and the plurality of vertical signal lines 24 provided inside the insulating layer 57. The wiring layer 56 further includes, for example, a plurality of coupling wiring lines 55 provided one by one for the respective sensor pixels 12. The coupling wiring line 55 couples the coupling section 59 and the through-wiring line 54 to each other.

The wiring layer 56 further includes, for example, a plurality of pad electrodes 58 inside the insulating layer 57. Each of the pad electrodes 58 is formed by Cu (copper), for example. Each of the pad electrodes 58 is exposed to a top surface of the wiring layer 56. Each of the pad electrodes 58 is used for electric coupling between the second substrate 20 and the third substrate 30 as well as for attaching the second substrate 20 and the third substrate 30 together. The plurality of pad electrodes 58 are provided one by one for the respective pixel drive lines 23 and the respective vertical signal lines 24, for example.

The third substrate 30 has a configuration in which an interlayer insulating film 61 is stacked on the semiconductor substrate 31, for example. The semiconductor substrate 31 is configured by a silicon substrate. The third substrate 30 has a configuration in which the logic circuit 32 is provided on a top surface of the semiconductor substrate 31. The third substrate 30 further includes, for example, a wiring layer 62 on the interlayer insulating film 61. The wiring layer 62 includes, for example, an insulating layer 63 and a plurality of pad electrodes 64 provided inside the insulating layer 63. The plurality of pad electrodes 64 is electrically coupled to the logic circuit 32. Each of the pad electrodes 64 is formed by Cu (copper), for example. Each of the pad electrodes 64 is exposed to a top surface of the wiring layer 62. Each of the pad electrodes 64 is used for electric coupling between the second substrate 20 and the third substrate 30 as well as for attaching the second substrate 20 and the third substrate 30 together. The second substrate 20 and the third substrate 30 are electrically coupled to each other by junctions between the pad electrodes 58 and 64. That is, the gate (transfer gate TG) of the transfer transistor TR is electrically coupled to the logic circuit 32 via the through-wiring line 54 and the pad electrodes 58 and 64. The third substrate 30 is attached to the second substrate 20, with the top surface of the semiconductor substrate 31 being opposed to side of the top surface of the semiconductor substrate 21. That is, the third substrate 30 is attached to the second substrate 20 in a face-to-face manner.

As illustrated in FIG. 4, a structure that electrically couples the first substrate 10 and the second substrate 20 to each other is the through-wiring line 54. In addition, as illustrated in FIG. 4, a structure that electrically couples the second substrate 20 and the third substrate 30 to each other is the junctions between the pad electrodes 58 and 64. Here, the through-wiring line 54 has a width that is narrower than a width of a junction part between the pad electrodes 58 and 64. That is, the through-wiring line 54 has a cross-sectional area that is smaller than a cross-sectional area of the junction part between the pad electrodes 58 and 64. Accordingly, the through-wiring line 54 does not interfere with higher integration of the sensor pixels 12 inside the first substrate 10. In addition, the readout circuit 22 is formed in the second substrate 20, and the logic circuit 32 is formed in the third substrate 30, thus making it possible to form the structure for electrically coupling the second substrate 20 and the third substrate 30 to each other, to have a lower density than the structure for electrically coupling the first substrate 10 and the second substrate 20 to each other. Thus, it is possible to use the junction between the pad electrodes 58 and 64, as the structure for electrically coupling the second substrate 20 and the third substrate 30 to each other.

### [Manufacturing Method]

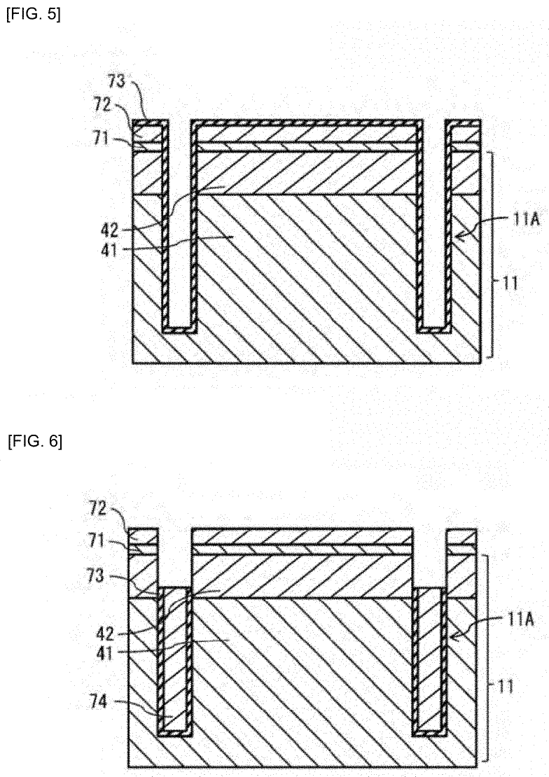

Next, description is given of a manufacturing method of the imaging device 1. FIGS. 5 to 22 each illustrate an example of a manufacturing process of the imaging device 1.

First, the p-well layer 42 is formed at an upper part of the semiconductor substrate 11. Next, an SiO₂ film 71 and an SiN film 72 are sequentially deposited on a front surface of the semiconductor substrate 11. Subsequently, a mask of a predetermined pattern is formed on the SiN film 72, and thereafter dry etching is used to selectively remove the SiN film 72, the SiO₂ film 71 and the semiconductor substrate 11. This allows for formation of the trench 11A for element separation, in the semiconductor substrate 11 (FIG. 5). Thereafter, the mask is removed. Subsequently, a silicate glass BSG film 73 containing boron is deposited on the entire surface including the trench 11A to have a film thickness in a degree not to fill the trench 11A (FIG. 5).

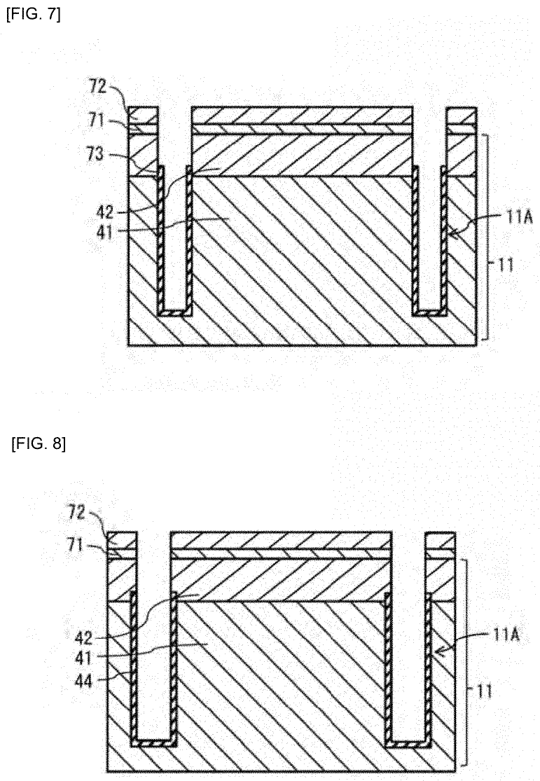

Next, a resist is applied to remove a front surface part of the applied resist. This allows for formation of a resist layer 74 at a predetermined depth inside the trench 11A (FIG. 6). Subsequently, an exposed part of the silicate glass BSG film 73 is selectively removed using the resist layer 74 as a mask. This leaves the silicate glass BSG film 73 only at the predetermined depth inside the trench 11A (FIG. 6)

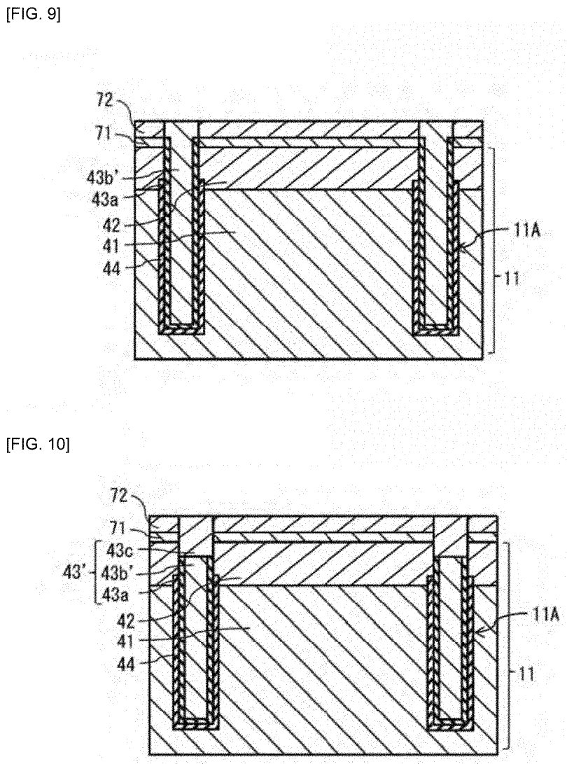

Next, the resist layer 74 inside the trench 11A is removed (FIG. 7). Subsequently, boron contained in the silicate glass BSG film 73 is diffused into the semiconductor substrate 11 through heat treatment at a high temperature to form the p-type solid-phase diffusion layer 44 to serve as a sidewall passivation in a self-aligned manner with the DTI (FIG. 8). Next, the inner wall of the trench 11A is thermally oxidized to thereby form the insulating film 43a to be in contact with the inner wall of the trench 11A. Further, a polysilicon part 43W is formed to fill the trench 11A, and thereafter surface polishing by CMP (Chemical Mechanical Polishing) is performed to remove a front surface part of the polysilicon part 43W (FIG. 9). In this manner, the DTI is formed inside the trench 11A.

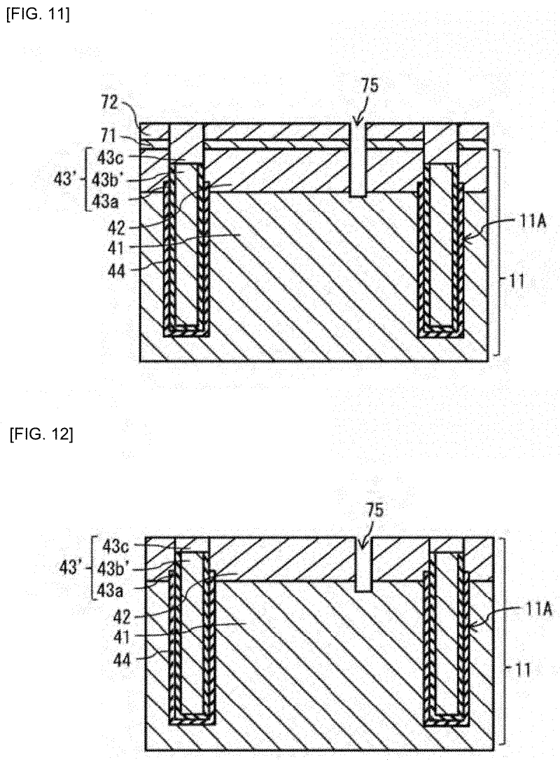

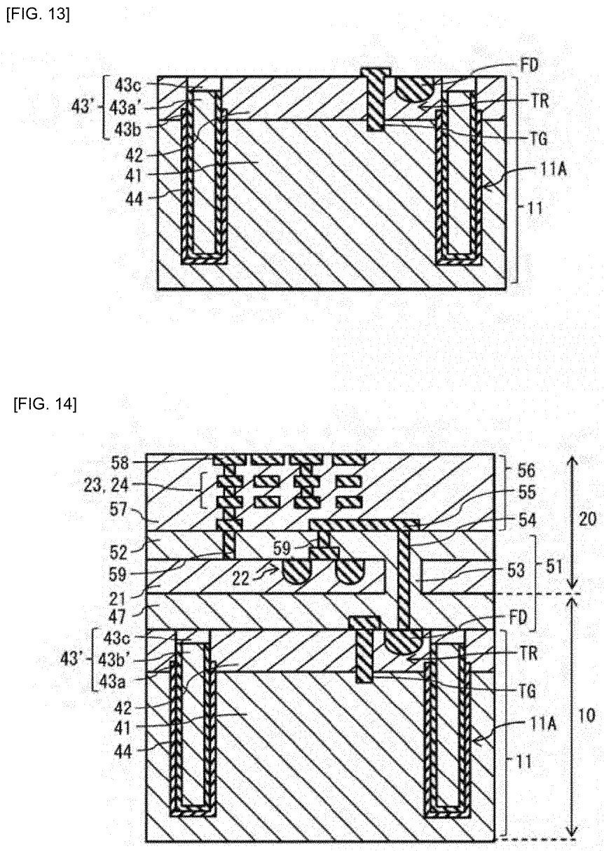

Next, an upper part of the DTI is etched, and an insulating material is deposited inside a trench formed by the etching to thereby form the STI 43c (FIG. 10). Further, a trench 75 is formed at a predetermined location of the semiconductor substrate 11 (FIG. 11). Subsequently, the SiO₂ film 71 and the SiN film 72 are removed (FIG. 12). Thereafter, a gate oxide film (unillustrated) is formed on an inner wall of the trench 75, and thereafter the transfer gate TG including polysilicon is formed inside the trench 75 (FIG. 13). Further, the floating diffusion FD is formed at a predetermined location of the semiconductor substrate 11 (FIG. 13). Thereafter, the insulating layer 47 is formed (FIG. 14). In this manner, the first substrate 10 is formed.

Next, the semiconductor substrate 21 is attached onto the first substrate 10 (insulating layer 47) (FIG. 14). At this time, the semiconductor substrate 21 is thinned as necessary. On this occasion, the thickness of the semiconductor substrate 21 is set to a film thickness necessary for formation of the readout circuit 22. The thickness of the semiconductor substrate 21 is typically about several hundred nm. However, an 1-1) (Fully Depletion) type is also available depending on the concept of the readout circuit 22; in such a case, a range from several nm to several μm may be employed as the thickness of the semiconductor substrate 21.

Next, the insulating layer 53 is formed inside the same layer as the semiconductor substrate 21 (FIG. 14). The insulating layer 53 is formed, for example, at a location facing the floating diffusion FD. For example, a slit penetrating the semiconductor substrate 21 is formed in the semiconductor substrate 21 to separate the semiconductor substrate 21 into a plurality of blocks. Thereafter, the insulating layer 53 is formed to fill the slit. Thereafter, the readout circuit 22 including the amplification transistor AMP, and the like is formed in each of the blocks of the semiconductor substrate 21 (FIG. 14). At this time, in a case where polysilicon having high heat resistance is used as an electrode material of the sensor pixel 12, it is possible to form a gate insulating film of the readout circuit 22 by thermal oxidation.

Next, the insulating layer 52 is formed on the semiconductor substrate 21. In this manner, the interlayer insulating film 51 including the insulating layers 47, 52, and 53 is formed. Subsequently, a through-hole is formed in the interlayer insulating film 51. Specifically, a through-hole penetrating the insulating layer 52 is formed at a location, of the insulating layer 52, facing the readout circuit 22. In addition, a through-hole penetrating the interlayer insulating film 51 is formed at a location, of the interlayer insulating film 51, facing the floating diffusion FD (i.e., a location facing the insulating layer 53).

Next, filling an electrically-conductive material in the through-holes described above allows for formation of the through-wiring line 54 as well as formation of the coupling section 59 (FIG. 14). Further, the coupling wiring line 55 electrically coupling the through-wiring line 54 and the coupling section 59 to each other is formed on the insulating layer 52 (FIG. 14). Thereafter, the wiring layer 56 including the pad electrode 58 is formed on the insulating layer 52. In this manner, the second substrate 20 is formed.

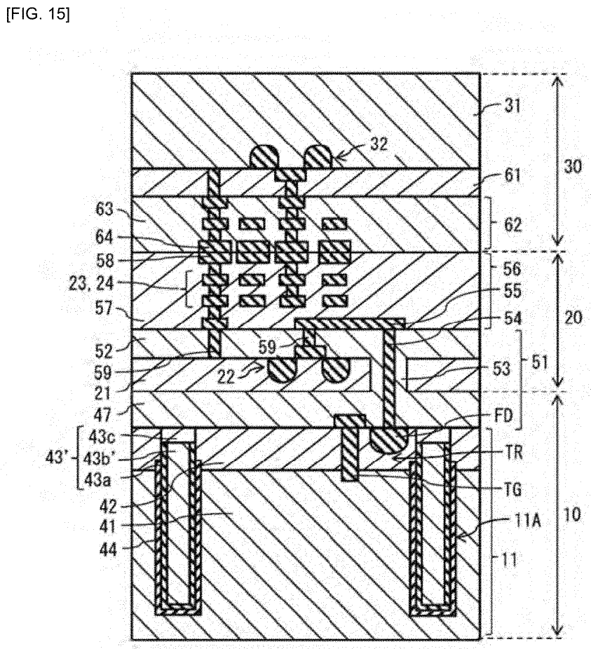

Next, the third substrate 30 is attached to the second substrate 20, with the wiring layer 62 facing side of the second substrate 20 (FIG. 15). At this time, the pad electrode 58 of the second substrate 20 and the pad electrode 64 of the third substrate 30 are bonded to each other, thereby electrically coupling the second substrate 20 and the third substrate 30 to each other.

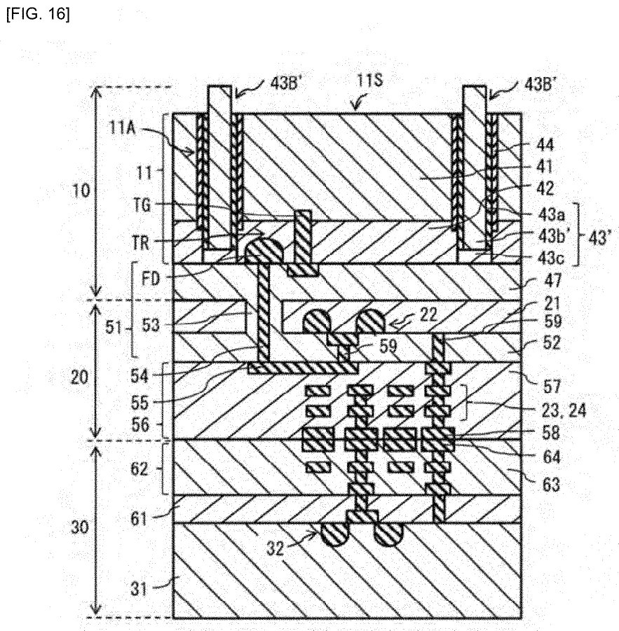

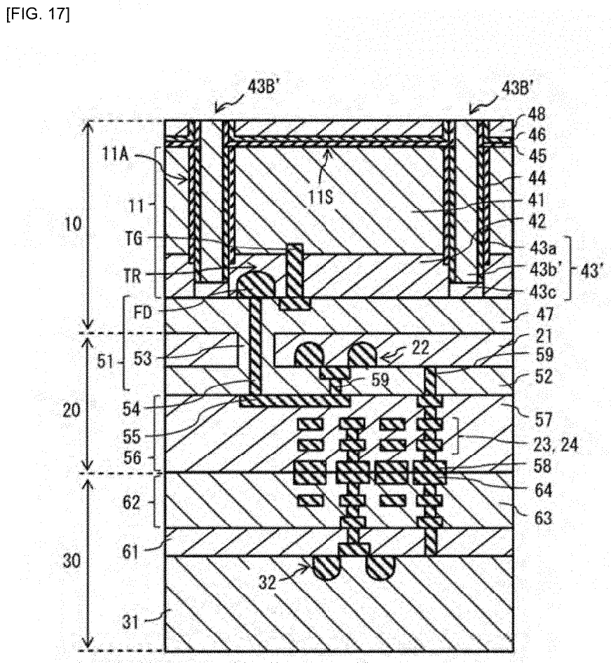

Next, a back surface of the semiconductor substrate 11 is ground using BSG, CMP, or the like to thin the semiconductor substrate 11. Next, partially etching the semiconductor substrate 11 to thereby cause a portion of the polysilicon part 43b′ to protrude from the back surface of the semiconductor substrate 11 (FIG. 16). Hereinafter, a part, of the polysilicon part 43b′, protruding from the back surface of the semiconductor substrate 11 is referred to as a protrusion 43B′. In addition, a region, of the back surface of the semiconductor substrate 11, surrounded by the protrusion 43B′ is referred to as the light-receiving surface 11S. The light-receiving surface 11S corresponds to a bottom surface of a recessed part formed by the protrusion 43B′. Subsequently, the fixed-charge film 45, the antireflection film 46, and an insulating layer 48 are formed in the recessed part surrounded by the protrusion 43B′ (FIG. 17). The insulating layer 48 may be formed by depositing SiO₂ by plasma CVD, for example.

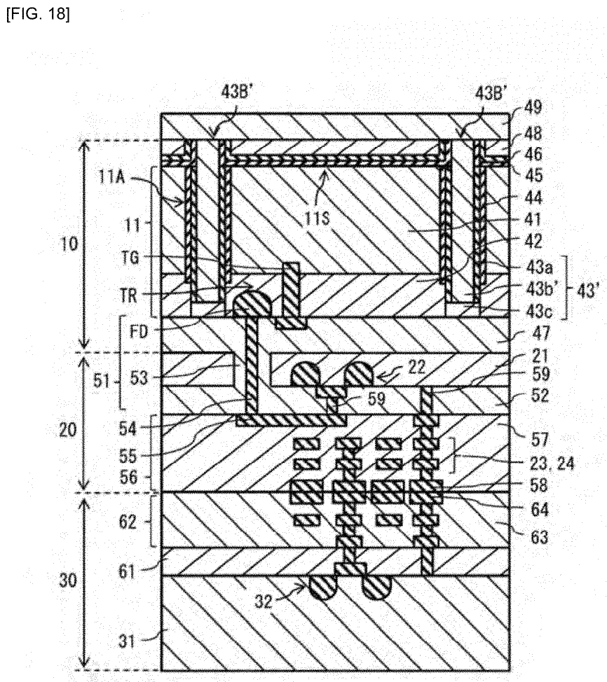

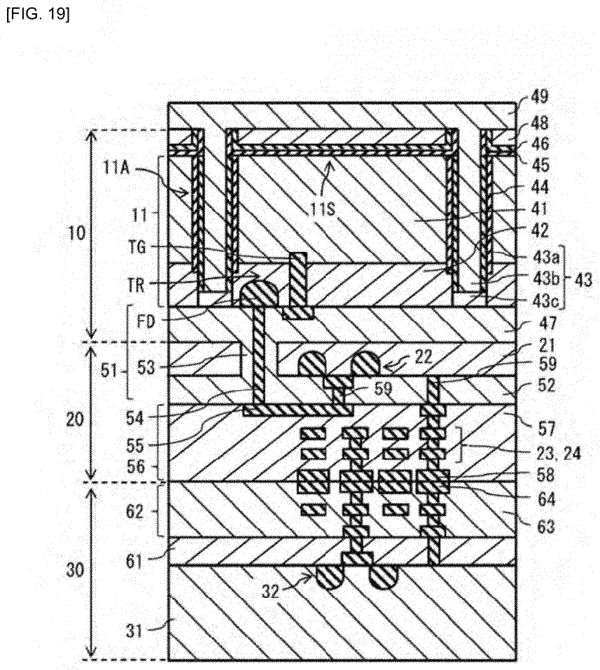

Next, for example, a sputtering method is used to form an aluminum layer 49 to be in contact with the protrusion 43B′ (FIG. 18). Subsequently, a substitution phenomenon through heat treatment is utilized to substitute the polysilicon with aluminum. This allows for substitution of the polysilicon part 43b′ inside the trench 11A with the metal buried part 43b (FIG. 19). This substitution phenomenon is described, for example, in Japanese Unexamined Patent Application Publication No. H10-125677. It is to be noted that an aluminum alloy layer may be formed in place of the aluminum layer 49. At this time, the substitution phenomenon through heat treatment is utilized to be able to substitute the polysilicon with an aluminum alloy.

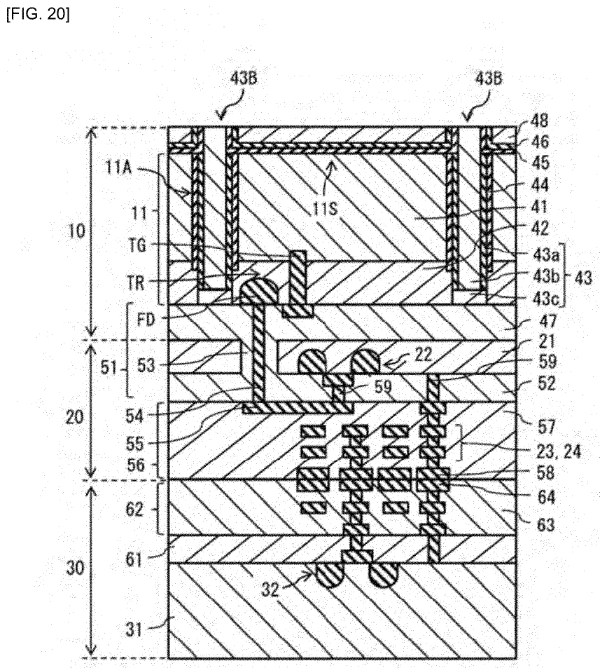

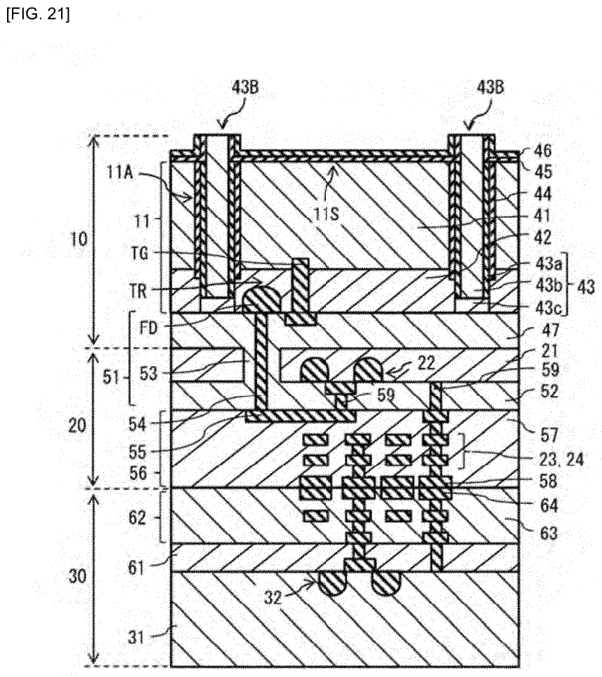

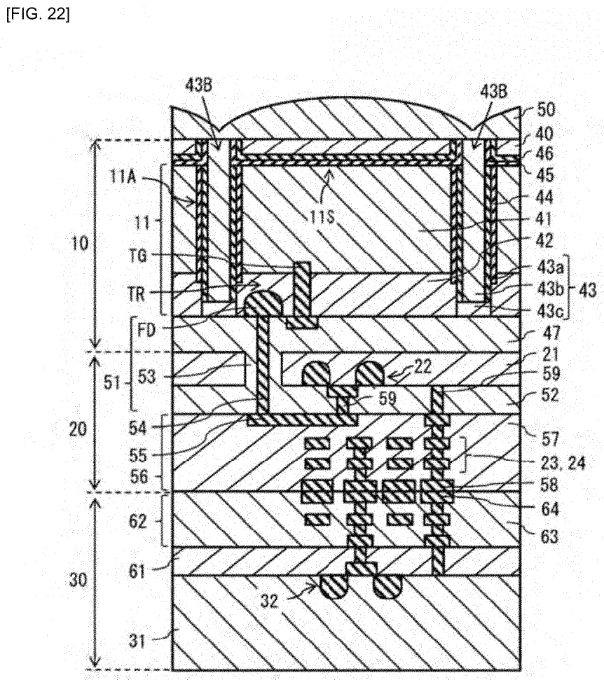

Next, the aluminum layer 49 of the front surface is removed (FIG. 20), and further the insulating layer 48 is also removed (FIG. 21). This allows an upper part of the metal buried part 43b to protrude from the back surface (light-receiving surface 11S) of the semiconductor substrate 11. A part, of the metal buried part 43b, protruding from the back surface (light-receiving surface 11S) of the semiconductor substrate 11 is the protrusion 43B described above. Subsequently, the color filter 40 is formed in the recessed part surrounded by the protrusion 43B, and thereafter the light-receiving lens 50 is formed on the color filter 40 (FIG. 22). At this time, the light-receiving lens 50 is formed to be in contact with the metal buried part 43b (specifically, the protrusion 43B). In this manner, the imaging device 1 is manufactured.

### Effects

Next, description is given of effects of the imaging device 1 according to the present embodiment.

In imaging devices, suppressing a crosstalk between pixels is an important issue. In order to suppress the crosstalk between pixels, it has heretofore been common to provide a separation structure called the DTI between pixels. For example, NPTL 1 discloses the FDTI formed from side of a top surface of a silicon wafer. In addition, for example, NPTLs 2 and 3 disclose a BDTI formed from side of a back surface of a silicon wafer.

The FDTI described in NPTL 1 is formed at an early stage of the process. For this reason, the material of the FDTI is limited to a material that is able to withstand heat treatment at a high temperature used in a process at a subsequent stage. Examples of such a material include an insulating material such as SiO or SiN, and polysilicon. Therefore, the DTI described in NPTL 1 has an issue of occurrence of deterioration of a crosstalk due to light leakage and decrease in sensitivity due to light absorption.

In addition, the BDTI described in NPTLs 2 and 3 is formed at a later stage of the process after a wiring step. For this reason, the material of the BDTI is limited to a material that is able to be formed at a temperature low enough not to adversely influence a configuration built into the silicon wafer. Therefore, the DTI described in NPTLs 2 and 3 has an issue of occurrence of a dark current and pixel degradation. The DTI described in NPTL 2 also has an issue of insufficient sensitivity due to low reflectance.

Meanwhile, in the present embodiment, the element separation section 43 is provided, extending from between the two adjacent PDs 41 to between the two adjacent color filters 40. This makes it possible to suppress light leakage through a gap between the PD 41 and the color filter 40. As a result, as compared with a case of not providing the element separation section 43, it is possible to suppress the crosstalk between the sensor pixels 12 more effectively. Further, in the present embodiment, the p-type solid-phase diffusion layer 44 is formed in contact with a surface, of the element separation section 43, on the side of the PD 41. This makes it possible to reduce the mixing of a dark current into the PD 41. Accordingly, it is possible, in the present embodiment, to suppress not only the crosstalk between the sensor pixels 12 but also the mixing of a dark current into the PD 41 more effectively.

In addition, in the present embodiment, the p-type solid-phase diffusion layer 44 and the p-well layer 42 are electrically conducted to each other. This allows an interface between the element separation section 43 and the semiconductor substrate 11 to be covered with the p-type solid-phase diffusion layer 44, thus allowing the p-type solid-phase diffusion layer 44 to be conducted to the p-well layer 42. As a result, electrons generated at the interface between the element separation section 43 and the semiconductor substrate 11 do not flow into the PD 41, thus making it possible to reduce the dark current.

In addition, in the present embodiment, the element separation section 43 is provided within the trench 11A provided in the semiconductor substrate 11, and is provided to protrude from the back surface (light-receiving surface 11S) of the semiconductor substrate 11. This enables each color filter 40 to be provided in the recessed part surrounded by the protrusion 43B of the metal buried part 43b and further enables an edge of the light-receiving lens 50 to abut the protrusion 43B of the metal buried part 43b. As a result, it is possible to suppress the light leakage through a gap between the PD 41 and the color filter 40. As a result, as compared with the case of not providing the element separation section 43, it is possible to suppress the crosstalk between the sensor pixels 12 more effectively.

In addition, in the present embodiment, the element separation section 43 has the DTI structure configured by the insulating film 43a in contact with the inner wall of the trench 11A and the metal buried part 43b formed inside the insulating film 43a. Further, the DTI structure extends from between the two adjacent PDs 41 to between the two adjacent color filters 40. This makes it possible to suppress the light leakage through a gap between the PD 41 and the color filter 40. As a result, as compared with the case of not providing the element separation section 43, it is possible to suppress the crosstalk between the sensor pixels 12 more effectively.

In addition, in the present embodiment, the metal buried part 43b is formed by aluminum or an aluminum alloy. Here, the reflectance of aluminum or an aluminum alloy to visible light is higher than the reflectance of tungsten to visible light (about 50% to 60%), and is 70% or more. This makes it possible to efficiently guide incident light to the PD 41 and to further suppress the light leakage through a gap between the PD 41 and the color filter 40. As a result, as compared with the case of not providing the element separation section 43, it is possible not only to achieve good efficiency of light incident into the PD 41, but also to suppress the crosstalk between the sensor pixels 12 more effectively.

In addition, in the present embodiment, the metal buried part 43b is collectively formed by utilizing the substitution phenomenon through heat treatment. This makes it possible to form polysilicon inside the trench 11A at an early stage of the process and to substitute polysilicon with a metal material (e.g., aluminum or an aluminum alloy) that is difficult to withstand heat treatment at a high temperature at a later stage of the process after the wiring step. As a result, even in a case where the element separation section 43 is formed by the FDTI, it is possible to use, as the metal buried part 43b, the metal material (e.g., aluminum or an aluminum alloy) that is difficult to withstand the heat treatment at a high temperature. Accordingly, as compared with the case of using the material, such as polysilicon, that is able to withstand the heat treatment at a high temperature, it is possible not only to achieve good efficiency of light incident into the PD 41, but also to suppress the crosstalk between the sensor pixels 12 more effectively.

In addition, in the present embodiment, the trench 11A and the element separation section 43 are both formed to penetrate the semiconductor substrate 11. This makes it possible to suppress the crosstalk between the sensor pixels 12 more effectively.

### 2. Modification Examples of First Embodiment

Although the description has been given above of the present disclosure by referring to the embodiment, the present disclosure is not limited to the present embodiment, and may be modified in a wide variety of ways.

### Modification Example A

For example, in the foregoing embodiment, as illustrated in FIG. 23, for example, a side surface of the protrusion 43B of the metal buried part 43b may be in direct contact with the color filter 40 without being covered with the fixed-charge film 45 and the antireflection film 46. At this time, the DTI included in the element separation section 43 is the FDTI.

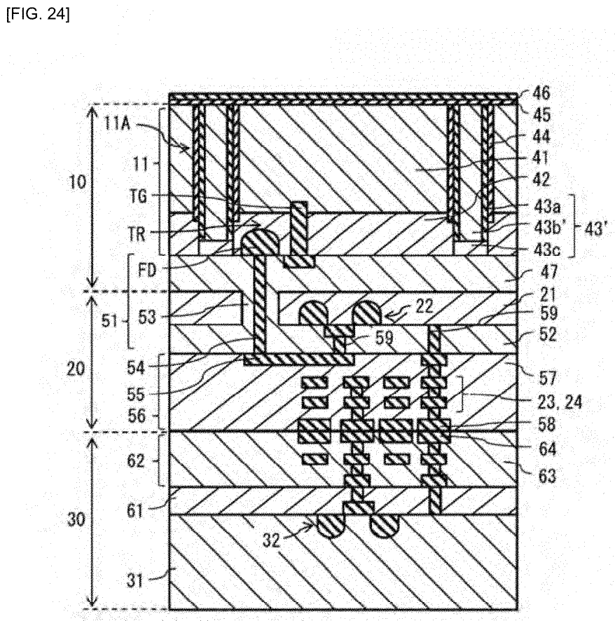

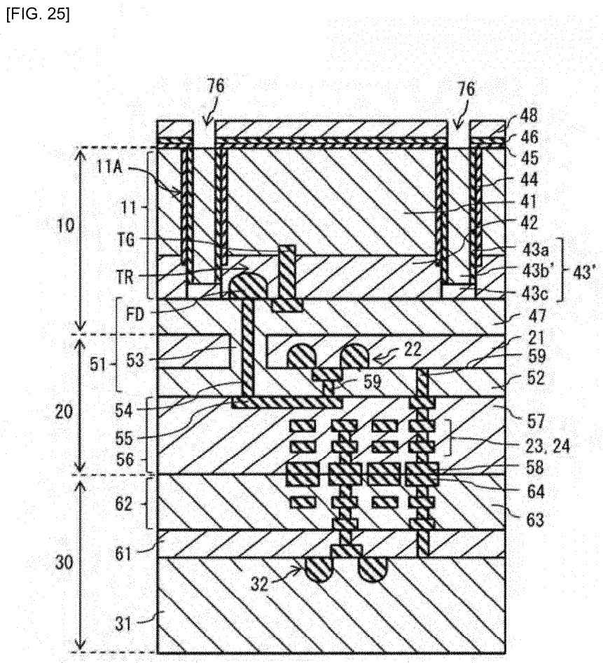

In this case, for example, in the process subsequent to FIG. 15, the back surface of the semiconductor substrate 11 is ground using BSG, CMP, or the like, and, when thinning the semiconductor substrate 11, the polysilicon part 43b′ is also ground together (FIG. 24). Next, the fixed-charge film 45 and the antireflection film 46 are sequentially formed on the back surface of the semiconductor substrate 11 (FIG. 24). Subsequently, after forming the insulating layer 48 on the antireflection film 46, a location, of the fixed-charge film 45, the antireflection film 46 and the insulating layer 48, facing the polysilicon part 43b′ is selectively etched. In this manner, a trench 76 is formed in the fixed-charge film 45, the antireflection film 46, and the insulating layer 48 (FIG. 25). At this time, the polysilicon part 43b′ is exposed to a bottom surface of the trench 76.

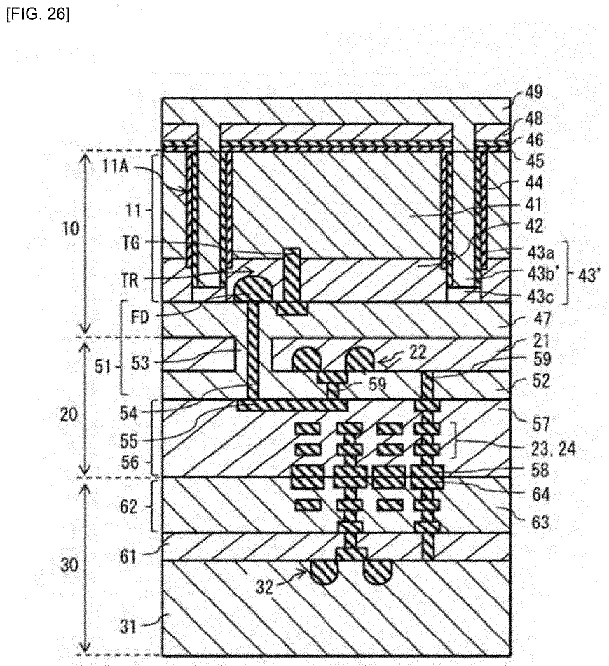

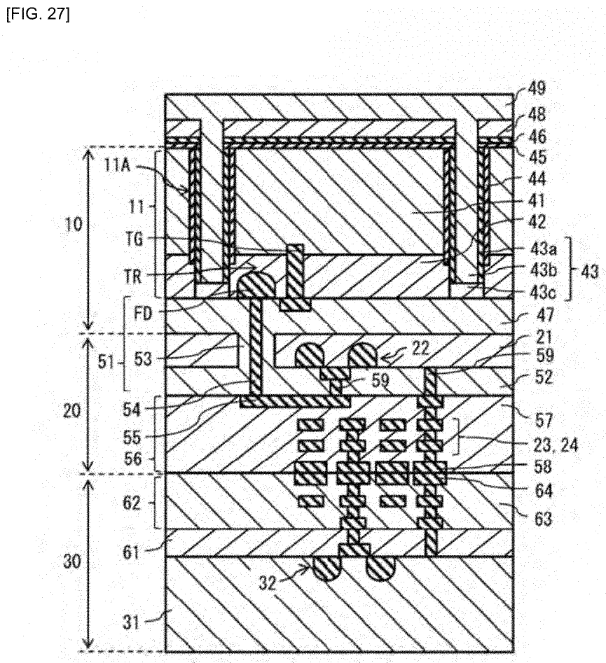

Next, for example, a sputtering method is used to form the aluminum layer 49 to be in contact with a part, of the polysilicon part 43b′, exposed to the bottom surface of the trench 76 (FIG. 26). Subsequently, the polysilicon is substituted with aluminum by utilizing a substitution phenomenon through heat treatment. This allows for substitution of the polysilicon part 43b′ inside the trench 11A with the metal buried part 43b (FIG. 27). It is to be noted that an aluminum alloy layer may be formed in place of the aluminum layer 49. At this time, polysilicon is able to be substituted with an aluminum alloy by utilizing the substitution phenomenon through heat treatment.

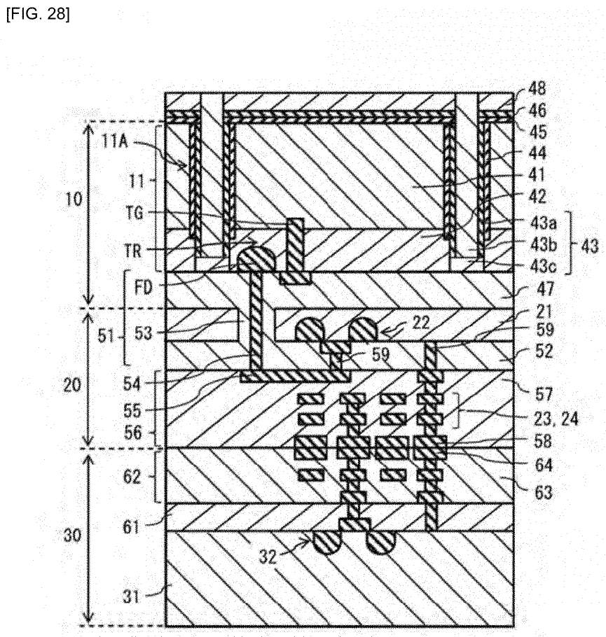

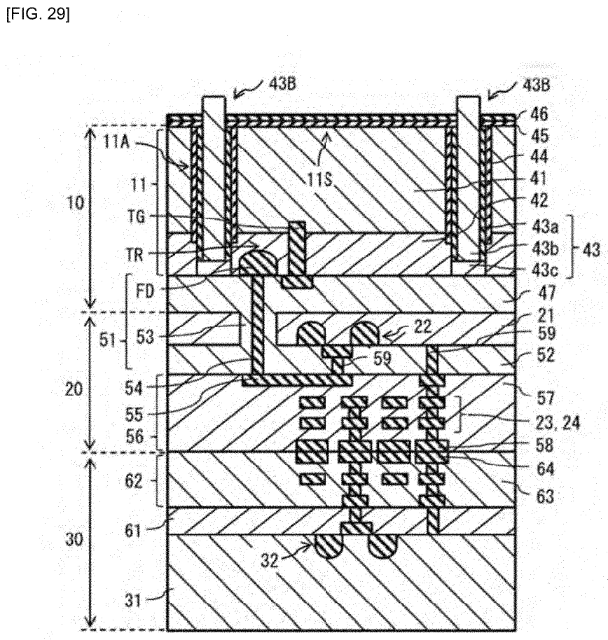

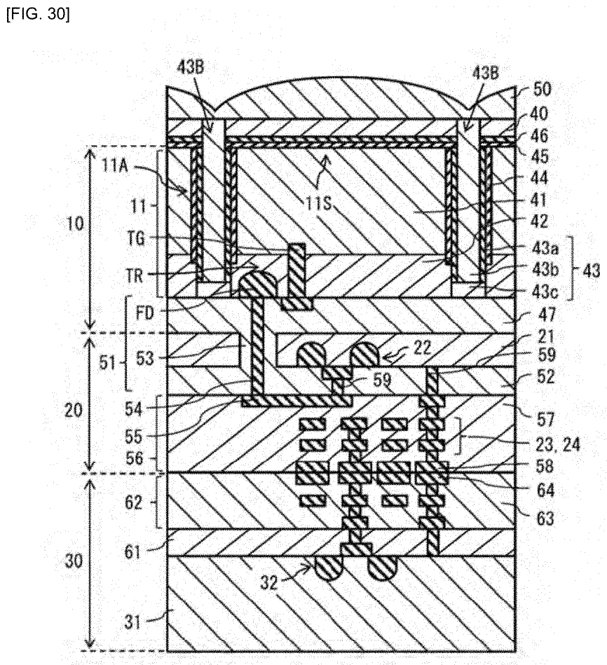

Next, a front surface of the aluminum layer 49 is removed (FIG. 28), and the insulating layer 48 is also removed (FIG. 29). This allows a portion of the metal buried part 43b to protrude from the back surface of the semiconductor substrate 11 (FIG. 29). Hereinafter, a part, of the metal buried part 43b, protruding from the back surface of the semiconductor substrate 11 is the protrusion 43B described above. In addition, a region, of the back surface of the semiconductor substrate 11, surrounded by the protrusion 43B is the light-receiving surface 11S described above. Subsequently, after forming the color filter 40 in the recessed part surrounded by the protrusion 43B of the metal buried part 43b, the light-receiving lens 50 is formed on the color filter 40 (FIG. 30). At this time, the light-receiving lens 50 is formed to be in contact with the metal buried part 43b (in particular, the protrusion 43B). In this manner, the imaging device 1 is manufactured.

In the present modification example, except for the point where the side surface of the protrusion 43B is not covered with the fixed-charge film 45 and the antireflection film 46, other configurations are common to the configurations of the foregoing embodiment. Accordingly, the present modification example achieves effects similar to those of the foregoing embodiment.

### Modification Example B

In the imaging device 1 according to the foregoing Modification Example A, for example, as illustrated in FIG. 31, an element separation section 82 may be provided in place of the element separation section 43. Here, the element separation section 82 is the BDTI formed from the side of the back surface (light-receiving surface 11S) of the semiconductor substrate 11. The element separation section 82 does not penetrate the semiconductor substrate 11, and the p-well layers 42 are electrically conducted to each other in the sensor pixels 12 adjacent to each other.

The first substrate 10 includes the element separation section 82 that separates the sensor pixels 12 from each other. The element separation section 82 is formed to extend in the normal direction (thickness direction) of the semiconductor substrate 11. The element separation section 82 extends from between the two mutually adjacent PDs 41 to between the two mutually adjacent color filters 40. The element separation section 82 is provided inside a trench 11B provided in the semiconductor substrate 11, and is provided to protrude from the light-receiving surface 11S of the semiconductor substrate 11. The trench 11B is formed to extend in the normal direction (thickness direction) of the semiconductor substrate 11. The element separation section 82 electrically and optically separates the two mutually adjacent PDs 41 from each other, and optically separates the two mutually adjacent color filters 40 from each other.

The element separation section 82 and the trench 11B are formed to surround the sensor pixel 12 in a horizontal in-plane direction. Further, the element separation section 82 and the trench 11B do not penetrate the semiconductor substrate 11, and each one end of the element separation section 82 and the trench 11B is provided inside the p-well layer 42. The element separation section 82 includes the DTI structure. The DTI is the BDTI formed from the side of the back surface (side of the light-receiving surface 11S) of the semiconductor substrate 11. The DTI structure is formed to extend in the normal direction (thickness direction) of the semiconductor substrate 11. The DTI structure extends from between the two mutually adjacent PDs 41 to between the two mutually adjacent color filters 40. The DTI structure is provided within the trench 11B provided in the semiconductor substrate 11, and is provided to protrude from the light-receiving surface 11S of the semiconductor substrate 11.

In the element separation section 82, the DTI is configured by an insulating film 82a in contact with an inner wall of the trench 11B provided in the semiconductor substrate 11, and a metal buried part 82b provided inside the insulating film 82a. The insulating film 82a is formed by, for example, an insulating film having negative fixed charges (i.e., fixed-charge film). At this time, the insulating film 82a suppresses occurrence of a dark current due to an interface state of the trench 11B of the semiconductor substrate 11. The metal buried part 82b is formed by aluminum or an aluminum alloy, for example. The metal buried part 82b is formed using CVD, for example. It is to be noted that the metal buried part 82b may be formed by utilizing the substitution phenomenon through heat treatment.

The element separation section 82 is formed in contact with the light-receiving lens 50. The element separation section 82 is formed to allow a protrusion 82B, of the element separation section 82, protruding from the back surface (light-receiving surface 11S) of the semiconductor substrate 11 to be in contact with the light-receiving lens 50. Accordingly, the element separation section 82 is formed to extend between the two mutually adjacent color filters 40. That is, the element separation section 82 (specifically, the DTI) not only separates the two mutually adjacent PDs 41, but also separates a gap between the PD 41 and the color filter 40.

Next, description is given of a manufacturing method of the imaging device 1 according to the present modification example.

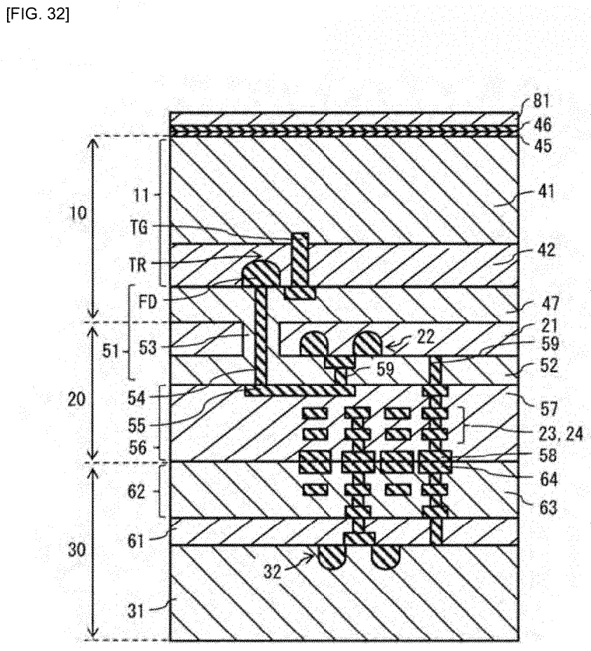

In the present modification example, the first substrate 10 is formed in the semiconductor substrate 11 without forming the trench 11, and the second substrate 20 and the third substrate 30 are formed on the first substrate 10 (FIG. 32), in the manufacturing process of the imaging device 1 according to the foregoing Modification Example A. Subsequently, the fixed-charge film 45, the antireflection film 46 and an insulating layer 81 are formed on the back surface of the semiconductor substrate 11 (FIG. 32). The insulating layer 81 may be formed, for example, by depositing SiO₂ by plasma CVD.

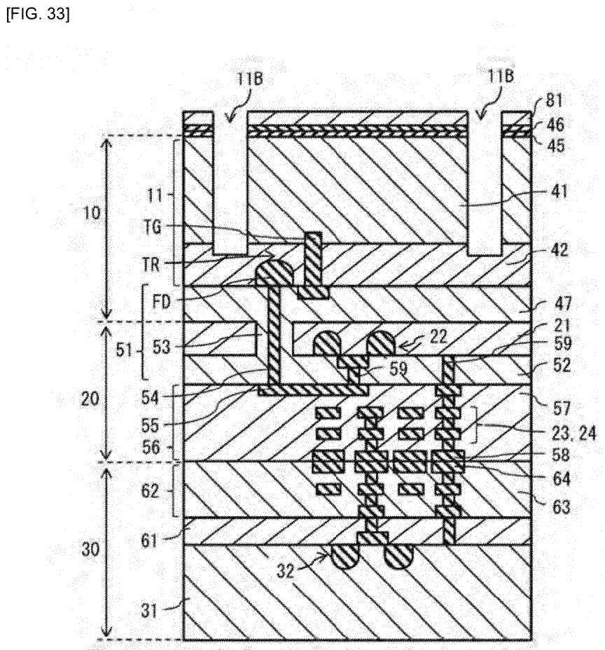

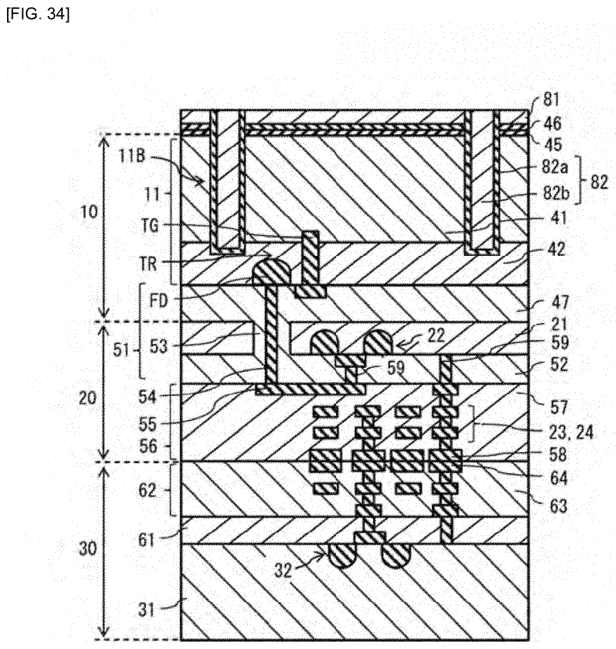

Next, after forming a mask of a predetermined pattern on the insulating layer 81, dry etching is used to selectively remove the insulating layer 81, the antireflection film 46, the fixed-charge film 45, and the semiconductor substrate 11. This allows for formation of the trench 11B for element separation, in the semiconductor substrate 11 (FIG. 33). Thereafter, the mask is removed. Subsequently, after forming the insulating film 82a on the inner wall of the trench 11B, the metal buried part 82b is formed inside the trench 11B using, for example, CVD (FIG. 34). At this time, the metal buried part 82b is configured by aluminum or an aluminum alloy, for example. It is to be noted that the metal buried part 82b may be formed inside the trench 11B using the substitution phenomenon described above.

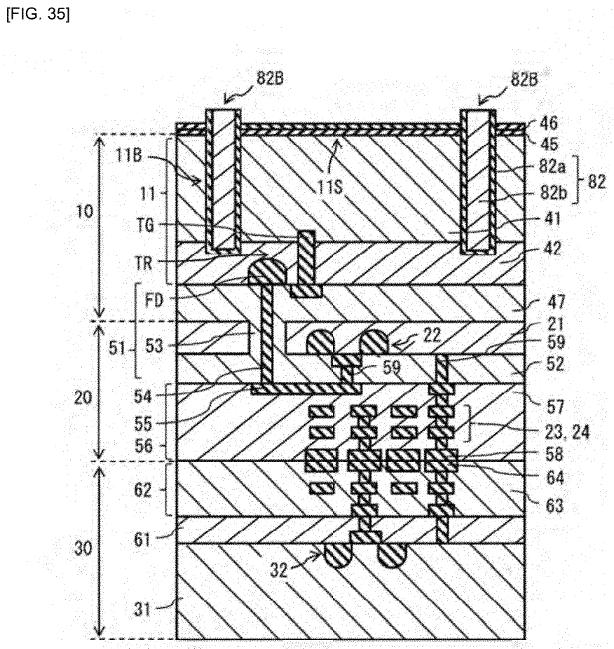

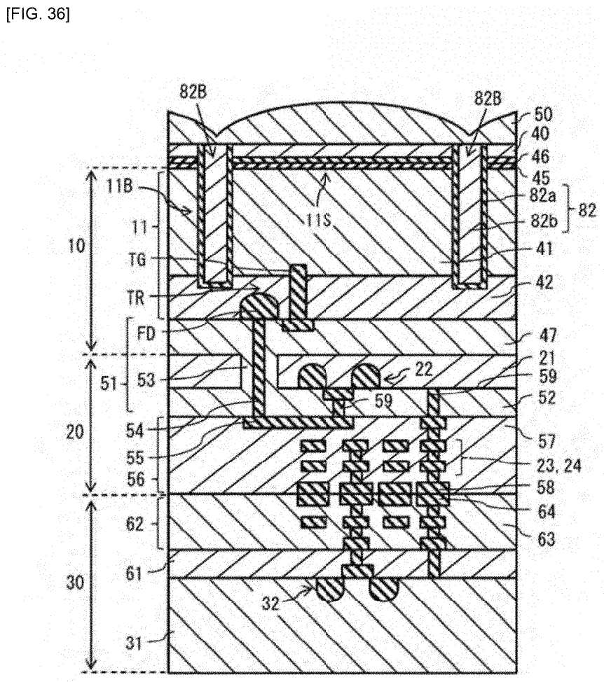

Next, the insulating layer 81 of the front surface is removed (FIG. 35). This causes a portion of the metal buried part 82b to protrude from the back surface of the semiconductor substrate 11 (FIG. 35). Hereinafter, a part, of the metal buried part 82b, protruding from the back surface of the semiconductor substrate 11 is referred to as the protrusion 82B. In addition, a region, of the back surface of the semiconductor substrate 11, surrounded by the protrusion 82B is referred to as the light-receiving surface 11S. The light-receiving surface 11S corresponds to a bottom surface of a recessed part formed by the protrusion 82B. Subsequently, after forming the color filter 40 in the recessed part surrounded by the protrusion 82B, the light-receiving lens 50 is formed on the color filter 40 (FIG. 36). At this time, the light-receiving lens 50 is formed to be in contact with the metal buried part 82b. In this manner, the imaging device 1 is manufactured.

Next, description is given of effects of the imaging device 1 according to the present modification example.

In the present modification example, the element separation section 82 is provided, extending from between the two adjacent PDs 41 to between the two adjacent color filters 40. This makes it possible to suppress the light leakage through a gap between the PD 41 and the color filter 40. As a result, as compared with the case of not providing the element separation section 82, it is possible to suppress the crosstalk between the sensor pixels 12 more effectively.

In addition, in the present modification example, the element separation section 82 is provided within the trench 11B provided in the semiconductor substrate 11, and is provided to protrude from the back surface (light-receiving surface 11S) of the semiconductor substrate 11. This enables each color filter 40 to be provided in the recessed part surrounded by the protrusion 82B of the metal buried part 82b and further enables an edge of the light-receiving lens 50 to abut the protrusion 82B of the metal buried part 82b. As a result, it is possible to suppress the light leakage through a gap between the PD 41 and the color filter 40. As a result, as compared with the case of not providing the element separation section 82, it is possible to suppress the crosstalk between the sensor pixels 12 more effectively.

In addition, in the present modification example, the element separation section 82 has the DTI structure configured by the insulating film 82a in contact with the inner wall of the trench 11B and the metal buried part 82b formed inside the insulating film 82a. Further, the DTI structure extends from between the two adjacent PDs 41 to between the two adjacent color filters 40. This makes it possible to suppress the light leakage through a gap between the PD 41 and the color filter 40. As a result, as compared with the case of not providing the element separation section 82, it is possible to suppress the crosstalk between the sensor pixels 12 more effectively.

In addition, in the present modification example, the metal buried part 82b is formed by aluminum or an aluminum alloy. Here, the reflectance of aluminum or an aluminum alloy to visible light is higher than the reflectance of tungsten to visible light (about 50% to 60%), and is 70% or more. This makes it possible to efficiently guide incident light to the PD 41 and to further suppress the light leakage through a gap between the PD 41 and the color filter 40. As a result, as compared with the case of not providing the element separation section 82, it is possible not only to achieve good efficiency of light incident into the PD 41, but also to suppress the crosstalk between the sensor pixels 12 more effectively.

### 3. Second Embodiment

FIG. 37 illustrates an example of a schematic configuration of an imaging device 2 according to a second embodiment of the present disclosure. The imaging device 2 includes two substrates (a first substrate 110 and the third substrate 30). The imaging device 2 is a three-dimensionally structured imaging device configured by attaching the two substrates (first substrate 110 and third substrate 30) together.

The first substrate 110 is a substrate including a plurality of pixels 112 on a semiconductor substrate 111. The plurality of pixels 112 are provided in matrix in a pixel region 113 in the first substrate 110. The pixel 112 includes the sensor pixel 12 and the readout circuit 22. As illustrated in FIG. 38, for example, the readout circuits 22 are provided one by one for the respective sensor pixels 12. The first substrate 110 further includes a wiring layer 114 on the semiconductor substrate 111. The wiring layer 114 includes the plurality of pixel drive lines 23 and the plurality of vertical signal lines 24. The third substrate 30 is a substrate including the logic circuit 32 on the semiconductor substrate 31. The logic circuit 32 includes, for example, the vertical drive circuit 33, the column signal processing circuit 34, the horizontal drive circuit 35, and the system control circuit 36.

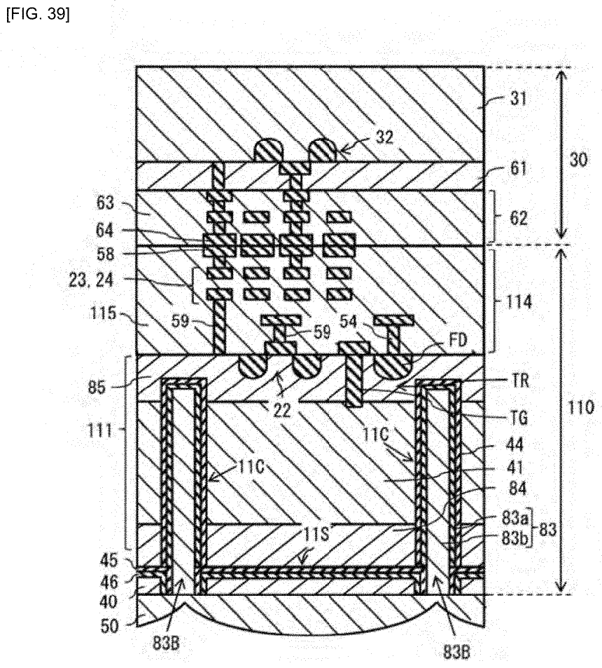

FIG. 39 illustrates an example of a cross-sectional configuration in the vertical direction of the imaging device 2. FIG. 39 exemplifies a cross-sectional configuration of a location, of the imaging device 2, facing the pixel 112. The imaging device 2 includes a stacked body in which the first substrate 110 and the third substrate 30 are stacked on each other, and further includes, on side of a back surface of the first substrate 110, the plurality of color filters 40 and the plurality of light-receiving lenses 50. The plurality of color filters 40 and the plurality of light-receiving lenses 50 are provided one by one for the respective PDs 41, for example, and are each provided at a position opposed to the PD 41. The sensor pixel 12 includes, for example, the PD 41, the transfer transistor TR, the floating diffusion FD, and the color filter 40.

The first substrate 110 has a configuration in which the wiring layer 114 is stacked on the semiconductor substrate 111. The wiring layer 114 is provided in a gap between the semiconductor substrate 111 and the third substrate 30. The semiconductor substrate 111 is configured by a silicon substrate. The semiconductor substrate 111 includes, for example, a p-well layer 85 at a portion of the top surface and a vicinity thereof, and includes the PD 41 of an electric conductivity type different from that of the p-well layer 85 at a deeper region than the p-well layer 85. The p-well layer 85 is provided on side of a surface opposite to the light-receiving surface 11S of the semiconductor substrate 111. The semiconductor substrate 111 further includes, for example, an n-type semiconductor layer 84 serving as a portion of the PD at a region deeper than the PD 41. The electric conductivity type of the p-well layer 85 is p-type. The electric conductivity type of the PD 41 is an electric conductivity type different from that of the p-well layer 85, and is n-type. The electric conductivity type of the n-type semiconductor layer 84 is n-type. The semiconductor substrate 111 includes, inside the p-well layer 85, the floating diffusion FD of an electric conductivity type different from that of the p-well layer 85.

The first substrate 110 includes the photodiode PD, the transfer transistor TR, and the floating diffusion FD for each sensor pixel 12. The first substrate 110 has a configuration in which the photodiode PD, the transfer transistor TR and the floating diffusion FD are provided on a top surface of the semiconductor substrate 111. The first substrate 110 includes an element separation section 83 that separates the sensor pixels 12 from each other. The element separation section 83 is formed to extend in a normal direction (thickness direction) of the semiconductor substrate 111. The element separation section 83 extends from between the two mutually adjacent PDs 41 to between the two mutually adjacent color filters 40. The element separation section 83 is provided inside a trench 11C provided in the semiconductor substrate 111, and is provided to protrude from the light-receiving surface 11S of the semiconductor substrate 111. The trench 11C is formed to extend in the normal direction (thickness direction) of the semiconductor substrate 111. The element separation section 83 electrically and optically separates the two mutually adjacent PDs 41 from each other, and optically separates the two mutually adjacent color filters 40 from each other.

The element separation section 83 and the trench 11C are formed to surround the sensor pixel 12 in a horizontal in-plane direction. Further, the element separation section 83 and the trench 11C do not penetrate the semiconductor substrate 111, and each one end of the element separation section 83 and the trench 11C is provided inside the p-well layer 85. The element separation section 83 includes the DTI structure. The DTI is the FDTI formed from the side of the light-receiving surface 11S of the semiconductor substrate 111. The DTI structure is formed to extend in the normal direction (thickness direction) of the semiconductor substrate 111. The DTI structure is provided to extend from between the two mutually adjacent PDs 41 to between the two mutually adjacent color filters 40. The DTI structure is provided within the trench 11C provided in the semiconductor substrate 111, and is provided to protrude from the light-receiving surface 11S of the semiconductor substrate 111.

In the element separation section 83, the DTI is configured by an insulating film 83a in contact with an inner wall of the trench 11C provided in the semiconductor substrate 111, and a metal buried part 83b provided inside the insulating film 83a. The insulating film 83a is, for example, an oxide film formed by thermally oxidizing the semiconductor substrate 111, and is formed by silicon oxide, for example. The metal buried part 83b is formed by utilizing, for example, a substitution phenomenon through heat treatment, and is formed by aluminum or an aluminum alloy, for example. The metal buried part 83b is collectively formed by utilizing, for example, the substitution phenomenon through heat treatment.

The first substrate 110 further includes, for example, the p-type solid-phase diffusion layer 44 in contact with a surface, of the element separation section 83, on the side of the PD 41. The electric conductivity type of the p-type solid-phase diffusion layer 44 is an electric conductivity type different from that of the PD 41, and is p-type. The p-type solid-phase diffusion layer 44 is in contact with the p-well layer 85, and is electrically conducted to the p-well layer 85. The p-type solid-phase diffusion layer 44 is formed by diffusing p-type impurities from an inner surface of the trench 11C provided in the semiconductor substrate 111, and reduces mixing of a dark current into the PD 41.

The first substrate 110 further includes, for example, the fixed-charge film 45 in contact with the back surface (light-receiving surface 11S) of the semiconductor substrate 111. The first substrate 110 further includes, for example, the antireflection film 46 on the side of the back surface of the semiconductor substrate 111. The color filter 40 is provided on the side of the back surface (light-receiving surface 11S) of the semiconductor substrate 111. The color filter 40 is formed in contact with the antireflection film 46, for example, and is provided at a position opposed to the PD 41, with the fixed-charge film 45 and the antireflection film 46 interposed therebetween. The light-receiving lens 50 is provided in contact with the color filter 40, for example, and is provided at a position opposed to the PD 41, with the color filter 40, the fixed-charge film 45 and the antireflection film 46 interposed therebetween.

The element separation section 83 is formed in contact with the light-receiving lens 50. The element separation section 83 is formed to allow a protrusion 83B, of the element separation section 83, protruding from the top surface (light-receiving surface 11S) of the semiconductor substrate 111 to be in contact with the light-receiving lens 50. Accordingly, the element separation section 83 is formed to extend from between the two adjacent PDs 41 to between the two adjacent color filters 40. That is, the element separation section 83 (specifically, the DTI) not only separates the two mutually adjacent PDs 41, but also separates a gap between the PD 41 and the color filter 40.

Next, description is given of a manufacturing method of the imaging device 2 according to the present embodiment.

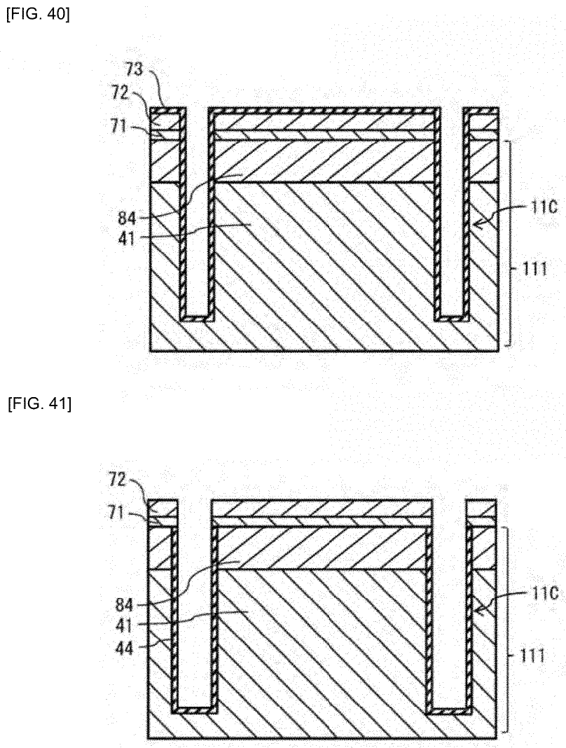

In the present embodiment, first, the n-type semiconductor layer 84 is formed at an upper part of the semiconductor substrate 111 (FIG. 40). The n-type semiconductor layer 84 is integrated with the PD 41 to form one photodiode, and serves to adjust the photodiode to a predetermined potential. In the present embodiment, the photodiode is also able to be formed either from side of a front surface of the semiconductor substrate 111, or from the side of the back surface thereof, which not only increases a degree of freedom in the manufacturing, but is also suitable for optimization of a higher performance photodiode. Next, the SiO₂ film 71 and the SiN film 72 are sequentially deposited on the front surface of the semiconductor substrate 111 (FIG. 40). Subsequently, after forming a mask of a predetermined pattern on the SiN film 72, dry etching is used to selectively remove the SiN film 72, the SiO₂ film 71, and the semiconductor substrate 111. This allows for formation of the trench 11C for element separation, in the semiconductor substrate 111 (FIG. 40). Thereafter, the mask is removed. Subsequently, the silicate glass BSG film 73 containing boron is deposited on the entire surface including the trench 11C.

Subsequently, the boron contained in the silicate glass BSG film 73 is diffused into the semiconductor substrate 111 through heat treatment at a high temperature to form the p-type solid-phase diffusion layer 44 to serve as a sidewall passivation in a self-aligned manner with the DTI (FIG. 41). Next, after removing the silicate glass BSG film 73, the inner wall of the trench 11C is thermally oxidized to thereby form the insulating film 83a in contact with the inner wall of the trench 11C. Further, a polysilicon section 83b′ is formed to fill the trench 11C, and thereafter surface polishing by CMP is performed to remove a front surface part of the polysilicon section 83W (FIG. 42). In this manner, the DTI is formed inside the trench 11C.

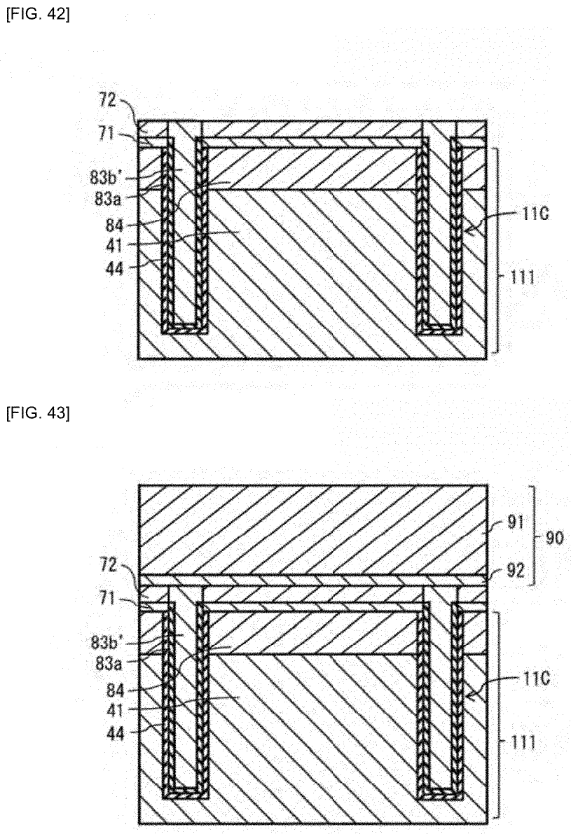

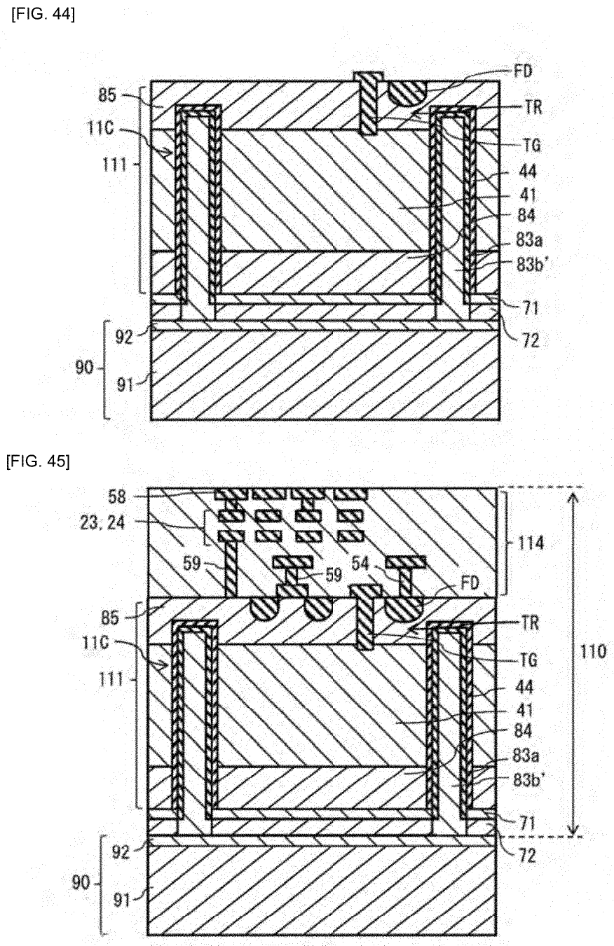

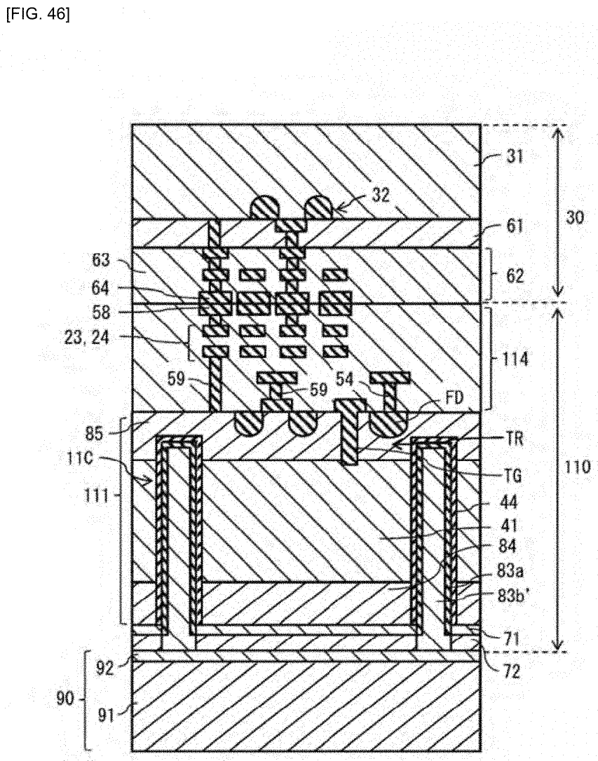

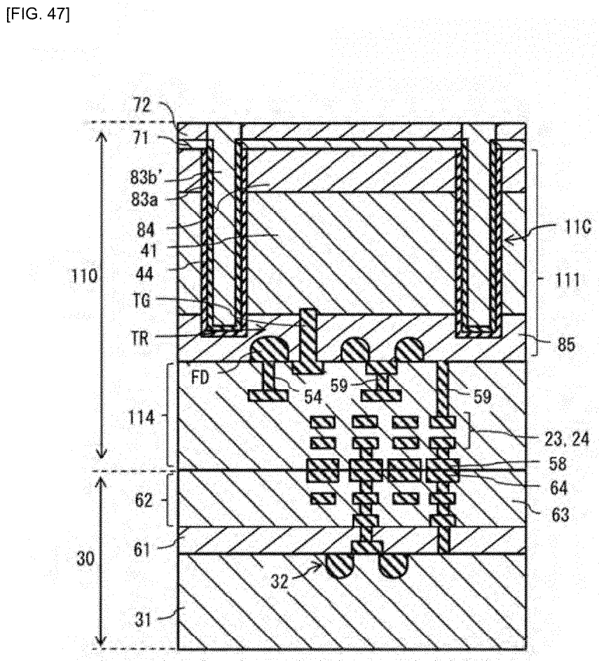

Next, a substrate 90 is attached to the front surface including the polysilicon section 83W and the SiN film 72 (FIG. 43). The substrate 90 is a substrate in which an SiO₂ film 92 is formed on a support substrate 91. Subsequently, the back surface of the semiconductor substrate 111 is ground using BSG, CMP, or the like, as necessary, to thin the semiconductor substrate 111. Subsequently, the p-well layer 85 is formed on the back surface (a surface on upper side in FIG. 44) of the semiconductor substrate 111 (FIG. 44). At this time, the p-well layer 85 is formed to electrically conduct the p-well layer 85 to the p-type solid-phase diffusion layer 44. Subsequently, the transfer gate TG and the floating diffusion FD are formed at predetermined locations of the p-well layer 85 (FIG. 44). Thereafter, the wiring layer 114 is formed (FIG. 45). In this manner, the first substrate 110 is formed. Subsequently, the third substrate 30 is attached to the first substrate 110 in a method similar to that of the foregoing first embodiment (FIG. 46). Thereafter, the substrate 90 is detached (FIG. 47).

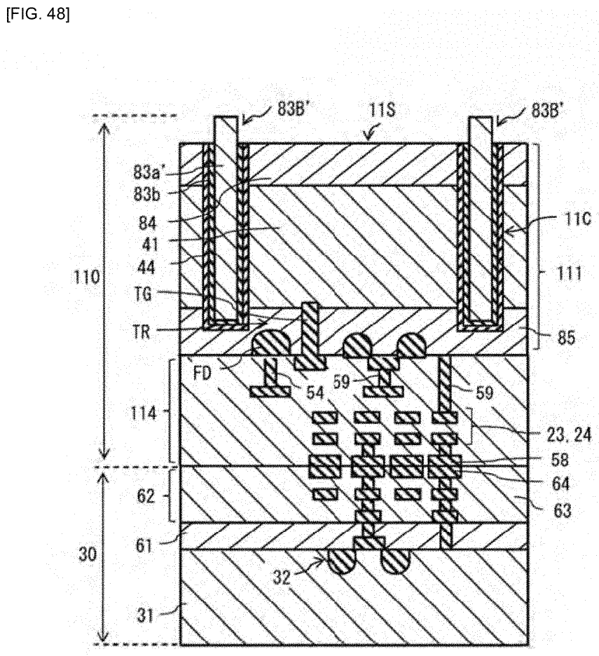

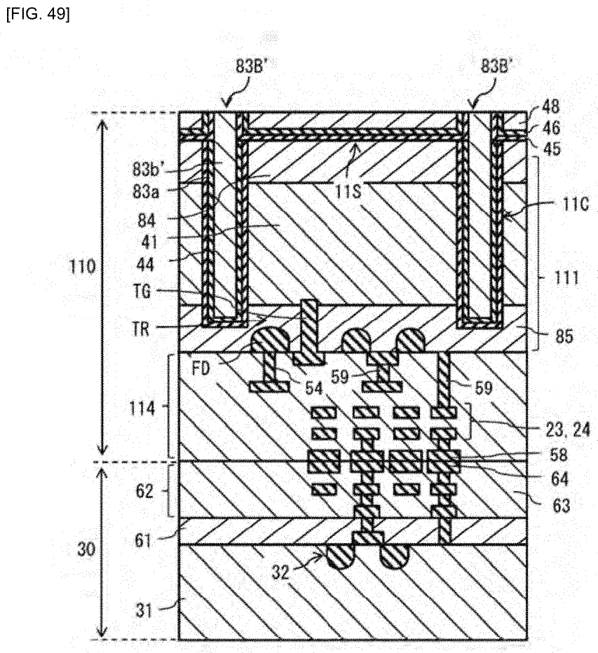

Next, the SiO₂ film 71 and the SiN film 72 are removed (FIG. 48). This causes a portion of the polysilicon section 83b′ to protrude from the top surface of the semiconductor substrate 111 (FIG. 48). Hereinafter, a part, of the polysilicon section 83b′, protruding from the top surface of the semiconductor substrate 111 is referred to as a protrusion 83B′. In addition, a region, of the top surface of the semiconductor substrate 111, surrounded by the protrusion 83B′ is referred to as the light-receiving surface 11S. The light-receiving surface 11S corresponds to a bottom surface of a recessed part formed by the protrusion 83B′. Subsequently, the fixed-charge film 45, the antireflection film 46 and the insulating layer 48 are formed in the recessed part surrounded by the protrusion 83B′ (FIG. 49).

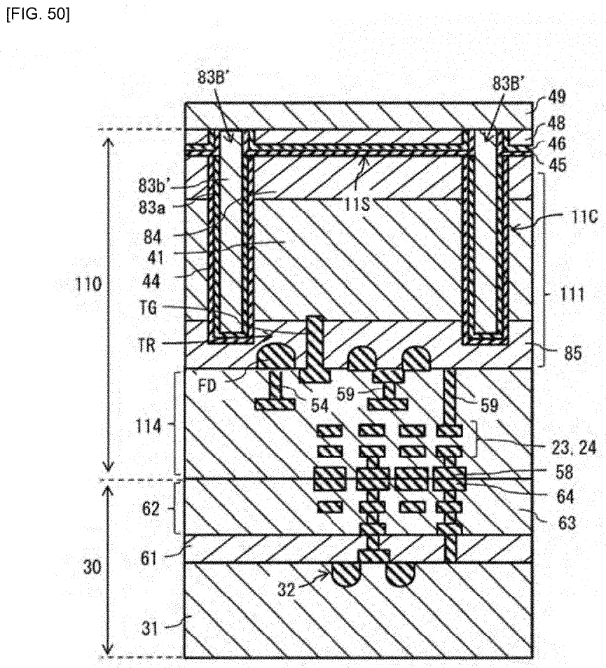

Next, for example, a sputtering method is used to form the aluminum layer 49 to be in contact with the protrusion 83B′ (FIG. 50). Subsequently, the substitution phenomenon through heat treatment is utilized to substitute the polysilicon with aluminum. This allows for substitution of the polysilicon section 83b′ inside the trench 11C with the metal buried part 83b (FIG. 51). It is to be noted that an aluminum alloy layer may be formed in place of the aluminum layer 49. At this time, the substitution phenomenon through heat treatment is utilized to be able to substitute the polysilicon with an aluminum alloy.

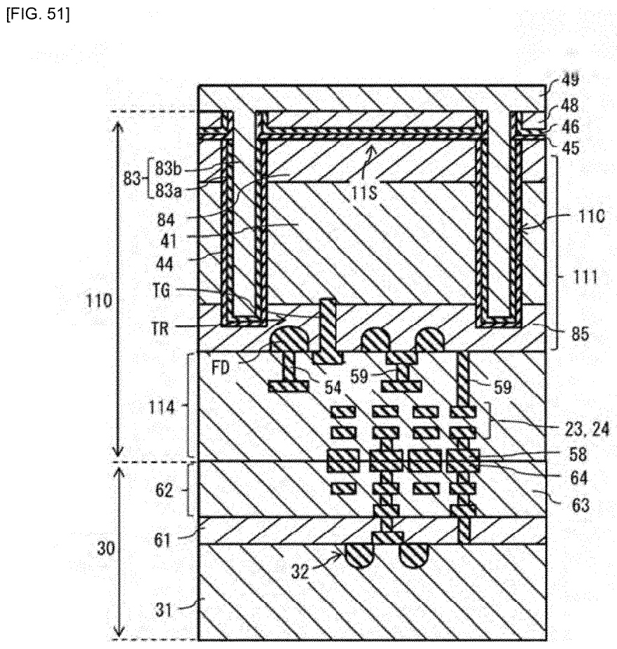

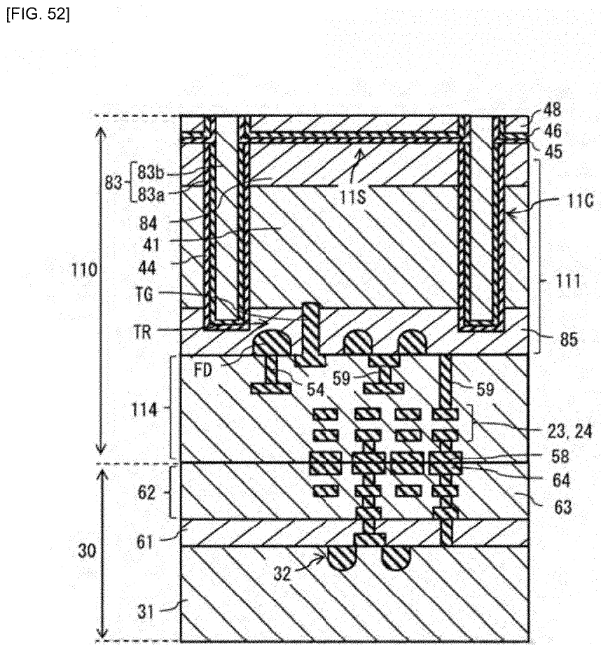

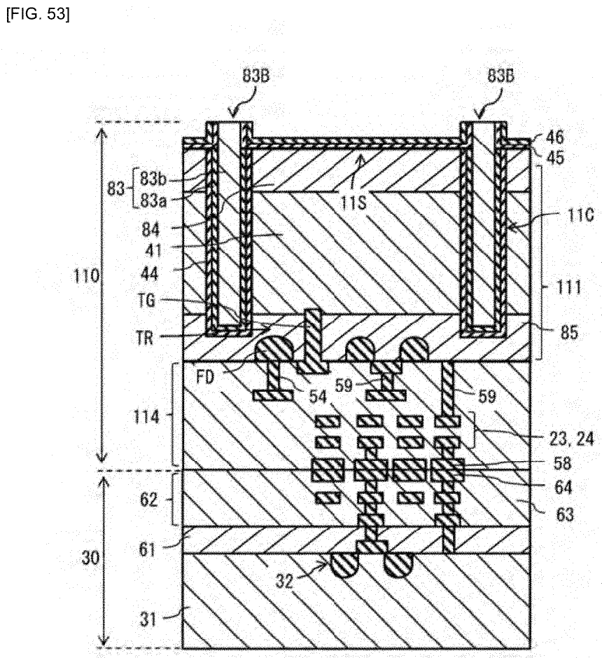

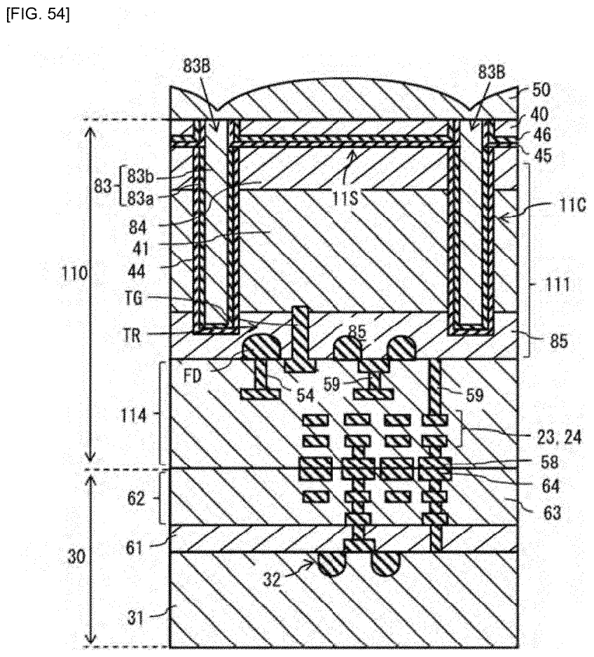

Next, the aluminum layer 49 of the front surface is removed (FIG. 52), and further the insulating layer 48 is also removed (FIG. 53). This allows an upper part of the metal buried part 83b to protrude from the top surface (light-receiving surface 11S) of the semiconductor substrate 111. A part, of the metal buried part 83b, protruding from the top surface (light-receiving surface 11S) of the semiconductor substrate 111 is the protrusion 83B described above. Subsequently, the color filter 40 is formed in the recessed part surrounded by the protrusion 83B, and thereafter the light-receiving lens 50 is formed on the color filter 40 (FIG. 54). At this time, the light-receiving lens 50 is formed to be in contact with the metal buried part 43b. In this manner, the imaging device 2 is manufactured.

Next, description is given of effects of the imaging device 2 according to the present embodiment.

In the present embodiment, the element separation section 83 is provided, extending from between the two adjacent PDs 41 to between the two adjacent color filters 40. This makes it possible to suppress the light leakage through a gap between the one photodiode, which is the integration of the PD 41 and the n-type semiconductor layer 84, and the color filter 40. As a result, as compared with the case of not providing the element separation section 83, it is possible to suppress the crosstalk between the sensor pixels 12 more effectively. Further, in the present embodiment, the p-type solid-phase diffusion layer 44 is formed in contact with a surface, of the element separation section 83, on the side of the PD 41. This makes it possible to reduce the mixing of a dark current into the PD 41. Accordingly, it is possible, in the present embodiment, to suppress not only the crosstalk between the sensor pixels 12 but also the mixing of a dark current into the PD 41 more effectively.

In addition, in the present embodiment, the p-type solid-phase diffusion layer 44 and the p-well layer 85 are electrically conducted to each other. This causes an interface between the element separation section 43 and the semiconductor substrate 11 to be covered with the p-type solid-phase diffusion layer 44, thus allowing the p-type solid-phase diffusion layer 44 to be conducted to the p-well layer 42. As a result, electrons generated at the interface between the element separation section 43 and the semiconductor substrate 11 do not flow into the PD 41, thus making it possible to reduce the dark current.

In addition, in the present embodiment, the element separation section 83 is provided within the trench 11C provided in the semiconductor substrate 111, and is provided to protrude from the top surface (light-receiving surface 11S) of the semiconductor substrate 111. This enables each color filter 40 to be provided in the recessed part surrounded by the protrusion 83B of the metal buried part 83b and further enables an edge of the light-receiving lens 50 to abut the protrusion 83B of the metal buried part 83b. As a result, it is possible to suppress the light leakage through a gap between the PD 41 and the color filter 40. As a result, as compared with the case of not providing the element separation section 83, it is possible to suppress the crosstalk between the sensor pixels 12 more effectively.

In addition, in the present embodiment, the element separation section 83 has the DTI structure configured by the insulating film 83a in contact with the inner wall of the trench 11C and the metal buried part 83b formed inside the insulating film 83a. Further, the DTI structure is provided to extend from between the two adjacent PDs 41 to between the two adjacent color filters 40. This makes it possible to suppress the light leakage through a gap between the PD 41 and the color filter 40. As a result, as compared with the case of not providing the element separation section 83, it is possible to suppress the crosstalk between the sensor pixels 12 more effectively.

In addition, in the present embodiment, the metal buried part 83b is formed by aluminum or an aluminum alloy. Here, the reflectance of aluminum or an aluminum alloy to visible light is higher than the reflectance of tungsten to visible light (about 50% to 60%), and is 70% or more. This makes it possible to efficiently guide incident light to the PD 41 and to further suppress the light leakage through a gap between the PD 41 and the color filter 40. As a result, as compared with the case of not providing the element separation section 83, it is possible not only to achieve good efficiency of light incident into the PD 41, but also to suppress the crosstalk between the sensor pixels 12 more effectively.

### 4. Modification Examples of Each Embodiment

Next, description is given of modification examples of each embodiment.

### Modification Example C

In the imaging device 1 according to any of the first embodiment and Modification Examples A and B, the second substrate 20 may include one readout circuit 22 for each of the plurality of sensor pixels 12. For example, as illustrated in FIG. 55, the second substrate 20 may include one readout circuit 22 for every four sensor pixels 12. At this time, the four sensor pixels 12 share one readout circuit 22. Alternatively, the second substrate 20 may include one readout circuit 22 for every eight sensor pixels 12 (unillustrated).

### Modification Example D

In the imaging device 2 according to the second embodiment, the first substrate 110 may include one readout circuit 22 for each of the plurality of sensor pixels 12. For example, as illustrated in FIG. 56, the first substrate 110 may include one readout circuit 22 for every four sensor pixels 12. At this time, the four sensor pixels 12 share one readout circuit 22. Alternatively, the first substrate 110 may include one readout circuit 22 for every eight sensor pixels 12 (unillustrated). In addition, in Modification Example D, the respective sensor pixels 12 sharing one readout circuit 22 may include mutually different floating diffusions FD.

### Modification Example E

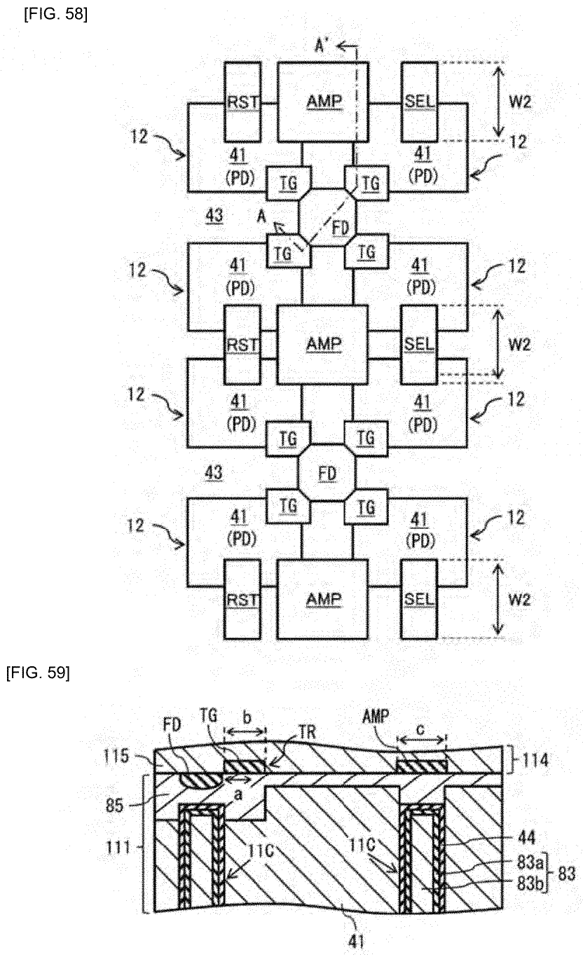

For example, as illustrated in FIG. 57, in Modification Example D, the sensor pixels 12 sharing one readout circuit 22 may share the floating diffusion FD. In addition, for example, as illustrated in FIG. 58, in Modification Example D, the sensor pixels 12 sharing one readout circuit 22 may share the floating diffusion FD.

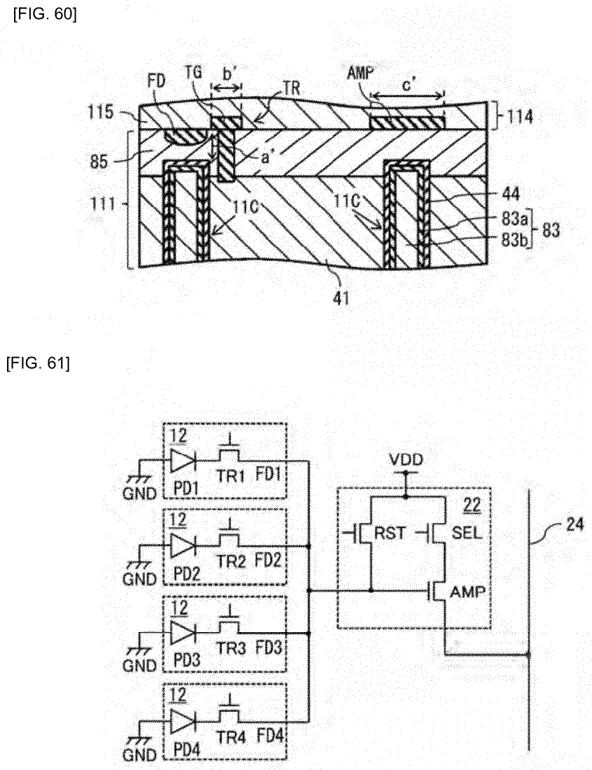

FIG. 59 illustrates an example of a cross-sectional configuration along a line A-A of FIG. 57. FIG. 60 illustrates an example of a cross-sectional configuration along a line A-A of FIG. 58. FIG. 59 exemplifies a case where the transfer transistor TR includes a planar transfer gate TG, and the transfer gate TG is formed only on the front surface of the semiconductor substrate 111 without penetrating the p-well layer 85. Meanwhile, FIG. 60 exemplifies a case where the transfer transistor TR includes a vertical transfer gate TG, and the transfer gate TG penetrates the p-well layer 85 to extend to such a depth as to reach the PD 41. In FIGS. 59 and 60, the p-well layer 85 is not separated for each sensor pixel 112 by the element separation section 83.

A channel length a or a′ of the transfer gate TG that transfers charges from the PD 41 to the floating diffusion 1-1) requires a predetermined length. Therefore, a gate length b′ of the vertical transfer gate TG may be shorter than a gate length b of the planar transfer gate TG. Accordingly, a size c′ of the transistor (e.g., the amplification transistor AMP) of the readout circuit 22 coupled to the vertical transfer gate TG may be larger than a size c of the transistor (e.g., the amplification transistor AMP) of the readout circuit 22 coupled to the planar transfer gate TG. Consequently, the readout circuit 22 coupled to the vertical transfer gate TG is able to reduce random noise as compared with the readout circuit 22 coupled to the planar transfer gate TG.

### Modification Example F

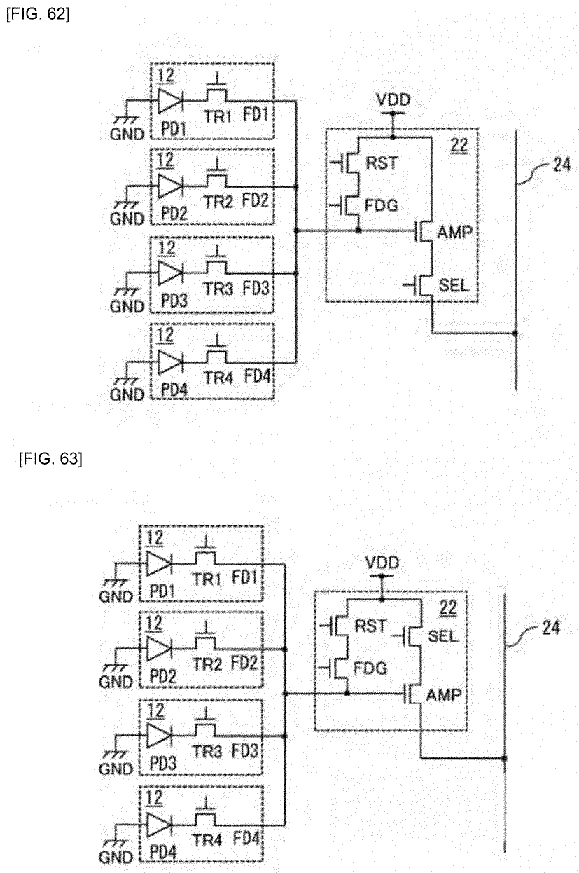

For example, as illustrated in FIG. 61, in Modification Examples C and D, the selection transistor SEL may be provided between the power source line VDD and the amplification transistor AMP. In this case, a drain of the reset transistor RST is electrically coupled to the power source line VDD and a drain of the selection transistor SEL. A source of the selection transistor SEL is electrically coupled to a drain of the amplification transistor AMP, and a gate of the selection transistor SEL is electrically coupled to the pixel drive line 23 (see FIG. 1). A source of the amplification transistor AMP (an output end of the readout circuit 22) is electrically coupled to the vertical signal line 24, and a gate of the amplification transistor AMP is electrically coupled to a source of the reset transistor RST. In addition, for example, as illustrated in FIGS. 62 and 63, an FD transfer transistor FDG may be provided between the source of the reset transistor RST and the gate of the amplification transistor AMP.

The FD transfer transistor FDG is used when switching a conversion efficiency. In general, a pixel signal is small when shooting in a dark place. When performing charge-voltage conversion on a basis of Q=CV, larger capacity of the floating diffusion FD (FD capacity C) causes the value V to be smaller upon conversion to a voltage at the amplification transistor AMP. Meanwhile, the pixel signal becomes large in a bright place; it is therefore not possible, for the floating diffusion FD, to receive the charges of the photodiode PD unless the FD capacity C is large. Further, the FD capacity C needs to be large to allow the value V not to be too large (in other words, to be small) upon the conversion to a voltage at the amplification transistor AMP. Taking these into account, when the FD transfer transistor FDG is turned ON, a gate capacity for the FD transfer transistor FDG is increased, thus causing the entire 1-1) capacity C to be large. Meanwhile, when the FD transfer transistor FUG is turned off, the entire FD capacity C becomes small. In this manner, performing ON/OFF switching of the FD transfer transistor FDG enables the FD capacity C to be variable, thus making it possible to switch the conversion efficiency.

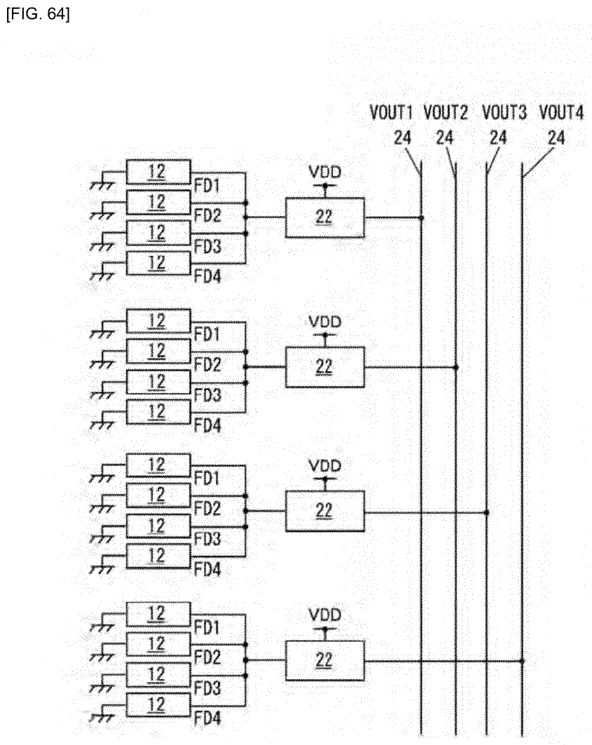

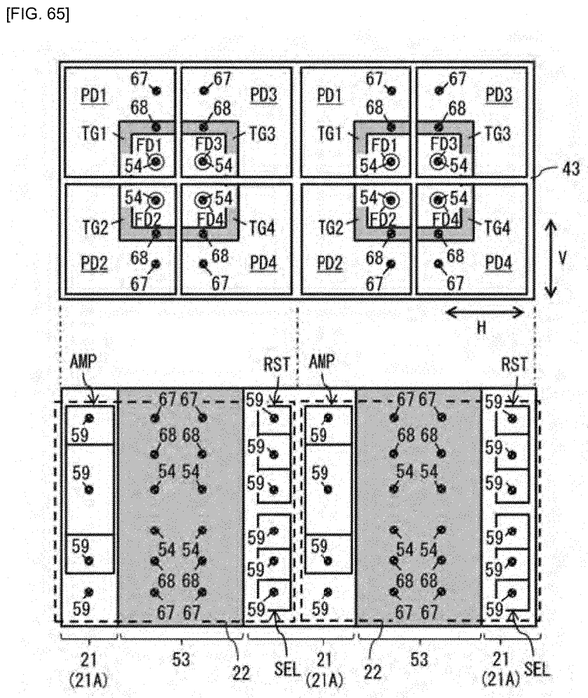

FIG. 64 illustrates an example of a coupling mode between the plurality of readout circuits 22 and the plurality of vertical signal lines 24. In a case where the plurality of readout circuits 22 are arranged side by side in a direction in which the vertical signal lines 24 extend (e.g., column direction), the plurality of vertical signal lines 24 may be assigned one by one for the respective readout circuits 22. For example, as illustrated in FIG. 64, in a case where four readout circuits 22 are arranged side by side in the direction in which the vertical signal lines 24 extend (e.g., column direction), four vertical signal lines 24 may be assigned one by one for the respective readout circuits 22. It is to be noted that, in FIG. 64, in order to distinguish the vertical signal lines 24, the identification number (1, 2, 3, or 4) is assigned to the end of the symbol of each vertical signal line 24.

### Modification Example G

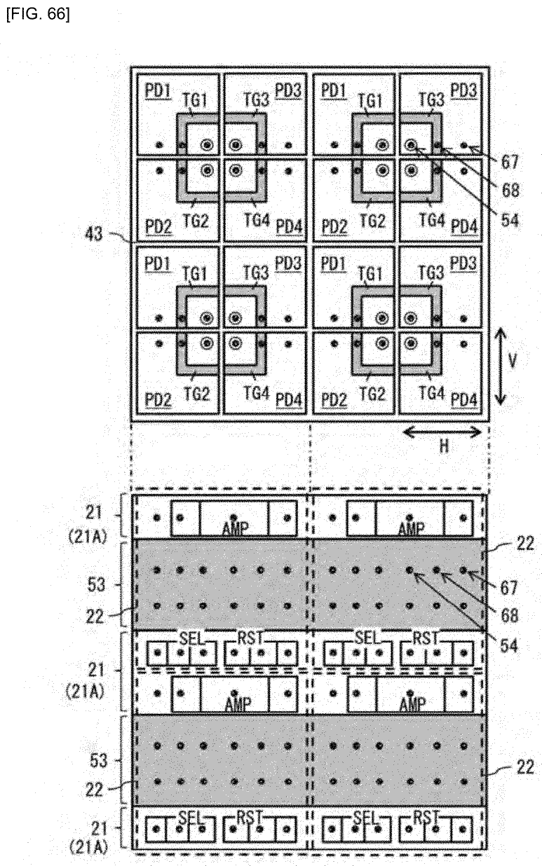

FIGS. 65 and 66 each illustrate a modification example of a cross-sectional configuration in the horizontal direction of each of the imaging devices 1 having the configurations of FIGS. 55 and 61. Each diagram on upper side of FIGS. 65 and 66 illustrates an example of a cross-sectional configuration of an insulating layer 46 taken along the horizontal direction in each of the imaging devices 1 having the configurations of Modification Examples C and F. Each diagram on lower side of FIGS. 65 and 66 illustrates an example of a cross-sectional configuration of the insulating layer 52 taken along the horizontal direction in each of the imaging devices 1 having the configurations of Modification Examples C and F. FIG. 65 exemplifies a configuration in which two sets of four sensor pixels 12 of 2×2 are arranged in a second direction H, and FIG. 66 exemplifies a configuration in which four sets of four sensor pixels 12 of 2×2 are arranged in a first direction V and the second direction H. It is to be noted that, in each cross-sectional view on the upper side of FIGS. 65 and 66, a diagram illustrating an example of the front surface configuration of the semiconductor substrate 11 is superimposed on a diagram illustrating the example of the cross-sectional configuration of the insulating layer 46 taken along the horizontal direction in the imaging device 1 having any of the configurations of Modification Examples C and F, with the insulating layer 46 being omitted. In addition, in each cross-sectional view on the lower side of FIGS. 65 and 66, a diagram illustrating an example of the front surface configuration of the semiconductor substrate 21 is superimposed on a diagram illustrating the example of the cross-sectional configuration of the insulating layer 52 taken along the horizontal direction in the imaging device 1 having any of the configurations of Modification Examples C and F.

The stacked body including the first substrate 10 and the second substrate 20 includes through-wiring lines 67 and 68 provided inside the interlayer insulating film 51. The stacked body includes one through-wiring line 67 and one through-wiring line 68 for each sensor pixel 12. Each of the through-wiring lines 67 and 68 extends in the normal direction of the semiconductor substrate 21, and is provided to penetrate a location, of the interlayer insulating film 51, including the insulating layer 53. The first substrate 10 and the second substrate 20 are electrically coupled to each other by the through-wiring lines 67 and 68. Specifically, the through-wiring line 67 is electrically coupled to the p-well layer 42 of the semiconductor substrate 11 and to a wiring line inside the second substrate 20. The through-wiring line 68 is electrically coupled to the transfer gate TG and to the pixel drive line 23. As illustrated in FIGS. 65 and 66, a plurality of through-wiring lines 54, a plurality of through-wiring lines 68, and a plurality of through-wiring lines 67 are arranged side by side in a strip shape in the first direction V (vertical direction in FIG. 65, horizontal direction in FIG. 66) within the plane of the first substrate 10. It is to be noted that FIGS. 65 and 66 each exemplify the case where the plurality of through-wiring lines 54, the plurality of through-wiring lines 68, and the plurality of through-wiring lines 67 are arranged side by side in two rows in the first direction V. The first direction V is parallel to one arrangement direction (e.g., column direction) of two arrangement directions (e.g., row direction and column direction) of the plurality of sensor pixels 12 arranged in matrix. In the four sensor pixels 12 sharing the readout circuit 22, four floating diffusions FD are arranged close to each other, for example, with the element separation section 43 interposed therebetween. In the four sensor pixels 12 sharing the readout circuit 22, four transfer gates TG are arranged to surround the four floating diffusions FD, and the four transfer gates TG form an annular shape, for example.

The insulating layer 53 is configured by a plurality of blocks extending in the first direction V. The semiconductor substrate 21 extends in the first direction V, and is configured by a plurality of island-shaped blocks 21A arranged side by side in the second direction H orthogonal to the first direction V, with the insulating layer 53 interposed therebetween. Each block 21A is provided with, for example, a plurality of sets of the reset transistors RST, the amplification transistors AMP, and the selection transistors SEL. The one readout circuit 22 shared by the four sensor pixels 12 is configured by, for example, the reset transistor RST, the amplification transistor AMP, and the selection transistor SEL in a region facing the four sensor pixels 12. The one readout circuit 22 shared by the four sensor pixels 12 is configured by, for example, the amplification transistor AMP inside the left adjacent block 21A of the insulating layer 53, and the reset transistor RST and the selection transistor SEL inside the right adjacent block 21A of the insulating layer 53.

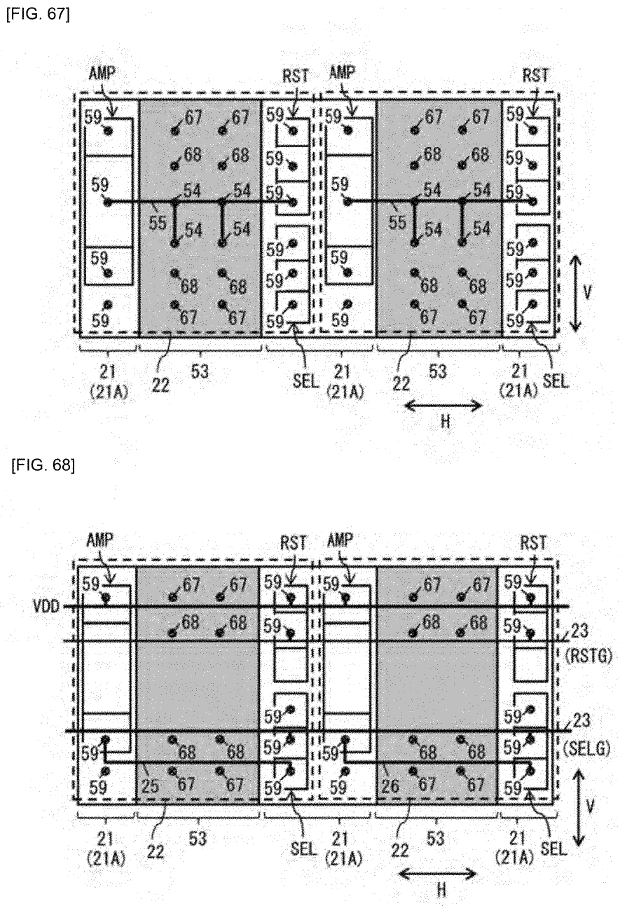

FIGS. 67, 68, 69 and 70 each illustrate an example of a wiring line layout in a horizontal plane of the imaging device 1. FIGS. 67 to 70 each exemplify the case where the one readout circuit 22 shared by the four sensor pixels 12 is provided inside a region facing the four sensor pixels 12. The wiring lines illustrated in FIGS. 67 to 70 are provided, for example, inside mutually different layers in the wiring layer 56.

Four through-wiring lines 54 adjacent to one another are electrically coupled to the coupling wiring line 55, for example, as illustrated in FIG. 67. The four through-wiring lines 54 adjacent to one another are further electrically coupled to the gate of the amplification transistor AMP included in the left adjacent block 21A of the insulating layer 53 and to the gate of the reset transistor RST included in the right adjacent block 21A of the insulating layer 53 via the coupling wiring line 55 and the coupling section 59, for example, as illustrated in FIG. 67.

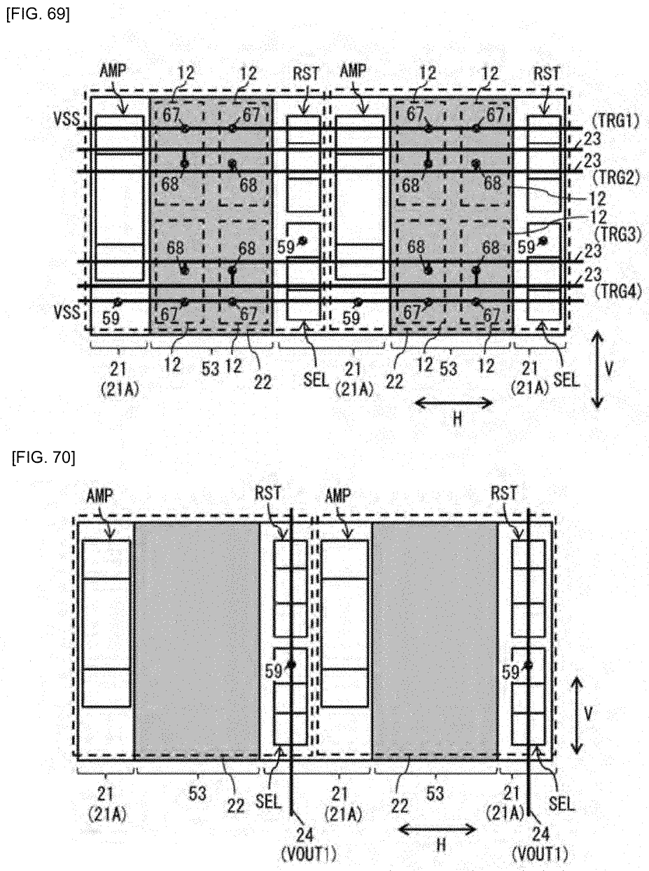

The power source line VDD is arranged at positions facing the readout circuits 22 arranged side by side in the second direction H, for example, as illustrated in FIG. 68. The power source line VDD is electrically coupled to the drain of the amplification transistor AMP and the drain of the reset transistor RST of each of the readout circuits 22 arranged side by side in the second direction H via the coupling section 59, for example, as illustrated in FIG. 68. Two pixel drive lines 23 are arranged at positions facing the readout circuits 22 arranged side by side in the second direction H, for example, as illustrated in FIG. 68. One pixel drive line 23 (a second control line) is a wiring line RSTG electrically coupled to the gate of the reset transistor RST of each of the readout circuits 22 arranged side by side in the second direction H, for example, as illustrated in FIG. 68. The other pixel drive line 23 (a third control line) is a wiring line SELG electrically coupled to the gate of the selection transistor SEL of each of the readout circuits 22 arranged side by side in the second direction H, for example, as illustrated in FIG. 68. In each of the readout circuits 22, the source of the amplification transistor AMP and the drain of the selection transistor SEL are electrically coupled to each other via a wiring line 25, for example, as illustrated in FIG. 68.

Two power source lines VSS are arranged at positions facing the readout circuits 22 arranged side by side in the second direction H, for example, as illustrated in FIG. 69. Each of the power source lines VSS is electrically coupled to the plurality of through-wiring lines 67 at positions facing the respective sensor pixels 12 arranged side by side in the second direction H, for example, as illustrated in FIG. 69. Four pixel drive lines 23 are each arranged at positions facing the readout circuits 22 arranged side by side in the second direction H, for example, as illustrated in FIG. 69. Each of the four pixel drive lines 23 is a wiring line TRG electrically coupled to the through-wiring line 68 of one sensor pixel 12 of the four sensor pixels 12 corresponding to each of the readout circuits 22 arranged side by side in the second direction H, for example, as illustrated in FIG. 69. That is, the four pixel drive lines 23 (first control lines) are each electrically coupled to the gate (transfer gate TG) of the transfer transistor TR of each of the sensor pixels 12 arranged side by side in the second direction H. In FIG. 69, in order to distinguish the wiring lines TRG from one another, an identification number (1, 2, 3, or 4) is assigned to the end of each wiring line TRG.

The vertical signal line 24 is arranged at positions facing the readout circuits 22 arranged side by side in the first direction V, for example, as illustrated in FIG. 70. The vertical signal line 24 (an output line) is electrically coupled to an output end (the source of the amplification transistor AMP) of each of the readout circuits 22 arranged side by side in the first direction V, for example, as illustrated in FIG. 70.

### Modification Example H

FIG. 71 illustrates a modification example of a cross-sectional configuration in the vertical direction of the imaging device 1 according to any of the first embodiment and Modification Examples thereof (A to C and E to G). In the present modification example, electric coupling between the second substrate 20 and the third substrate 30 is made in a region facing a peripheral region 14 in the first substrate 10. The peripheral region 14 corresponds to a frame region of the first substrate 10, and is provided on the periphery of the pixel region 13. In the present modification example, the second substrate 20 includes the plurality of pad electrodes 58 in the region facing the peripheral region 14, and the third substrate 30 includes the plurality of pad electrodes 64 in the region facing the peripheral region 14. The second substrate 20 and the third substrate 30 are electrically coupled to each other by junctions between the pad electrodes 58 and 64 provided in the region facing the peripheral region 14.

In this manner, in the present modification example, the second substrate 20 and the third substrate 30 are electrically coupled to each other by the junctions between the pad electrodes 58 and 64 provided in the region facing the peripheral region 14. This makes it possible to reduce the possibility of inhibiting miniaturization of an area per pixel, as compared with the case of bonding the pad electrodes 58 and 64 to each other in a region facing the pixel region 13. Thus, it is possible to provide the imaging device 1 having a three-layered structure that does not inhibit the miniaturization of an area per pixel, while having a chip size equivalent to an existing chip size.

### Modification Example I

FIGS. 72 and 73 each illustrate a modification example of a cross-sectional configuration in the horizontal direction of the imaging device 1 according to any of Modification Examples C, F, G, and H. Each diagram on upper side of FIGS. 72 and 73 illustrates a modification example of a cross-sectional configuration of the insulating layer 46 taken along the horizontal direction in the imaging device 1 having any of the configurations of Modification Examples C, F, G, and H. Each diagram on lower side of FIGS. 72 and 73 illustrates a modification example of a cross-sectional configuration of the insulating layer 52 taken along the horizontal direction in the imaging device 1 having any of the configurations of Modification Examples C, F, G, and H. It is to be noted that, in each cross-sectional view on the upper side of FIGS. 72 and 73, a diagram illustrating a modification example of the front surface configuration of the semiconductor substrate 11 is superimposed on a diagram illustrating the modification example of the cross-sectional configuration of the insulating layer 46 taken along the horizontal direction in the imaging device 1 having any of the configurations of Modification Examples C, F, G, and H, with the insulating layer 46 being omitted. In addition, in each cross-sectional view on the lower side of FIGS. 72 and 73, a diagram illustrating a modification example of the front surface configuration of the semiconductor substrate 21 is superimposed on a diagram illustrating the modification example of the cross-sectional configuration of the insulating layer 52 taken along the horizontal direction in the imaging device 1 having any of the configurations of Modification Examples C, F, G, and H.

As illustrated in FIGS. 72 and 73, the plurality of through-wiring lines 54, the plurality of through-wiring lines 68, and the plurality of through-wiring lines 67 (a plurality of dots arranged in matrix in the drawing) are arranged side by side in a strip shape in the first direction V (horizontal direction in FIGS. 72 and 73) in a plane of the first substrate 10. It is to be noted that FIGS. 72 and 73 each exemplify the case where the plurality of through-wiring lines 54, the plurality of through-wiring lines 68, and the plurality of through-wiring lines 67 are arranged side by side in two rows in the first direction V. In the four sensor pixels 12 sharing the readout circuit 22, the four floating diffusions FD are arranged close to each other with the element separation section 43 interposed therebetween, for example. In the four sensor pixels 12 sharing the readout circuit 22, the four transfer gates TG (TG1, TG2, TG3, and TG4) are arranged to surround the four floating diffusions FD, and the four transfer gates TG form an annular shape, for example.

The insulating layer 53 is configured by a plurality of blocks extending in the first direction V. The semiconductor substrate 21 extends in the first direction V, and is configured by the plurality of island-shaped blocks 21A arranged side by side in the second direction H orthogonal to the first direction V, with the insulating layer 53 interposed therebetween. Each block 21A includes, for example, the reset transistor RST, the amplification transistor AMP, and the selection transistor SEL. One readout circuit 22 shared by the four sensor pixels 12 is not arranged to squarely face the four sensor pixels 12, for example, and is arranged to be shifted in the second direction H.

In FIG. 72, the one readout circuit 22 shared by the four sensor pixels 12 is configured by the reset transistor RST, the amplification transistor AMP, and the selection transistor SEL, which are inside a region, of the second substrate 20, shifted in the second direction H from the region facing the four sensor pixels 12. The one readout circuit 22 shared by the four sensor pixels 12 is configured by, for example, the amplification transistor AMP, the reset transistor RST, and the selection transistor SEL inside one block 21A.

In FIG. 73, the one readout circuit 22 shared by the four sensor pixels 12 is configured by the reset transistor RST, the amplification transistor AMP, the selection transistor SEL, and the FD transfer transistor FDG, which are inside a region, of the second substrate 20, shifted in the second direction H from the region facing the four sensor pixels 12. The one readout circuit 22 shared by the four sensor pixels 12 is configured by, for example, the amplification transistor AMP, the reset transistor RST, the selection transistor SEL, and the FD transfer transistor FDG inside the one block 21A.

In the present modification example, the one readout circuit 22 shared by the four sensor pixels 12 is not arranged to squarely face the four sensor pixels 12, for example, and is arranged to be shifted in the second direction H from a position squarely facing the four sensor pixels 12. In such a case, it may be possible to shorten the wiring line 25, or it may be possible to omit the wiring line 25 and to configure a source of the amplification transistor AMP and a drain of the selection transistor SEL using an impurity region in common. As a result, it is possible to reduce a size of the readout circuit 22 or to increase a size of another location inside the readout circuit 22.

### Modification Example J

FIG. 74 illustrates a modification example of a cross-sectional configuration in the horizontal direction of the imaging device 1 according to any of Modification Examples C, F, G, H, and I. A diagram on upper side of FIG. 74 illustrates an example of a cross-sectional configuration of the insulating layer 46 taken along the horizontal direction in the imaging device 1 having any of the configurations of Modification Examples C, F, G, H, and I. A diagram on lower side of FIG. 74 illustrates an example of a cross-sectional configuration of the insulating layer 52 taken along the horizontal direction in the imaging device 1 having any of the configurations of Modification Examples C, F, G, H, and I. FIG. 74 exemplifies a configuration in which two sets of four sensor pixels 12 of 2×2 are arranged in the second direction H. It is to be noted that, in the cross-sectional view on the upper side of FIG. 74, a diagram illustrating the example of the front surface configuration of the semiconductor substrate 11 is superimposed on a diagram illustrating the example of the cross-sectional configuration of the insulating layer 46 taken along the horizontal direction in the imaging device 1 having any of the configurations of Modification Examples C, F, G, H, and I, with the insulating layer 46 being omitted. In addition, in the cross-sectional view on the lower side of FIG. 74, a diagram illustrating the example of the front surface configuration of the semiconductor substrate 21 is superimposed on a diagram illustrating the example of the cross-sectional configuration of the insulating layer 52 taken along the horizontal direction in the imaging device 1 having any of the configurations of Modification Examples C, F, G, H, and I.

In the present modification example, the semiconductor substrate 21 is configured by the plurality of island-shaped blocks 21A arranged side by side in the first direction V and the second direction H, with the insulating layer 53 interposed therebetween. Each block 21A includes, for example, a set of the reset transistor RST, the amplification transistor AMP, and the selection transistor SEL. In such a case, it is possible to cause the insulating layer 53 to suppress a crosstalk between the readout circuits 22 adjacent to each other, thus making it possible to suppress image quality degradation due to a decrease in resolution and color mixing on a reproduced image.

### Modification Example K

FIG. 75 illustrates a modification example of a cross-sectional configuration in the horizontal direction of the imaging device 1 according to any of Modification Examples C, F, G, H, I, and J. A diagram on upper side of FIG. 75 illustrates an example of a cross-sectional configuration of the insulating layer 46 taken along the horizontal direction in the imaging device 1 having any of the configurations of Modification Examples C, F, G, H, I, and J. A diagram on lower side of FIG. 75 illustrates an example of a cross-sectional configuration of the insulating layer 52 taken along the horizontal direction in the imaging device 1 having any of the configurations of Modification Examples C, F, G, H, I, and J. FIG. 75 exemplifies a configuration in which two sets of four sensor pixels 12 of 2×2 are arranged in the second direction H. It is to be noted that, in the cross-sectional view on the upper side of FIG. 75, a diagram illustrating the example of the front surface configuration of the semiconductor substrate 11 is superimposed on a diagram illustrating the example of the cross-sectional configuration of the insulating layer 46 taken along the horizontal direction in the imaging device 1 having any of the configurations of Modification Examples C, F, G, H, I, and J, with the insulating layer 46 being omitted. In addition, in the cross-sectional view on the lower side of FIG. 75, a diagram illustrating the example of the front surface configuration of the semiconductor substrate 21 is superimposed on a diagram illustrating the example of the cross-sectional configuration of the insulating layer 52 taken along the horizontal direction in the imaging device 1 having any of the configurations of Modification Examples C, F, G, H, I, and J.

In the present modification example, the one readout circuit 22 shared by the four sensor pixels 12 is not arranged to squarely face the four sensor pixels 12, for example, and is arranged to be shifted in the first direction V. In the present modification example, similarly to Modification Example F, the semiconductor substrate 21 is further configured by the plurality of island-shaped blocks 21A arranged side by side in the first direction V and the second direction H, with the insulating layer 53 interposed therebetween. Each block 21A includes, for example, a set of the reset transistor RST, the amplification transistor AMP, and the selection transistor SEL. In the present modification example, the plurality of through-wiring lines 67 and the plurality of through-wiring lines 54 are further arranged also in the second direction H. Specifically, the plurality of through-wiring lines 67 is disposed between the four through-wiring lines 54 sharing a certain readout circuit 22 and the four through-wiring lines 54 sharing another readout circuit 22 adjacent to the certain readout circuit 22 in the second direction H. In such a case, it is possible to cause the insulating layer 53 and the through-wiring line 67 to suppress a crosstalk between the readout circuits 22 adjacent to each other, thus making it possible to suppress image quality degradation due to a decrease in resolution and color mixing on a reproduced image.

### Modification Example L

FIG. 76 illustrates an example of a cross-sectional configuration in the horizontal direction of the imaging device 1 according to any of Modification Examples C, E, F, G, H, I, J, and K. A diagram on upper side of FIG. 76 illustrates an example of a cross-sectional configuration of the insulating layer 46 taken along the horizontal direction in the imaging device 1 having any of the configurations of Modification Examples C, E, F, G, H, I, J, and K. A diagram on lower side of FIG. 76 illustrates an example of a cross-sectional configuration of the insulating layer 52 taken along the horizontal direction in the imaging device 1 having any of the configurations of Modification Examples C, E, F, G, H, I, J, and K. FIG. 76 exemplifies a configuration in which two sets of four sensor pixels 12 of 2×2 are arranged in the second direction H. It is to be noted that, in the cross-sectional view on the upper side of FIG. 76, a diagram illustrating the example of the front surface configuration of the semiconductor substrate 11 is superimposed on a diagram illustrating the example of the cross-sectional configuration of the insulating layer 46 taken along the horizontal direction in the imaging device 1 having any of the configurations of Modification Examples C, E, F, G, H, I, J, and K, with the insulating layer 46 being omitted. In addition, in the cross-sectional view on the lower side of FIG. 76, a diagram illustrating the example of the front surface configuration of the semiconductor substrate 21 is superimposed on a diagram illustrating the example of the cross-sectional configuration of the insulating layer 52 taken along the horizontal direction in the imaging device 1 having any of the configurations of Modification Examples C, E, F, G, H, I, J, and K.

In the present modification example, the first substrate 10 includes the photodiode PD and the transfer transistor TR for each sensor pixel 12, and includes the floating diffusion FD shared by every four sensor pixels 12. Accordingly, in the present modification example, one through-wiring line 54 is provided for every four sensor pixels 12.

In the plurality of sensor pixels 12 arranged in matrix, four sensor pixels 12 corresponding to a region, which is obtained by shifting the unit region corresponding to four sensor pixels 12 sharing one floating diffusion FD by one sensor pixel 12 in the first direction V, is referred to as four sensor pixels 12A, for the sake of convenience. At this time, in the present modification example, the first substrate 10 includes the through-wiring line 67 shared by every four sensor pixels 12A. Accordingly, in the present modification example, one through-wiring line 67 is provided for every four sensor pixels 12A.

In the present modification example, the first substrate 10 includes the element separation section 43 that separates the photodiodes PD and the transfer transistors TR for the respective sensor pixels 12. When viewed from the normal direction of the semiconductor substrate 11, the element separation section 43 does not completely surround the sensor pixel 12, and has a gap (unformed region) in the vicinity of the floating diffusion FD (through-wiring line 54) and in the vicinity of the through-wiring line 67. In addition, the gap enables sharing of the one through-wiring line 54 by the four sensor pixels 12 as well as sharing of the one through-wiring line 67 by the four sensor pixels 12A. In the present modification example, the second substrate 20 includes the readout circuit 22 for every four sensor pixels 12 sharing the floating diffusion FD.

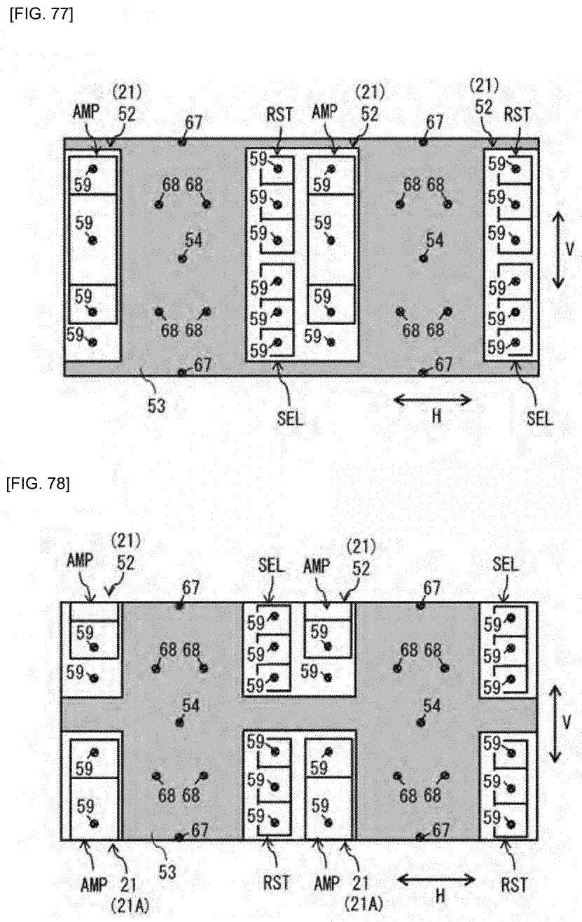

FIG. 77 illustrates a modification example of a cross-sectional configuration in the horizontal direction of the imaging device 1 according to the present modification example. FIG. 77 illustrates a modification example of the cross-sectional configuration of the diagram on the lower side of FIG. 76. In the present modification example, the semiconductor substrate 21 is configured by the plurality of island-shaped blocks 21A arranged side by side in the first direction V and the second direction H, with the insulating layer 53 interposed therebetween. Each block 21A includes, for example, a set of the reset transistor RST, the amplification transistor AMP, and the selection transistor SEL. In such a case, it is possible to cause the insulating layer 53 to suppress a crosstalk between the readout circuits 22 adjacent to each other, thus making it possible to suppress image quality degradation due to a decrease in resolution and color mixing on a reproduced image.

FIG. 78 illustrates a modification example of a cross-sectional configuration in the horizontal direction of the imaging device 1 according to the present modification example. FIG. 78 illustrates a modification example of the cross-sectional configuration of the diagram on the lower side of FIG. 75. In the present modification example, the one readout circuit 22 shared by the four sensor pixels 12 is not arranged to squarely face the four sensor pixels 12, for example, and is arranged to be shifted in the first direction V. In the present modification example, the semiconductor substrate 21 is further configured by the plurality of island-shaped blocks 21A arranged side by side in the first direction V and the second direction H, with the insulating layer 53 interposed therebetween. Each block 21A includes, for example, a set of the reset transistor RST, the amplification transistor AMP, and the selection transistor SEL. In such a case, it is possible to cause the insulating layer 53 and the through-wiring line 67 to suppress a crosstalk between the readout circuits 22 adjacent to each other, thus making it possible to suppress image quality degradation due to a decrease in resolution and color mixing on a reproduced image.

### Modification Example M

FIG. 79 illustrates an example of a circuit configuration of the imaging device 1 according to any of the foregoing embodiments and modification examples thereof. The imaging device 1 according to the present modification example is a CMOS image sensor mounted with a column-parallel ADC.

As illustrated in FIG. 79, the imaging device 1 according to the present modification example is configured to include the vertical drive circuit 33, the column signal processing circuit 34, a reference voltage supply section 38, the horizontal drive circuit 35, a horizontal output line 37, and the system control circuit 36, in addition to the pixel region 13 in which the plurality of sensor pixels 12 each including a photoelectric conversion element are two-dimensionally arranged in matrix (matrix shape).

In this system configuration, on the basis of a master clock MCK, the system control circuit 36 generates a clock signal, a control signal, or the like that serves as a criterion for an operation of the vertical drive circuit 33, the column signal processing circuit 34, the reference voltage supply section 38, the horizontal drive circuit 35, and the like, and provides the clock signal, the control signal, or the like to the vertical drive circuit 33, the column signal processing circuit 34, the reference voltage supply section 38, the horizontal drive circuit 35, and the like.

In addition, the vertical drive circuit 33 is formed in the first substrate 10 together with each of the sensor pixels 12 of the pixel region 13, and is further formed in the second substrate 20, as well, in which the readout circuit 22 is formed. The column signal processing circuit 34, the reference voltage supply section 38, the horizontal drive circuit 35, the horizontal output line 37 and the system control circuit 36 are formed in the third substrate 30.

It may be possible to use, as the sensor pixel 12, for example, a configuration including, in addition to the photodiode PD, the transfer transistor TR that transfers charges obtained by photoelectric conversion at the photodiode PD to the floating diffusion FD, although illustration is omitted here. In addition, it may be possible to use, as the readout circuit 22, for example, a three-transistor configuration including the reset transistor RST that controls an electric potential of the floating diffusion 1-D, the amplification transistor AMP that outputs a signal corresponding to an electric potential of the floating diffusion FD, and the selection transistor SEL for selecting a pixel, although illustration is omitted here.

In the pixel region 13, the sensor pixels 12 are two-dimensionally arranged; with respect to this pixel arrangement of m-row and n-column, the pixel drive lines 23 are wired for respective rows, and the vertical signal lines 24 are wired for respective columns. Each one end of the plurality of pixel drive lines 23 is coupled to a corresponding output end of the rows of the vertical drive circuit 33. The vertical drive circuit 33 is configured by a shift register or the like, and controls row address and row scanning of the pixel region 13 via the plurality of pixel drive lines 23.

The column signal processing circuit 34 includes, for example, ADCs (analog-to-digital conversion circuits) 34-1 to 34-m provided for respective pixel columns, i e, for the respective vertical signal lines 24 of the pixel region 13, and converts analog signals outputted for respective columns from the sensor pixels 12 of the pixel region 13 into digital signals for outputting.

The reference voltage supply section 38 includes, for example, a DAC (digital-to-analog conversion circuit) 38A as a means to generate a reference voltage Vref of a so-called ramp (RAMP) waveform having a level that changes in an inclined manner as time elapses. It is to be noted that the means to generate the reference voltage Vref of the ramp waveform is not limited to the DAC 38A.

Under the control of a control signal CS1 provided from the system control circuit 36, the DAC 38A generates the reference voltage Vref of the ramp waveform on the basis of a clock CK provided from this system control circuit 36 to supply the generated reference voltage Vref to the ADCs 34-1 to 34-m of the column signal processing circuit 34.

It is to be noted that each of the ADCs 34-1 to 34-m is configured to selectively perform an AD conversion operation corresponding to each operation mode of a normal frame rate mode in a progressive scanning system for reading information on all of the sensor pixels 12, and a high-speed frame rate mode for setting exposure time of the sensor pixel 12 to 1/N to increase a frame rate by N times, e.g., by twice, as compared with the time of the normal frame rate mode. The switching between the operation modes is executed by controls performed by control signals CS2 and CS3 provided from the system control circuit 36. In addition, instruction information for switching between the operation modes of the normal frame rate mode and the high-speed frame rate mode is provided from an external system controller (unillustrated) to the system control circuit 36.

All of the ADCs 34-1 to 34-m have the same configuration; description is given here referring to the example of the ADC 34-m. The ADC 34-m is configured to include a comparator 34A, an up/down counter (referred to as U/D CNT in the drawing) 34B, e.g., as a number-counting means, a transfer switch 34C, and a memory 34D.

The comparator 34A compares a signal voltage Vx of the vertical signal line 24 corresponding to a signal outputted from each sensor pixel 12 of an n-th column of the pixel region 13 and the reference voltage Vref of the ramp waveform supplied from the reference voltage supply section 38 with each other. For example, when the reference voltage Vref is larger than the signal voltage Vx, an output Vco becomes an “H” level, whereas, when the reference voltage Vref is equal to or less than the signal voltage Vx, the output Vco becomes an “L” level.

The up/down counter 34B is an asynchronous counter; under the control of the control signal CS2 provided from the system control circuit 36, the up/down counter 34B is provided with the clock CK from the system control circuit 36 simultaneously with the DAC 38A, and performs down (DOWN)-counting or up (UP)-counting in synchronization with the clock CK to thereby measure a comparison period from the start of a comparison operation to the end of the comparison operation in the comparator 34A.

Specifically, in the normal frame rate mode, when performing a reading operation of signals from one sensor pixel 12, the down-counting is performed upon a first reading operation to thereby measure comparison time upon the first reading, whereas the up-counting is performed upon a second reading operation to measure comparison time upon the second reading.

Meanwhile, in the high-speed frame rate mode, while holding a count result for the sensor pixel 12 of a certain row as it is, the down-counting is subsequently performed for the sensor pixel 12 of the next row upon a first reading operation from the previous count result to thereby measure comparison time upon the first reading, and the up-counting is performed upon a second reading operation to thereby measure comparison time upon the second reading.

Under the control of the control signal CS3 provided from the system control circuit 36, the transfer switch 34C, in the normal frame rate mode, is brought into an ON (closed) state upon completion of the counting operation of the up/down counter 34B for the sensor pixel 12 of the certain row to transfer, to the memory 34D, the count results of the up/down counter 34B.

Meanwhile, for example, in the high-speed frame rate of N=2, an OFF (open) state remains upon completion of the counting operation of the up/down counter 34B for the sensor pixel 12 of the certain row, and subsequently an ON state is obtained upon completion of the counting operation of the up/down counter 34B for the sensor pixel 12 of the next row to transfer, to the memory 34D, the count results of the up/down counter 34B for the vertical two pixels.

In this manner, analog signals supplied for respective columns from the respective sensor pixels 12 of the pixel region 13 via the vertical signal lines 24 are converted into N-bit digital signals by respective operations of the comparators 34A and the up/down counters 34B in the ADCs 34-1 to 34-m, and are stored in the memories 34D.

The horizontal drive circuit 35 is configured by a shift register or the like, and controls column address and column scanning of the ADCs 34-1 to 34-m in the column signal processing circuit 34. Under the control of the horizontal drive circuit 35, the N-bit digital signals having been subjected to the AD conversion in the respective ADCs 34-1 to 34-m are read to the horizontal output line 37 in order, and are outputted as imaging data via the horizontal output line 37.

It is to be noted that it may also be possible to provide, in addition to the above-described components, a circuit, etc. that performs various types of signal processing on the imaging data outputted via the horizontal output line 37, although no particular illustration is given because there is no direct relationship with the present disclosure.

In the imaging device 1 mounted with the column-parallel ADC according to the present modification example having the above configuration, the count results of the up/down counter 34B are able to be selectively transferred to the memory 34D via the transfer switch 34C. This makes it possible to control the counting operation of the up/down counter 34B and the reading operation of the count results of the up/down counter 34B to the horizontal output line 37 independently of each other.

### Modification Example N

FIG. 80 illustrates an example of a configuration of the imaging device of FIG. 79, in which the three substrates (first substrate 10, second substrate 20, and third substrate 30) are stacked. In the present modification example, the first substrate 10 has a middle part where the pixel region 13 including the plurality of sensor pixels 12 is formed, with the vertical drive circuit 33 being formed around the pixel region 13. In addition, the second substrate 20 has a middle part where a readout circuit region 15 including the plurality of readout circuits 22 is formed, with the vertical drive circuit 33 being formed around the readout circuit region 15. In the third substrate 30, the column signal processing circuit 34, the horizontal drive circuit 35, the system control circuit 36, the horizontal output line 37, and the reference voltage supply section 38 are formed. This eliminates an increase in a chip size and inhibition of miniaturization of an area per pixel due to the structure of electrically coupling substrates to each other, similarly to the foregoing embodiments and modification examples thereof. As a result, it is possible to provide the imaging device 1 having a three-layered structure not inhibiting the miniaturization of an area per pixel, while having a chip size equivalent to an existing chip size. It is to be noted that the vertical drive circuit 33 may be formed only in the first substrate 10 or may be formed only in the second substrate 20.

### Modification Example 0

FIG. 81 illustrates a modification example of the cross-sectional configuration of the imaging device 1 according to any of the foregoing second embodiment and modification examples thereof. In the foregoing second embodiment and modification examples thereof, the logic circuits 32 is formed separately in the first substrate 10 and the second substrate 20, for example, as illustrated in FIG. 81. Here, a circuit 32A, of the logic circuit 32, provided on side of the first substrate 10 is provided with a transistor having a gate structure, in which a high dielectric constant film including a material (e.g., high-k) that is able to withstand a high-temperature process and a metal gate electrode are stacked. Meanwhile, in a circuit 32B provided on side of the second substrate 20, a low-resistance region 26 is formed, which includes a silicide formed using a Salicide (Self Aligned Silicide) process such as CoSi₂ and NiSi, on a front surface of an impurity diffusion region in contact with a source electrode and a drain electrode. The low-resistance region including a silicide is formed by a compound of a semiconductor substrate material and a metal. This makes it possible to use a high-temperature process such as thermal oxidation when forming the sensor pixel 12. In addition, it is possible to reduce contact resistance in a case of providing the low-resistance region 26 including a silicide on the front surface of the impurity diffusion region in contact with a source electrode and a drain electrode in the circuit 32B, of the logic circuit 32, provided on the side of the second substrate 20. As a result, it is possible to increase the speed of an arithmetic operation in the logic circuit 32.

FIG. 82 illustrates a modification example of the cross-sectional configuration of the imaging device 1 according to any of the foregoing first embodiment and modification examples thereof. In the logic circuit 32 of the foregoing first embodiment and modification examples thereof, a low-resistance region 37 including a silicide formed by using the Salicide (Self Aligned Silicide) process such as CoSi₂ and NiSi may be formed on the front surface of the impurity diffusion region in contact with the source electrode and the drain electrode. This makes it possible to use a high-temperature process such as thermal oxidation when forming the sensor pixel 12. In addition, it is possible, in the logic circuit 32, to reduce contact resistance in a case of providing the low-resistance region 37 including a silicide on the front surface of the impurity diffusion region in contact with the source electrode and the drain electrode. As a result, it is possible to increase the speed of an arithmetic operation in the logic circuit 32.

It is to be noted that, in the foregoing embodiments and modification examples thereof, the electric conductivity type may be opposite. For example, in the descriptions of the foregoing embodiments and modification examples thereof, the p-type may be read as the n-type, and the n-type may be read as the p-type. Even in such a case, it is possible to obtain effects similar to those of the foregoing embodiments and modification examples thereof.

### 5. Application Example

FIG. 83 illustrates an example of a schematic configuration of an imaging system 2 including the imaging device according to any of the foregoing embodiments and modification examples thereof.

The imaging system 2 is an electronic apparatus including, for example, an imaging apparatus such as a digital still camera or a video camera, or a portable terminal apparatus such as a smartphone or a tablet-type terminal. The imaging system 2 includes, for example, the imaging device 1 according to any of the foregoing embodiments and modification examples thereof, a DSP circuit 141, a frame memory 142, a display unit 143, a storage unit 144, an operation unit 145, and a power source unit 146. In the imaging system 2, the imaging device 1 according to any of the foregoing embodiments and modification examples thereof, the DSP circuit 141, the frame memory 142, the display unit 143, the storage unit 144, the operation unit 145, and the power source unit 146 are coupled to one another via a bus line 147.

The imaging device 1 according to any of the foregoing embodiments and modification examples thereof outputs image data corresponding to incident light. The DSP circuit 141 is a signal processing circuit that processes a signal (image data) outputted from the imaging device 1 according to any of the foregoing embodiments and modification examples thereof. The frame memory 142 temporarily holds the image data processed by the DSP circuit 141 in a frame unit. The display unit 143 includes, for example, a panel-type display device such as a liquid crystal panel or an organic EL (Electro Luminescence) panel, and displays a moving image or a still image captured by the imaging device 1 according to any of the foregoing embodiments and modification examples thereof. The storage unit 144 records image data of a moving image or a still image captured by the imaging device 1 according to any of the foregoing embodiments and modification examples thereof in a recording medium such as a semiconductor memory or a hard disk. The operation unit 145 issues an operation command for various functions of the imaging system 2 in accordance with an operation by a user. The power source unit 146 appropriately supplies various types of power for operation to the imaging device 1 according to any of the foregoing embodiments and modification examples thereof, the DSP circuit 141, the frame memory 142, the display unit 143, the storage unit 144, and the operation unit 145 which are supply targets.

Next, description is given of an imaging procedure in the imaging system 2.

FIG. 84 illustrates an example of a flowchart of an imaging operation in the imaging system 2. A user instructs start of imaging by operating the operation unit 145 (step S101). Then, the operation unit 145 transmits an imaging command to the imaging device 1 (step S102). The imaging device 1 (specifically, the system control circuit 36) executes imaging in a predetermined imaging method upon receiving the imaging command (step S103).

The imaging device 1 outputs image data obtained by the imaging to the DSP circuit 141. As used herein, the image data refers to data for all pixels of pixel signals generated on the basis of charges temporarily held in the floating diffusion FD. The DSP circuit 141 performs predetermined signal processing (e.g., noise reduction processing, etc.) on the basis of the image data inputted from the imaging device 1 (step S104). The DSP circuit 141 causes the frame memory 142 to hold the image data having been subjected to the predetermined signal processing, and the frame memory 142 causes the storage unit 144 to store the image data (step S105). In this manner, the imaging in the imaging system 2 is performed.

In the present application example, the imaging device 1 according to any of the foregoing embodiments and modification examples thereof is applied to the imaging system 2. This enables smaller size or higher definition of the imaging device 1, thus making it possible to provide a small or high-definition imaging system 2.

### 6. Examples of Practical Applications

### Practical Application Example 1

The technology according to an embodiment of the present disclosure (present technology) is applicable to various products. For example, the technology according to an embodiment of the present disclosure may be achieved in the form of an apparatus to be mounted to a mobile body of any kind. Non-limiting examples of the mobile body may include an automobile, an electric vehicle, a hybrid electric vehicle, a motorcycle, a bicycle, any personal mobility device, an airplane, an unmanned aerial vehicle (drone), a vessel, and a robot.

FIG. 85 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 85, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automatic driving, which makes the vehicle to travel autonomously without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 85, an audio speaker 12061, a display section 12062, and an instrument panel 12063 are illustrated as the output device. The display section 12062 may, for example, include at least one of an on-board display and a head-up display.

FIG. 86 is a diagram depicting an example of the installation position of the imaging section 12031.

In FIG. 86, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 86 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automatic driving that makes the vehicle travel autonomously without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

The description has been given hereinabove of one example of the mobile body control system, to which the technology according to an embodiment of the present disclosure may be applied. The technology according to an embodiment of the present disclosure may be applied to the imaging section 12031 among components of the configuration described above. Specifically, the imaging device 1 according to any of the foregoing embodiment and modification examples thereof is applicable to the imaging section 12031. The application of the technology according to an embodiment of the present disclosure to the imaging section 12031 allows for a high-definition captured image with less noise, thus making it possible to perform highly accurate control utilizing the captured image in the mobile body control system. [Practical Application Example 2]

FIG. 87 is a view depicting an example of a schematic configuration of an endoscopic surgery system to which the technology according to an embodiment of the present disclosure (present technology) can be applied.

In FIG. 87, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

FIG. 88 is a block diagram depicting an example of a functional configuration of the camera head 11102 and the CCU 11201 depicted in FIG. 87.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

The description has been given above of one example of the endoscopic surgery system, to which the technology according to an embodiment of the present disclosure is applicable. The technology according to an embodiment of the present disclosure is suitably applicable to, for example, the image pickup unit 11402 provided in the camera head 11102 of the endoscope 11100, among the configurations described above. Applying the technology according to an embodiment of the present disclosure to the image pickup unit 11402 enables miniaturization or higher definition of the image pickup unit 11402, thus making it possible to provide the miniaturized or high-definition endoscope 11100.

Although the description has been given hereinabove of the present disclosure with reference to the embodiments and modification examples thereof, the application example, and the practical application examples, the present disclosure is not limited to the foregoing embodiment, etc., and various modifications may be made. It is to be noted that the effects described herein are merely illustrative. The effects of the present disclosure are not limited to those described herein. The present disclosure may have other effects than those described herein.

In addition, the present disclosure may also have the following configurations.

(1)

An imaging device including:

a plurality of photoelectric conversion sections;

a plurality of color filters provided for the respective photoelectric conversion sections;

an element separation section extending from between adjacent two of the photoelectric conversion sections to between adjacent two of the color filters; and

a diffusion layer provided in contact with a surface, of the element separation section, on side of the photoelectric conversion section, the diffusion layer having an electric conductivity type different from an electric conductivity type of the photoelectric conversion section.

(2)

The imaging device according to (1), in which

the plurality of photoelectric conversion sections are provided in matrix in a semiconductor substrate,

the plurality of color filters are provided at positions on side of a light-receiving surface of the semiconductor substrate and opposed to the plurality of photoelectric conversion sections,

the imaging device further includes a well layer provided on side of a surface, of the semiconductor substrate, opposite to the light-receiving surface, the well layer having an electric conductivity type different from the electric conductivity type of the photoelectric conversion section, and

the diffusion layer and the well layer are electrically conducted to each other.

(3)

The imaging device according to (2), in which the element separation section is provided within a trench provided in the semiconductor substrate, and is provided to protrude from the light-receiving surface.

(4)

The imaging device according to (3), in which the element separation section has a DTI (Deep Trench Isolation) structure configured by an insulating film in contact with an inner wall of the trench and a metal buried part formed inside the insulating film, and

the DTI structure is provided to extend from between adjacent two of the photoelectric conversion sections to between adjacent two of the color filters.

(5)

The imaging device according to (4), in which the metal buried part is formed by aluminum or an aluminum alloy.

(6)

The imaging device according to (4), in which the metal buried part is formed collectively by utilizing a substitution phenomenon through heat treatment.

(7)

The imaging device according to (3), in which the trench and the element separation section are each formed to penetrate the semiconductor substrate.

(8)

The imaging device according to (3), in which the trench and the element separation section each have one end provided in the well layer, while the trench and the element separation section each do not penetrate the semiconductor substrate.

(9)

The imaging device according to (8), further including, in the well layer, a readout circuit that outputs a pixel signal based on charges outputted from the photoelectric conversion section, the readout circuit being provided one by one for each of the photoelectric conversion sections, or being provided one by one for each of the plurality of photoelectric conversion sections.

(10)

An imaging device including:

a plurality of photoelectric conversion sections provided in matrix in a semiconductor substrate; and

an element separation section provided in the semiconductor substrate and between adjacent two of the photoelectric conversion sections,

the element separation section having a DTI (Deep Trench Isolation) structure configured by an insulating film in contact with an inner wall of a trench provided in the semiconductor substrate and a metal buried part formed inside the insulating film, and

the metal buried part being formed by aluminum or an aluminum alloy.

(11)

The imaging device according to (10), further including a well layer provided on side of a surface, of the semiconductor substrate, opposite to a light-receiving surface, the well layer having an electric conductivity type different from an electric conductivity type of the photoelectric conversion section, in which

the trench and the element separation section each have one end provided in the well layer, while the trench and the element separation section each do not penetrate the semiconductor substrate.

(12)

The imaging device according to (11), including, in the well layer, a readout circuit that outputs a pixel signal based on charges outputted from the photoelectric conversion section, the readout circuit being provided one by one for each of the photoelectric conversion sections, or being provided one by one for each of the plurality of photoelectric conversion sections.

According to the imaging device of a first aspect of the present disclosure, the element separation section is provided, extending from between the two adjacent photoelectric conversion sections to between the two adjacent color filters, thus making it possible to suppress a crosstalk between pixels more effectively.

According to the imaging device of a second aspect of the present disclosure, the element separation section between the two adjacent photoelectric conversion sections is provided with the metal buried part formed by aluminum or an aluminum alloy, thus making it possible to suppress a crosstalk between pixels more effectively.

According to the imaging device of a third aspect of the present disclosure, the element separation section and the diffusion layer in contact with the surface on the side of the photoelectric conversion section and having an electric conductivity type different from an electric conductivity type of the photoelectric conversion section are provided between the two adjacent photoelectric conversion sections. Further, the plurality of readout circuits each sharing the plurality of photoelectric conversion sections are provided in the well layer provided in contact with the surface on the side of the photoelectric conversion section. This makes it possible to suppress a crosstalk between pixels more effectively, while sharing the plurality of photoelectric conversion sections by one readout circuit.

It is to be noted that the effects of the present technology are not necessarily limited to the effects described herein, and may have any of the effects described herein.

This application claims the benefit of Japanese Priority Patent Application JP2018-215383 filed with the Japan Patent Office on Nov. 16, 2018, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

1. An imaging device comprising:
a plurality of photoelectric conversion sections;
a plurality of color filters provided for the respective photoelectric conversion sections;
an element separation section extending from between adjacent two of the photoelectric conversion sections to between adjacent two of the color filters; and
a diffusion layer provided in contact with a surface, of the element separation section, on side of the photoelectric conversion section, the diffusion layer having an electric conductivity type different from an electric conductivity type of the photoelectric conversion section.

2. The imaging device according to claim 1, wherein
the plurality of photoelectric conversion sections are provided in matrix in a semiconductor substrate,
the plurality of color filters are provided at positions on side of a light-receiving surface of the semiconductor substrate and opposed to the plurality of photoelectric conversion sections,
the imaging device further comprises a well layer provided on side of a surface, of the semiconductor substrate, opposite to the light-receiving surface, the well layer having an electric conductivity type different from the electric conductivity type of the photoelectric conversion section, and
the diffusion layer and the well layer are electrically conducted to each other.

3. The imaging device according to claim 2, wherein the element separation section is provided within a trench provided in the semiconductor substrate, and is provided to protrude from the light-receiving surface.

4. The imaging device according to claim 3, wherein
the element separation section has a DTI (Deep Trench Isolation) structure configured by an insulating film in contact with an inner wall of the trench and a metal buried part formed inside the insulating film, and
the DTI structure is provided to extend from between adjacent two of the photoelectric conversion sections to between adjacent two of the color filters.

5. The imaging device according to claim 4, wherein the metal buried part is formed by aluminum or an aluminum alloy.

6. The imaging device according to claim 4, wherein the metal buried part is formed collectively by utilizing a substitution phenomenon through heat treatment.

7. The imaging device according to claim 3, wherein the trench and the element separation section are each formed to penetrate the semiconductor substrate.

8. The imaging device according to claim 3, wherein the trench and the element separation section each have one end provided in the well layer, while the trench and the element separation section each do not penetrate the semiconductor substrate.

9. The imaging device according to claim 8, further comprising, in the well layer, a readout circuit that outputs a pixel signal based on charges outputted from the photoelectric conversion section, the readout circuit being provided one by one for each of the photoelectric conversion sections, or being provided one by one for each of the plurality of photoelectric conversion sections.

10. An imaging device comprising:
a plurality of photoelectric conversion sections provided in matrix in a semiconductor substrate; and
an element separation section provided in the semiconductor substrate and between adjacent two of the photoelectric conversion sections,
the element separation section having a DTI (Deep Trench Isolation) structure configured by an insulating film in contact with an inner wall of a trench provided in the semiconductor substrate and a metal buried part formed inside the insulating film, and
the metal buried part being formed by aluminum or an aluminum alloy.

11. The imaging device according to claim 10, further comprising a well layer provided on side of a surface, of the semiconductor substrate, opposite to a light-receiving surface, the well layer having an electric conductivity type different from an electric conductivity type of the photoelectric conversion section, wherein
the trench and the element separation section each have one end provided in the well layer, while the trench and the element separation section each do not penetrate the semiconductor substrate.

12. The imaging device according to claim 11, comprising, in the well layer, a readout circuit that outputs a pixel signal based on charges outputted from the photoelectric conversion section, the readout circuit being provided one by one for each of the photoelectric conversion sections, or being provided one by one for each of the plurality of photoelectric conversion sections.

13. An imaging device comprising:
a plurality of photoelectric conversion sections provided in matrix in a semiconductor substrate;
an element separation section provided in the semiconductor substrate and between adjacent two of the photoelectric conversion sections;
a well layer provided on side of a surface, of the semiconductor substrate, opposite to a light-receiving surface, the well layer having an electric conductivity type different from an electric conductivity type of the photoelectric conversion section;
a diffusion layer provided in contact with a surface, of the element separation section, on side of the photoelectric conversion section, the diffusion layer having an electric conductivity type different from the electric conductivity type of the photoelectric conversion section; and
a plurality of readout circuits provided, in the well layer, one by one for each of the plurality of photoelectric conversion sections, the readout circuits each outputting a pixel signal based on charges outputted from the photoelectric conversion section.

14. The imaging device according to claim 13, wherein
the element separation section has a DTI (Deep Trench Isolation) structure configured by an insulating film in contact with an inner wall of a trench provided in the semiconductor substrate and a metal buried part formed inside the insulating film, and
the trench and the element separation section each have one end provided in the well layer, while the trench and the element separation section each do not penetrate the semiconductor substrate.
